(19) United States
(12) Patent Application Publication
(10) Pub. No.: US 2021/0040581 A1
(43) Pub. Date: Feb. 11, 2021

(54) INTEGRATED ELECTRONIC WASTE RECYCLING AND RECOVERY SYSTEM AND PROCESS OF USING SAME

(71) Applicant: ENTEGRIS, Inc., Billerica, MA (US)

(72) Inventors: Yuxin Song, Shanghai (CN); Eric David Simms, Billerica, MA (US); James Moen, Billerica, MA (US); Jianfen Tong, Billerica, MA (US); Biqin Chen, Pudong (CN); Michael B. Korzenski, Billerica, MA (US); Ping Jiang, Beijing (CN); Bryan Hinzie, Billerica, MA (US); Richard T. Graves, Billerica, MA (US); Maryam Khoroshahi, Billerica, MA (US); James R. Garstka, Billerica, MA (US); Christopher Vroman, Billerica, MA (US); Brian Wesley Diessel-Horst, Billerica, MA (US)

(21) Appl. No.: 16/069,722

(22) PCT Filed: Jan. 14, 2016
(86) PCT No.: PCT/CN2016/070904

§ 371 Date: Jul. 12, 2018

(51) Int. Cl. C22B 3/00; H05K 3/22; C22B 1/00

(52) U.S. Cl. CPC C22B 11/046; H05K 2203/178; C22B 1/005; H05K 3/22

(57) ABSTRACT

Systems and processes for recycling printed circuit boards, wherein precious metals may be reclaimed. The system generally includes a number of modules to systematically remove materials from the printed circuit boards and to separate the precious metals from the materials.

### FIELD

The present invention relates generally to systems and processes for recycling waste electrical and electronic equipment such as printed circuit boards to separate materials including, but not limited to, precious metals.

### DESCRIPTION OF THE RELATED ART

As electronic equipment becomes more ever-present, disposal of used electronic equipment including obsolete or damaged computers, computer monitors, television receivers, cellular telephones, and similar products, is increasing at a rapid rate. It is recognized that there are significant hazards to living things and to the environment generally when electronic equipment is dumped in landfills. Equally, it is understood that improper disassembly of such equipment poses appreciable risks to the health and safety of people performing manual disassembly.

Printed circuit boards (PCBs) are a common element of many electronic systems, e.g., motherboards, noteboards, TV boards, server boards, hard drive boards, SCSI cards, and smartphones. PCBs are typically manufactured by laminating film on clean copper foil, which is supported on a fiberglass plate matrix. The film is exposed with a film negative of the circuit board design, and an etcher is used to remove unmasked copper foil from the plate. Solder is then applied over the unetched copper on the board. Depending upon the use and design of the particular PCB, various other metals may be used in the manufacturing process, including lead, tin, nickel, iron, zinc, aluminum, silver, gold, platinum, palladium, and mercury. The PCBs include many components, for example, transistors, capacitors, heat sinks, fans, integrated circuit chips (IC's), resistors, integrated switches, processors, connectors, or other “miscellaneous parts” present on the PCB's including iron parts, batteries, crystals, USB ports, BGA chips, metal covers, metal casings, metal shields, stickers, foam or plastic shields, and metal or plastic brackets.

PCBs are potentially a difficult waste material to process since they generally have little usefulness once they are removed from the electrical system in which they were installed. In addition, they typically consist of materials that cause them to be classified as a hazardous or “special” waste stream. They must be segregated and handled separately from other nonhazardous solid waste streams. PCBs that are handled as waste materials must be processed using any one of several available disposal options. Not only are these options expensive, they require a significant amount of effort and handling by the generator. Furthermore, since some of these disposal options do not include destruction of the waste circuit boards, the generator also retains much of the liability associated with improper handling or disposal.

Different methods have been suggested to try to combat the waste of raw materials and environmental pollution caused by the ever increasing load of scrap electronic waste. To date, methods requiring a high energy demand are needed to separate the materials so that they can be recycled. Mechanical, hydrometallurgical and pyrometallurgical methods have been the traditional methods of recycling of waste PCBs, which comprise grinding of the whole waste, followed by attempts to separate and concentrate different material streams. Disadvantageously, when PCBs are ground, only the plastic fraction can be effectively liberated from metals and toxic gases and dust can be evolved. Accordingly, mechanical methods do not result in high recovery rates, especially for precious metals. In hydrometallurgical methods, large amounts of chemicals are used, generating huge quantities of waste acids and sludge, which have to be disposed as hazardous waste. Furthermore, the overall processes of recycling of various metals by chemical processes are very long and complicated. Thermal methods, including pyrometallurgical processing of waste PCBs, result in the emission of hazardous chemicals to the atmosphere and water as the result of thermal degradation of epoxy (formation of dioxins and furans) and volatilization of metals (including Pb, Sb, As and Ga). Thermal methods are further characterized by high energy consumption, and the necessity to use expensive exhaust gas purification systems and corrosion resistance equipment.

Disadvantageously, the known methods of extracting precious metals (e.g., gold) from materials include using toxic and/or expensive chemicals (i.e., lixiviants) to leach the gold from the material. One of the oldest commercial processes for dissolving gold is the so-called “cyanide process” whereby cyanide ions form a stable complex with gold. The effectiveness of the cyanide process has led to its commercial usage for both extraction of gold from its ores and for the reclamation of gold from gold coated scrap parts. Generally, a potassium cyanide solution is used in the “cyanide process.” Such a solution is very toxic and disposing of spent cyanide solution has become a significant and increasing waste disposal and pollution abatement control problem.

The traditional methods of recycling waste PCBs resulted in environmental contamination, high cost expenditure and low efficiency. In contrast, the systems and methods described herein are based on a differential approach to the recycling of materials, wherein the various parts of the waste PCBs are separated and processed based on appearance and physical and chemical properties.

Processes for removing at least one recyclable material from a printed circuit board (PCB) were previously described in International Patent Application No. PCT/US2011/032675 filed on Apr. 15, 2011 in the name of André Brosseau et al. and entitled “Method for Recycling of Obsolete Printed Circuit Boards,” which is hereby incorporated by reference herein in its entirety. Broadly, the method described in PCT/US2011/032675 comprised at least one of (a), (b), (c), or any combination thereof:

(a) releasing a component from the PCB;
(b) recovering a precious metal from the PCB and/or PCB component;
(c) recovering a base metal from the PCB.

Systems and processes for recycling printed circuit boards, integrated circuits and printed circuit board components to separate materials for reuse and/or recovery were also previously described in International Patent Application No. PCT/US2012/069404 filed on Dec. 13, 2012 in the name of Tianniu CHEN et al. and entitled “Apparatus and Method for Stripping Solder Metals During the Recycling of Waste Electrical and Electronic Equipment,” which is hereby incorporated herein by reference in its entirety. Broadly, the apparatus described in PCT/US2012/069404 comprised (a) at least one of a mechanical solder removal module and/or a heater module, and (b) a chemical solder removal module.

Thus, a need exists for a method of recycling waste electrical and electronic equipment such as printed circuit boards and PCB components that overcomes or minimizes the above-referenced problems.

### SUMMARY

Embodiments of the invention relate generally to systems and processes for recycling printed circuit boards, integrated circuits, and printed circuit board components to separate materials for reuse and/or recovery. More particularly, the embodiments of the invention relate generally to systems and processes for recycling PCBs to efficiently recover precious metals while minimizing the amount of chemicals and other resources used.

Embodiments of the invention relate to integrated, intelligent systems and processes for recycling printed circuit boards, integrated circuits, and other printed circuit board components.

Embodiments of the invention relate to intelligent systems and processes for recycling printed circuit boards, integrated circuits, and other printed circuit board components comprising means to select a processing sequence based on PCB and/or PCB component type.

Embodiments of the invention relate to intelligent systems and processes for recycling printed circuit boards, integrated circuits, and other printed circuit board components comprising means to select a processing sequence based on PCB and/or PCB component type, wherein the processing sequence comprises processing in a gold leaching module (280).

Embodiments of the invention relate to intelligent systems and processes for recycling printed circuit boards, integrated circuits, and other printed circuit board components comprising intelligence means and a gold leaching module (280) for processing PCBs and/or PCB components.

Another embodiment of the invention relates to an integrated, intelligent system for recycling material selected from the group consisting of printed circuit boards (PCB), PCB components, materials comprising gold, and combinations thereof, wherein the system efficiently recovers more than about 80% of the gold contained in the material, wherein the system comprises a solids processing technology (SPT) base metal removal module and a SPT gold removal module.

Another embodiment of the invention relates to an integrated, intelligent system for recycling material selected from the group consisting of printed circuit boards (PCB), PCB components, materials comprising gold, and combinations thereof, wherein the system efficiently recovers more than about 80% of the gold contained in the material, wherein the system comprises a solids processing technology (SPT) base metal removal module and a SPT gold removal module, and optionally at least one additional module selected from the group consisting of:

(a) a SPT furnace module,

(b) a SPT milling module,

(c) a SPT silver leaching module,

(d) any combination of (a)-(c), and

(e) every module of (a)-(c),

wherein the modules are positioned and/or operated in series with one another, with or without intervening parts.

Still another embodiment of the invention relates to an integrated, intelligent system for recycling material selected from the group consisting of printed circuit boards (PCB), PCB components, materials comprising gold, and combinations thereof, wherein the system efficiently recovers more than about 80% of the gold contained in the material, wherein the system comprises a solids processing technology (SPT) furnace module and a SPT gold removal module.

Still another embodiment of the invention relates to an integrated, intelligent system for recycling material selected from the group consisting of printed circuit boards (PCB), PCB components, materials comprising gold, and combinations thereof, wherein the system efficiently recovers more than about 80% of the gold contained in the material, wherein the system comprises a solids processing technology (SPT) furnace module and a SPT gold removal module, and optionally at least one additional module selected from the group consisting of:

(a) a SPT milling module,

(b) a SPT base metal removal module

(c) a SPT silver leaching module,

(d) any combination of (a)-(c), and

(e) every module of (a)-(c),

wherein the modules are positioned and/or operated in series with one another, with or without intervening parts.

Yet another embodiment of the invention relates to an integrated, intelligent system for recycling material selected from the group consisting of printed circuit boards (PCB), PCB components, materials comprising gold, and combinations thereof, wherein the system efficiently recovers more than about 80% of the gold contained in the material, said system comprising a gold leaching module and a SPT gold removal module.

Yet another embodiment of the invention relates to an integrated, intelligent system for recycling material selected from the group consisting of printed circuit boards (PCB), PCB components, materials comprising gold, and combinations thereof, wherein the system efficiently recovers more than about 80% of the gold contained in the material, said system comprising a gold leaching module and a SPT gold removal module, and optionally at least one additional module selected from the group consisting of:

(a) a pre-board clearing module,

(b) a Board clearing module,

(c) a desoldering module,

(d) a base metal removal module,

(e) a SPT furnace module,

(f) a SPT milling module,

(g) a SPT base metal removal module,

(h) a SPT silver leaching module,

(i) any combination of (a)-(h), and

(j) every module of (a)-(h),

wherein the modules are positioned and/or operated in series with one another, with or without intervening parts.

Another embodiment of the invention relates to a process of recycling material selected from the group consisting of printed circuit boards (PCB), PCB components, materials comprising gold, and combinations thereof, wherein the process efficiently recovers more than about 80% of the gold contained in the material, said process comprising (a) removing at least one base metal from a solid using a base metal removal composition in a solids processing technology (SPT) base metal removal module and (b) removing gold from a solid using a gold removal composition in a SPT gold removal module, wherein the solid comprises materials comprising gold that have been ashed, ground, and/or crushed, and optionally at least one additional step selected from the group consisting of:
(i) aching the materials in a SPT furnace module to yield a solid comprising ash,
(ii) grinding the materials in an SPT milling module to yield a solid comprising ground materials,
(iii) removing silver from the solid using a silver removal composition in a SPT silver leaching module,
(iv) any combination of (i)-(iii), and
(v) every process of (i)-(iii),
   wherein the processes are operated in series with one another, with or without intervening processes.

Still another embodiment of the invention relates to a process of recycling material selected from the group consisting of printed circuit boards (PCB), PCB components, materials comprising gold, and combinations thereof, said process comprising (a) ashing the materials in a solids processing technology (SPT) furnace module to yield a solid comprising ash, and at least one additional step selected from the group consisting of:
(i) grinding the materials in an SPT milling module to yield a solid comprising ground materials,
(ii) removing at least one base metal from a solid using a base metal removal composition in a SPT base metal removal module,
(iii) removing gold from the solid using a gold removal composition in a SPT gold removal module,
(iv) removing silver from the solid using a silver removal composition in a SPT silver leaching module,
(v) any combination of (i)-(iv), and
(vi) every process of (i)-(iv),
   wherein the processes are operated in series with one another, with or without intervening processes.

Still another embodiment of the invention relates to a process of recycling material selected from the group consisting of printed circuit boards (PCB), PCB components, materials comprising gold, and combinations thereof, wherein the process efficiently recovers more than about 80% of the gold contained in the material, said process comprising (a) ashing the materials in a solids processing technology (SPT) furnace module to yield a solid comprising ash, and (b) removing gold from the solid using a gold removal composition in a SPT gold removal module, and optionally at least one additional step selected from the group consisting of:
(i) grinding the materials in an SPT milling module to yield a solid comprising ground materials,
(ii) removing at least one base metal from a solid using a base metal removal composition in a SPT base metal removal module,
(iii) removing silver from the solid using a silver removal composition in a SPT silver leaching module,
(iv) any combination of (i)-(iii), and
(v) every process of (i)-(iii),
   wherein the processes are operated in series with one another, with or without intervening processes.

Yet another embodiment of the invention relates to a process of recycling material selected from the group consisting of printed circuit boards (PCB), PCB components, materials comprising gold, and combinations thereof, wherein the process efficiently recovers more than about 80% of the gold contained in the material, said process comprising removing gold from a solid using a gold removal composition in a SPT gold removal module, wherein the solid comprises the material that have been ashed, ground, and/or crushed, and optionally at least one additional step selected from the group consisting of:
(i) sorting the material in a pre-board clearing module, wherein the PCBs are sorted and the PCB components and materials comprising gold are removed manually and/or automatically,
(ii) removing PCB components and materials comprising gold from PCBs using heat and mechanical means in a Board clearing module,
(iii) removing solder, PCB components, and materials comprising gold from PCBs using a solder removal composition in a desoldering module,
(iv) leaching gold from materials comprising gold using a gold leaching composition in a gold leaching module
(v) removing base metals from the material using a base metal removal composition in a base metal removal module,
(vi) ashing the material in a SPT furnace module to yield a solid comprising ash,
(vii) grinding the material in an SPT milling module to yield a solid comprising ground materials,
(viii) removing at least one base metal from the solid using a base metal removal composition in a SPT base metal removal module,
(ix) removing silver from the solid using a silver removal composition in a SPT silver leaching module,
(x) any combination of (i)-(ix), and
(xi) every process of (i)-(ix),
   wherein the processes are operated in series with one another, with or without intervening processes.

Yet another embodiment of the invention relates to a process of recycling material selected from the group consisting of printed circuit boards (PCB), PCB components, materials comprising gold, and combinations thereof, wherein the process efficiently recovers more than about 80% of the gold contained in the material, said process comprising (a) leaching gold from materials comprising gold using a gold leaching composition in a gold leaching module and (b) removing gold from a solid using a gold removal composition in a SPT gold removal module, wherein the solid comprises the material that have been ashed, ground, and/or crushed, and optionally at least one additional step selected from the group consisting of:
(i) sorting the material in a pre-board clearing module, wherein the PCBs are sorted and the PCB components and materials comprising gold are removed manually and/or automatically,
(ii) removing PCB components and materials comprising gold from PCBs using heat and mechanical means in a Board clearing module,
(iii) removing solder, PCB components, and materials comprising gold from PCBs using a solder removal composition in a desoldering module,
(iv) removing base metals from the material using a base metal removal composition in a base metal removal module,
(v) ashing the material in a SPT furnace module to yield a solid comprising ash,
(vi) grinding the material in an SPT milling module to yield a solid comprising ground materials,
(vii) removing at least one base metal from the solid using a base metal removal composition in a SPT base metal removal module,
(viii) removing silver from the solid using a silver removal composition in a SPT silver leaching module,
(ix) any combination of (i)-(viii), and
(x) every process of (i)-(viii),
   wherein the processes are operated in series with one another, with or without intervening processes.

Other aspects, features and advantages will be more fully apparent from the ensuing disclosure and appended claims.

### BRIEF DESCRIPTION OF THE DRAWINGS

FIG. 1 is a general schematic of the system described herein including a PCB platform (20) and platform and a SPT platform (30).

FIG. 2 is a general schematic of the system described herein including modules that may be present in the PCB platform (20) and the SPT platform (30) of FIG. 1.

FIG. 3 is a schematic of one embodiment of the pre-board clearing module (220) process.

FIG. 4 is a schematic of one embodiment of the desoldering module (260) apparatus.

FIG. 5 illustrates one embodiment of a drum (500).

FIG. 6 illustrates another embodiment of a drum (500).

FIG. 7 illustrates one embodiment of a drum (500) being inserted into a tank (264, 266, 268, 270, 272, 274, 284, 286, 288, 290, 292, 294).

FIG. 8 illustrates an embodiment of the drum line that may be used in the desoldering module (260), the gold leaching module (280) and/or the base metal removal module (261).

FIG. 9 is a schematic of one embodiment of the gold leaching module (280).

FIG. 10 is a schematic of one embodiment of the SPT furnace module (320) and the SPT milling module (340).

FIG. 11 is a schematic of a basic SPT tool module (360) tank.

FIG. 12A is a schematic of one embodiment of the SPT tool module (360), wherein at least two modules may be contained therein.

FIG. 12B is a schematic of one embodiment of the SPT tool module (360), wherein at least three modules may be contained therein.

FIG. 13 is a schematic of one embodiment of an SPT tool module (360) comprising a reaction tank, a removal composition tank, and a rinse liquid tank.

FIG. 14 is a schematic of another embodiment of an SPT tool module (360) comprising a reaction tank, a removal composition tank, a rinse liquid tank, and a rinse tank.

FIG. 15 is a schematic of yet another embodiment of an SPT tool module (360) comprising a reaction tank, a removal composition tank, a holding tank, a rinse liquid tank, and a rinse tank.

FIG. 16 is a schematic of another embodiment of an SPT tool module (360) comprising a reaction tank, a removal composition tank, a holding tank, two rinse liquid tanks, and two rinse tanks

FIG. 17A is a schematic of still another embodiment of an SPT tool module (360) comprising a reaction tank, two removal composition tanks, two holding tanks, two rinse liquid tanks, and two rinse tanks

FIG. 17B illustrates the initiation of a first chemical reaction in the SPT tool module (360) of FIG. 17A.

FIG. 17C illustrates the initiation of a second chemical reaction in the SPT tool module (360) of FIG. 17A.

FIG. 17D illustrates the general chemical reaction occurring in the two holding tanks

FIG. 17E illustrates the centrifugation and first rinsing of the slurry of the first chemical reaction from the SPT tool module (360) of FIG. 17B.

FIG. 17F illustrates the centrifugation and first rinsing of the slurry of the second chemical reaction from the SPT tool module (360) of FIG. 17C.

FIG. 17G illustrates the centrifugation and second rinsing of the slurry from the first rinsing of the SPT tool module (360) of FIG. 17F.

FIG. 17H illustrates the optional centrifugation and third rinsing of the slurry from the second rinsing of the SPT tool module (360) of FIG. 17G.

FIG. 17I illustrates the centrifugation and separation of the slurry from the optional third rinsing of the SPT tool module (360) of FIG. 17H.

FIG. 17J illustrates the centrifugation and separation of the slurry from the second rinsing of the SPT tool module (360) of FIG. 17G.

### DETAILED DESCRIPTION OF PREFERRED EMBODIMENTS

The present invention relates generally to integrated systems and processes for recycling printed wire assemblies, printed circuit boards, integrated circuits and printed circuit board components to separate materials for reuse and/or recovery. More particularly, the present invention relates generally to integrated systems and processes for recycling PCBs to more efficiently separate and recover metals and working components, while simultaneously minimizing the use of chemicals and other resources. The system and process of using may be controlled by one or more programmable logic controllers (PLC) that coordinate and regulate automated process steps in the apparatus. The one or more PLCs allow multiple different processing modules, and multiple different drums and tanks within each module, to operate simultaneously through the apparatus, providing maximum throughput per square foot of factory space. Multi-tasking capability includes scheduling software that provides the system the intelligence necessary to be able to concurrently process multiple modules and multiple tanks within each module, when process times in each tank may not be balanced. Process recipes and procedures based on the type of board and/or components, as well as batch size, are stored in PLCs and automatically or manually initiated at the time batches of PCB boards and/or PCB components enter the process stream. The process stream entrance may vary depending on the type of board and/or component. In one embodiment, each module has at least one PLC. Further, when necessary, a supervisory control and data acquisition (SCADA) device or equivalent thereof and/or a communication network can be used to control the one or more PLCs. The systems described herein enable high volume processing of electronic waste with precious metal recovery efficiencies of greater than 80%, preferably greater than 90% and more preferably greater than 95%.

For the purposes of the present disclosure, “electronic waste” or “e-waste” corresponds to computers, computer monitors, television receivers, electronic pads, cellular telephones, personal digital assistants (PDA), video cameras, digital cameras, DVD players, video game consoles, facsimile machines, copiers, MP3 players, and similar products that have reached the end of their useful life or otherwise have been disposed of Electronic waste or e-waste includes the components contained within these well-known items such as printed circuit boards and the components contained thereon (e.g., transistors, capacitors, heat sinks, fans, chips, micro components, integrated circuits (IC's), resistors, integrated switches, processors, connectors, USB ports, BGA chips).

For the purposes of general disclosure, a board is described as comprising any one of paper, low dielectric plastics, thin and flexible plastics, ceramic/metal, fiberglass, epoxy, phenols, aluminum, copper layers, and foils. As will be appreciated by the skilled artisan, “fiberglass” is a glass-reinforced plastic or a glass fiber reinforced plastic and will correspond to any material that comprises plastic and glass.

As used herein, “precious metals” include the metals gold, silver, platinum, palladium, rhodium, iridium, osmium, rhenium, ruthenium and alloys comprising same.

As used herein, “base metals” corresponds to iron, nickel, zinc, copper, aluminum, tungsten, molybdenum, tantalum, magnesium, cobalt, bismuth, cadmium, titanium, zirconium, antimony, manganese, beryllium, chromium, germanium, vanadium, gallium, hafnium, indium, niobium, rhenium, thallium, alloys comprising same, and combinations thereof.

As used herein, “copper” corresponds to Cu(0) metal as well as alloys comprising Cu(0).

As used herein, “about” is intended to correspond to greater than or less than no more than 5% of the stated value.

As defined herein, “complexing agent” includes those compounds that are understood by one skilled in the art to be complexing agents, chelating agents, sequestering agents, and combinations thereof. Complexing agents will chemically combine with or physically associate with the metal atom and/or metal ion to be removed using the compositions described herein.

For the purposes of the present description, “printed circuit boards” is used to describe printed wire boards, printed circuit boards, as well as printed circuit board assemblies. The printed circuit board (PCB) provides the mechanical support and electrical connections for electronic components. PCBs can be single sided, double sided, or multi-layered. PCB assemblies correspond to PCBs populated with electronic components.

As used herein, “substantially dissolved” is defined herein to be that more than 95 wt. % of the material originally present is dissolved or otherwise solubilized, preferably more than 98 wt. %, more preferably more than 99 wt. %, and most preferably more than 99.9 wt. %. “Not substantially dissolved” is defined herein to be that less than 5 wt. % of the material originally present is dissolved or otherwise solubilized, preferably less than 2 wt. %, more preferably less than 1 wt. %, and most preferably less than 0.1 wt. %.

As used herein, the term “leaches” or “removes” corresponds to the complete or partial removal or extraction of the particular metal or other desired material into the particular removal composition. The particular metal or other desired material is dissolved or otherwise solubilized in the particular removal composition, preferably dissolved.

As defined herein, “crushing” corresponds to any method that substantially exposes the metals of the PCB and/or PCB component to a removal composition, e.g., cracking, pulverizing or shredding the PCB and/or PCB component.

As defined herein, “milling” corresponds to any method that reduces a larger material into a smaller material using a compressive force, thereby increasing the surface area of the material that can be exposed to a removal composition for removal of metals and other desired materials therefrom. Milling can be accomplished with a negligible rise in temperature of the materials being milled.

As defined herein, “grinding” corresponds to any method that reduces a larger material into a smaller material using a shearing force or a cutting action, thereby increasing the surface area of the material that can be exposed to a removal composition for removal of metals and other desired materials therefrom.

It should be appreciated that the “removal compositions” described herein are specifically and/or selectively formulated to remove one or more metals or other desired materials. Further, the removal compositions can be proprietary, commercially available, or both.

It should be appreciated by the skilled artisan that solder, adhesives, glues and/or epoxy attaches “components,” such as transistors, capacitors, heat sinks, fans, integrated circuit chips (IC's), resistors, integrated switches, processors (e.g., CPUs), connectors, USB ports, BGA chips, to the PCB.

As defined herein, “recyclable components” corresponds to components that comprise a metal that has value and is to be reclaimed. As defined herein, “micro components” correspond to any component that is less than about 2-3 mm in size, e.g., can be sorted from larger objects based on size. For the purposes of the figures, the term “M.Comp.” is shorthand for micro-component.

As defined herein, “chips” include ICs and CPUs as well as other solid state “micro-components” such as capacitors and/or resistors.

As defined herein, a “module” corresponds to a distinct system and corresponding process that is capable of facilitating the chemical, mechanical, thermal (i.e., heat), and physical processes needed to accomplish a desired end goal, for example, the removal of components from a PCB, the removal of solder, the leaching of gold, the leaching of silver, and the removal of base metals. The modules may be connected and/or operate serially or in parallel, with or without intervening steps therebetween, or not connected at all, e.g., a module could be off-site relative to other modules or a module may be within another module.

As defined herein, “epoxy” will principally denote the end products of epoxy resins, which can be used to attach a component or miscellaneous part to a PCB. The end products correspond to a thermosetting polymer with high mechanical properties as well as temperature and chemical resistance. In the electronics industry epoxy resins are often used in overmolding integrated circuits, transistors, and making printed circuit boards. In addition, epoxy resins are used to bond copper foil to PCB substrates, and are a component of the solder mask on many PCBs.

As used herein, “ashing” or “to ash” corresponds to a process wherein an organic material, also known as “ashable content,” is reacted with air or other oxygen source at a high temperature, e.g., burned, to leave only noncombustible material.

As used herein, “slurry” corresponds to a mixture of solids in a liquid, for example, particle-containing solids in a liquid. Slurries tend to be a thick fluid and can be pumped and the solid will settle as a result of gravity if left in an unagitated state.

For the purposes of the present disclosure, a “monorail” preferably includes at least one of layout flexibility, tracks, rails, slopes, switches turntables, interlocks, entry/exit sections, as well as curves. The monorail may be elevated and/or run at grade and can connect to other systems, such as conveyors, elevators, or cranes. The monorails can be arranged to move a “container” or a “containing means.” The monorail can also be arranged to move boards and/or components from one module to another.

As defined herein, a “container” or a “containing means” can include, but is not limited to, gaylords, drums, baskets, tanks, bags, barrels, boxes, hoppers, supersacks, bins, bottles, and cylinders.

As defined herein, “intelligent” refers to the control of one or more systems and/or processes of using said systems using one or more programmable logic controllers (PLC) that coordinate and regulate automated process steps in the systems. PLCs allow multiple different processing modules, and multiple different drums and tanks within each module, to operate simultaneously through the apparatus, providing maximum throughput per square foot of factory space. Multi-tasking capability includes, but is not limited to, scheduling software developed that provides the system the intelligence necessary to be able to concurrently process and sample multiple modules and multiple tanks within each module, recipe input and adaptation, materials handling, real-time monitoring, sensing, data acquisition and analysis, remote and/or wireless use and communication, and any combination thereof. The intelligent system(s) and/or process(es) can communicate with other system(s) and/or process(es) securely, using a network.

As defined herein, an “intelligent system” corresponds to a computer-based system that has the capacity to gather and analyze data and communicate with itself and/or other systems within the apparatus. For example, a module as described herein, can analyze data and communicate with itself and/or another module within the apparatus, thereby making adjustments to the process and/or recipe. In addition, an intelligent system is capable of shutting down a portion of, or the entire, system to ensure worker safety. Moreover, an intelligent system is capable of determining when maintenance to the hardware and/or software must occur.

As defined herein, a “loaded” removal composition corresponds to a removal composition that is substantially saturated with the metal ions or has otherwise reached a predetermined concentration or threshold of a constituent of a removal composition (e.g., a certain metal ion) or pH. Considered another way, the loaded removal composition can no longer substantially dissolve or solubilize the metal(s) it was intended to remove.

As defined herein, a “loaded” rinse liquid corresponds to a rinse liquid that no longer effectively rinses the solid or has otherwise reached a predetermined concentration or threshold of a chemical constituent (e.g., a certain metal ion) or pH.

As defined herein, a “recipe” corresponds to the parameters used and/or programmable and/or input and/or chosen and/or adjusted to ensure maximum process efficiency, maximum metal removal, and minimum waste production using at least one of the modules described herein. Parameters considered include, but are not limited to, ratio of solid to liquid during removal process, processing time, processing temperature, processing sequence, addition rates, the solids/components being processed, the amount of solids/components being processed, concentration of chemicals in the removal compositions, order of addition, the amount of effluent that must be disposed of properly, type of agitation means, speed of agitation, how many times the removal or rinse composition has been reused/recirculated, type of material being processed, concentration of metal ion constituents, current and voltage changes, and other prespecified thresholds.

As defined herein, “gold fingers” are gold-plated contact pins on PCBs used for edge-connector contacts.

As defined herein, “moving means” correspond to manual or mechanical systems for moving objects from one location to another location including one or more of a conveyor belt, a conveyor track, a conveying wheel, a conveying roller, gravity conveyor, robots, a robotic loading arm with a moving mechanism, Schmidt conveyors, overhead conveyors with powered channels/tracks, tracks, elevators, collection conveyors, monorails, belts, link chains, transporter with wheels, trucks, hand trucks, trays, fork lifts, boom lifts, scissor lifts, straddle lifts, cantilever lifts, post lifts, vertical lifts, horizontal lifts, trolleys, pallets, dollies, caddies, pulleys, clamps, hoists, hooks, forks, stackers, bucket elevators, carousels, cranes, guided vehicles, carts, pumps, slurry pumps, or combinations of the foregoing. For the purposes of this application, any conveying systems can include speed control and/or variable speed.

As used herein, a “platform” corresponds to two or more processes connected to one another by at least one common network that provides for information exchange between the two or more processes through the network and where the information exchange between the processes through the network increases yield or enhances performance of at least one of the two or more processes as compared to the yield and/or performance without the information exchange.

As defined herein, “agitation means” include, but are not limited to, top stirrers/mixers, bottom stirrers/mixers, side stirrers/mixers, screw agitators, rocking or rotating means, rotary mixers, sonication, ultrasonic energy, blenders, blades, dispersers, rotors, propellers, recirculators, baffles, impellers, internal fins or augers within containing means that result in agitation when rotated, and any combination thereof.

As defined herein, “liquid-solid separation means” include, but are not limited to, centrifugation (e.g., decanter, cone-shaped), decanting, filtering, drying, evaporation, osmosis, sedimentation, precipitation, filter presses, and combinations thereof.

As defined herein, “gold ions” are intended to cover Au (I) and Au (III), as well as gold-gold-containing ions comprising anions including, but not limited to, fluoride, chloride, bromide, iodide, nitrate, nitrite, sulfate, sulfite, cyanide, bisulfate, bisulfite, acetate, oxalate, chlorate, chlorite, hypochlorite, perchlorate, carbonate, bicarbonate, and phosphate.

As defined herein, “substantial completion” of the chemical reaction corresponds to the completion of at least about 90% of the chemical reaction, based on the limiting reagent present, preferably at least about 95%, and most preferably at least about 99%. A “complete reaction” corresponds to reaction of at least 99% of the limiting reagent, more preferably at least 99.5%.

As defined herein, a “chloride-containing salt” includes, but is not limited to, hydrochloric acid, and alkaline chlorides (e.g., sodium chloride, potassium chloride, rubidium chloride, cesium chloride, magnesium chloride, calcium chloride, strontium chloride, ammonium chloride, quaternary ammonium chloride salts), and combinations thereof.

As defined herein, “ventilation means” corresponds to forced air (mechanical) ventilation such as local exhaust ventilation (hoods, ductwork, air cleaning device, fans, exhaust stacks, scrubbers, and combinations thereof).

As defined herein, the “means to control air input into a furnace” corresponds to the use of ductwork and air pumps or pressure differentials to force atmospheric air or more oxygenated air into a furnace.

As defined herein, “loading means” include, but are not limited to chutes, conveyors, manually by hand, cranes, jacks, hoists, or any combination thereof. In addition, many of the moving means, as defined herein, can be loading means.

As defined herein, “air inputs” correspond to openings or holes that allow the user to introduce one or more gases, e.g., air, via a pipe or line into a tank, especially when the chemical reaction requires or otherwise is more efficient when carried out in the presence of one or more gases.

### Systems and Processes to Reclaim Precious Metals

In one aspect, an integrated, intelligent system and process for recycling material selected from the group consisting of PCBs, PCB components, materials comprising gold, and combinations thereof, is described, said system comprising a printed circuit board (PCB) platform and a solids processing technology (SPT) platform, wherein the system and process efficiently recovers more than about 80%, preferably more than about 90%, and most preferably more than about 95% of the gold contained in the PCBs, PCB components, materials comprising gold, and combinations thereof. In addition, the system and process efficiently recovers more than about 80%, preferably more than about 85%, and most preferably more than about 90% of the base metals contained in the PCBs, PCB components, materials comprising gold, and combinations thereof. Further, the system and process efficiently recovers more than about 70%, preferably more than about 75%, and most preferably more than about 80% of the silver contained in the PCBs, PCB components, materials comprising gold, and combinations thereof.

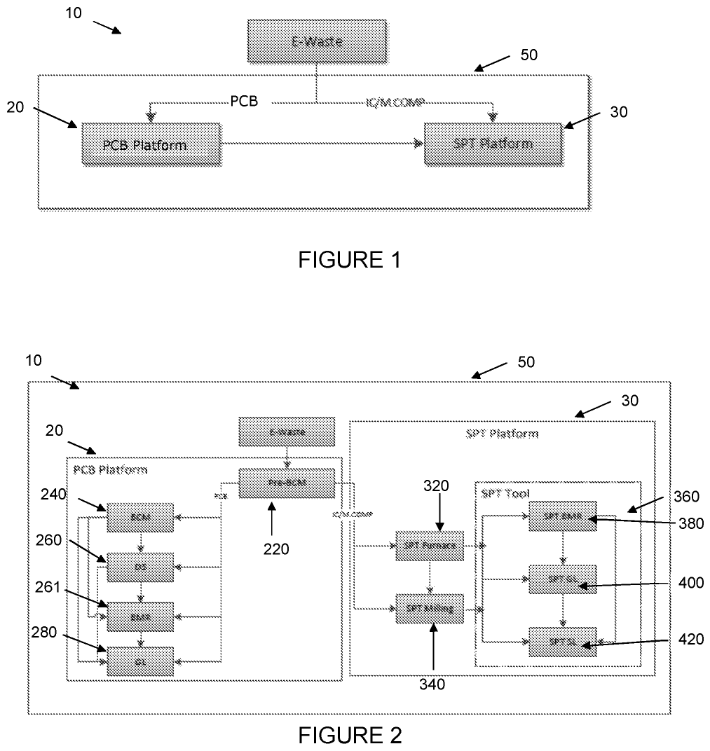

Referring to FIG. 1, it can be seen that the system (10) described herein may comprise a PCB platform (20) and a SPT platform (30), wherein the system is integrated and intelligent and capable of maximizing the efficiency of metals, e.g., gold, removal depending on the material being processed, e.g., PCB, PCB component, or material comprising gold. Put another way, the system ensures that the material, e.g., PCB, PCB component, or material comprising gold, is processed along the PCB platform (20), the SPT platform (30), or both, to ensure a minimization of resources (e.g., chemicals, energy, hardware, software, footprint of the facility, water), a minimization of waste, and a maximization of metal reclaimed. This is accomplished, in part, using at least one programmable logic controller, which can be controlled by a SCADA device (50). For the purposes of this disclosure, the PCB platform (20) may comprise one or more of a pre-board clearing module (pre-BCM) (220), a board clearing module (BCM) (240), a desoldering module (DS) (260), a base metal removal (BMR) module (261), and/or a gold leaching (GL) module (280) (see, e.g., FIG. 2). For the purposes of this disclosure, the SPT platform (30) may comprise one or more of a SPT furnace module (320), a SPT milling module (340), and/or a SPT tool module (360) (see, e.g., FIG. 2), wherein the SPT tool module (360) can comprise one or more of a SPT base metal removal module (380), a SPT gold removal module (400), and/or a SPT silver leaching module (420). It should be appreciated that depending on the module, the process can be either a wet process, a dry process, a chemical process, a physical process, an electrical process, a mechanical process, or some combination of more than one of the foregoing processes. For example, wet processing includes, but is not limited to, metal removal using chemicals and rinsing, while dry processing includes, but is not limited to, thermal processing (i.e., heating), mechanical processing, and burning. In one embodiment, each platform has at least one PLC controlling it. In another embodiment, at least PLC is used to control both the PCB platform (20) and the SPT platform (30). In yet another embodiment, each module has at least one PLC controlling it. In another embodiment, multiple modules have at least one PLC controlling them. When more than one PLC is present, a SCADA device (50) can be used to control the one or more PLCs. A SCADA device is a computer-based system that monitors and controls industrial, infrastructure and facility-based processes. A schematic is shown in FIGS. 1 and 2 wherein a SCADA control system (50) monitors the e-waste recycling and recovery system and process of using same.

In another aspect, an integrated, intelligent system for recycling material selected from the group consisting of PCBs, PCB components, materials comprising gold, and combinations thereof, is described, said system comprising a PCB platform (20) and an SPT platform (30), wherein the PCB platform (20) comprises at least one module selected from the group consisting of:

(a) a pre-board clearing module (220) (Sort),

(b) a board clearing module (240) (BCM),

(c) a desoldering module (260) (DS),

(d) a base metal removal module (261) (BMR)

(e) a precious metal leaching module (GL) (280)

(f) any combination of (a)-(e), and

(g) every module of (a)-(e),

wherein the modules are positioned and/or operated in series with one another, with or without intervening parts. Preferably, the system is designed such that the material to be recycled, whether batch or otherwise, moves within a module automatically or manually and/or can move from module to module, automatically or manually, using a moving means. The system may be controlled by one or more controlling device including, but not limited to, PLCs that coordinate and regulate one or more automated process steps in the apparatus.

In another aspect, an integrated, intelligent system for recycling material selected from the group consisting of PCBs, PCB components, materials comprising gold, and combinations thereof, is described, said system comprising a PCB platform (20) and an SPT platform (30), wherein the SPT platform (30) comprises at least one module selected from the group consisting of:

(a) a SPT furnace module (320),

(b) a SPT milling module (340),

(c) a SPT tool module (360),

(d) any combination of (a)-(c), and

(e) every module of (a)-(c),

wherein the modules are positioned and/or operated in series with one another, with or without intervening parts. The SPT tool module (360) can comprise at least one module selected from the group consisting of (i) a SPT base metal removal module (380), (ii) a SPT gold removal module (400), (iii) a SPT silver leaching module (420), (iv) any combination of (i)-(iii), and (v) the combination of each of (i)-(iii). Preferably, the system is designed such that the material to be recycled, whether batch or otherwise, moves within a module automatically or manually and/or can move from module to module, automatically or manually, using a moving means. The system may be controlled by one or more controlling device including, but not limited to, PLCs that coordinate and regulate one or more automated process steps in the apparatus.

In another aspect, an integrated, intelligent system for recycling PCB components is described, said system comprising a solids processing technology (SPT) furnace module (320) and optionally one or more modules selected from the group consisting of:

(a) a SPT milling module (340),

(b) a SPT base metal removal module (380),

(c) a SPT gold removal module (400),

(d) a SPT silver leaching module (420),

(e) any combination of (a)-(d), and

(f) every module of (a)-(d),

wherein the modules are positioned and/or operated in series with one another, with or without intervening parts. Preferably, the system is designed such that the material to be recycled, whether batch or otherwise, moves within a module automatically or manually and/or can move from module to module, automatically or manually, using a moving means. The system may be controlled by one or more controlling device including, but not limited to, PLCs that coordinate and regulate one or more automated process steps in the apparatus.

In still another aspect, an integrated, intelligent system for recycling PCB components is described, wherein the system efficiently recovers more than about 80%, preferably more than about 90%, and most preferably more than about 95% of the gold contained in the PCB components, said system comprising a SPT gold removal module (400), and at least one additional module selected from the group consisting of:

(a) a solids processing technology (SPT) furnace module (320),

(b) a SPT milling module (340),

(c) a SPT base metal removal module (380),

(d) a SPT silver leaching module (420),

(e) any combination of (a)-(d), and

(f) every module of (a)-(d),

wherein the modules are positioned and/or operated in series with one another, with or without intervening parts. Preferably, the system is designed such that the material to be recycled, whether batch or otherwise, moves within a module automatically or manually and/or can move from module to module, automatically or manually, using a moving means. The system may be controlled by one or more controlling device including, but not limited to, PLCs that coordinate and regulate one or more automated process steps in the apparatus.

In one aspect, an integrated, intelligent system for recycling material selected from the group consisting of PCBs, PCB components, materials comprising gold, and combinations thereof, is described, wherein the system efficiently recovers more than about 80%, preferably more than about 90%, and most preferably more than about 95% of the gold contained in the PCBs, PCB components and materials comprising gold, said system comprising a gold leaching module (280), and at least one additional module selected from the group consisting of:

(a) a pre-board clearing module (220),

(b) a board clearing module (240),

(c) a desoldering module (260),

(d) a base metal removal module (261),

(e) a solids processing technology (SPT) furnace module (320),

(f) a SPT milling module (340),

(g) a SPT tool module (360),

(h) any combination of (a)-(g), and

(i) every module of (a)-(g),

wherein the modules are positioned and/or operated in series with one another, with or without intervening parts. The SPT tool module (360) can comprise at least one module selected from the group consisting of (i) a SPT base metal removal module (380), (ii) a SPT gold removal module (400), (iii) a SPT silver leaching module (420), (iv) any combination of (i)-(iii), and (v) the combination of each of (i)-(iii). Preferably, the system is designed such that the material to be recycled, whether batch or otherwise, moves within a module automatically or manually and/or can move from module to module, automatically or manually, using a moving means. The system may be controlled by one or more controlling device including, but not limited to, PLCs that coordinate and regulate one or more automated process steps in the apparatus.

In another aspect, an integrated, intelligent system for recycling material selected from the group consisting of PCBs, PCB components, materials comprising gold, and combinations thereof, is described, said system comprising an SPT tool module (360), and at least one additional module selected from the group consisting of:

(a) a pre-board clearing module (220),

(b) a board clearing module (240),

(c) a desoldering module (260),

(d) a base metal removal module (261),

(e) a gold leaching module (280),

(f) a SPT furnace module (320),

(g) a SPT milling module (340),

(h) any combination of (a)-(g), and

(i) every module of (a)-(g),

wherein the modules are positioned and/or operated in series with one another, with or without intervening parts. The SPT tool module (360) can comprise at least one module selected from the group consisting of (i) a SPT base metal removal module (380), (ii) a SPT gold removal module (400), (iii) a SPT silver leaching module (420), (iv) any combination of (i)-(iii), and (v) the combination of each of (i)-(iii). Preferably, the system is designed such that the material to be recycled, whether batch or otherwise, moves within a module automatically or manually and/or can move from module to module, automatically or manually, using a moving means. The system may be controlled by one or more controlling device including, but not limited to, PLCs that coordinate and regulate one or more automated process steps in the apparatus.

In another aspect, an integrated, intelligent system for recycling material selected from the group consisting of PCBs, PCB components, materials comprising gold, and combinations thereof, is described, said system comprising a combination of modules selected from the group consisting of:
(a) a pre-board clearing module (220) and a gold leaching module (280),
(b) a board clearing module (240) and a gold leaching module (280),
(c) a pre-board clearing module (220), a board clearing module (240), and a gold leaching module (280),
(d) a pre-board clearing module (220), a desoldering module (260), and a gold leaching module (280),
(e) a board clearing module (240), a desoldering module (260), and a gold leaching module (280),
(f) a pre-board clearing module (220), a board clearing module (240), a desoldering module (260), and a gold leaching module (280),
(g) a pre-board clearing module (220), a desoldering module (260), and an SPT tool module (360),
(h) a board clearing module (240), a desoldering module (260), and an SPT tool module (360),
(i) a pre-board clearing module (220), a board clearing module (240), a desoldering module (260), and an SPT tool module (360),
(j) a SPT furnace module (320), a SPT milling module (340), and a SPT tool module (360),
(k) a desoldering module (260), a SPT furnace module (320), a SPT milling module (340), and an SPT tool module (360),
(l) a SPT furnace module (320) and an SPT tool module (360),
(m) a SPT milling module (340) and an SPT tool module (360),
(n) a desoldering module (260), a SPT furnace module (320), and an SPT tool module (360),
(o) a desoldering module (260), a SPT milling module (340), and an SPT tool module (360),
(p) a board clearing module (240), a desoldering module (260), a SPT furnace module (320), a SPT milling module (340), and an SPT tool module (360),
(q) a board clearing module (240), a desoldering module (260), a SPT furnace module (320), and an SPT tool module (360),
(r) a board clearing module (240), a desoldering module (260), a SPT milling module (340), and an SPT tool module (360),
(s) a pre-board clearing module (220), a board clearing module (240), a desoldering module (260), a SPT furnace module (320), a SPT milling module (340), and an SPT tool module (360),
(t) a pre-board clearing module (220), a board clearing module (240), a desoldering module (260), a SPT furnace module (320), and an SPT tool module (360),
(u) a pre-board clearing module (220), a board clearing module (240), a desoldering module (260), a SPT milling module (340), and an SPT tool module (360),
(v) a pre-board clearing module (220), a board clearing module (240), a desoldering module (260), a gold leaching module (280), a SPT furnace module (320), a SPT milling module (340), and an SPT tool module (360),
(w) a gold leaching module (280) and a SPT gold removal module (400),
   wherein the modules are positioned and/or operated in series with one another, with or without intervening parts. Any of embodiments (a)-(v) can further comprise at least one base metal removal module. Preferably, the system is designed such that the material to be recycled, whether batch or otherwise, moves within a module automatically or manually and/or can move from module to module, automatically or manually, using a moving means. The system may be controlled by one or more controlling device including, but not limited to, PLCs that coordinate and regulate one or more automated process steps in the apparatus. The SPT tool module (360) can comprise at least one module selected from the group consisting of (i) a SPT base metal removal module (380), (ii) a SPT gold removal module (400), (iii) a SPT silver leaching module (420), (iv) any combination of (i)-(iii), and (v) the combination of each of (i)-(iii). Preferably, the SPT tool module (360) comprises at least (i) the SPT gold removal module (400).

In another aspect, a process of recycling material selected from the group consisting of PCBs, PCB components, materials comprising gold, and combinations thereof, is described, wherein the process efficiently recovers more than about 80%, preferably more than about 90%, and most preferably more than about 95% of the gold contained in the PCBs, PCB components and materials comprising gold. The process comprises leaching gold from materials having gold using a gold leaching composition in a gold leaching module (280), and optionally at least one additional step selected from the group consisting of:
(a) sorting PCBs in a pre-board clearing module (220), wherein the PCBs are sorted manually and/or automatically,
(b) removing PCB components in a pre-board clearing module (220), wherein the PCB components are removed manually and/or automatically,
(c) removing materials comprising gold from PCBs in a pre-board clearing module (220), wherein the PCBs are sorted and the PCB components and materials comprising gold are removed manually and/or automatically,
(d) removing PCB components and/or materials comprising gold from PCBs using heat and mechanical means in a Board clearing module (240),
(e) removing solder, PCB components, and/or materials comprising gold from PCBs using a solder removal composition in a desoldering module (260),
(f) removing base metals from PCBs, PCB components, and/or materials comprising gold using a base metal removal composition in a base metal removal module (261),
(g) ashing PCB components and/or materials comprising gold in a solids processing technology (SPT) furnace module to yield a solid comprising ash,
(h) grinding PCB components and/or materials comprising gold in an SPT milling module (340) to yield a solid comprising ground materials,
(i) removing precious metals from (i) ash from (g), (ii) ground materials from (h) and/or (iii) unshed or unground PCBs, PCB components, materials comprising gold in an SPT tool module (360),
(j) any combination of (a)-(i), and
(k) every process of (a)-(i),
   wherein the processes are operated in series with one another, with or without intervening processes. Processing using the SPT tool module (360) can comprise at least one process selected from the group consisting of (i) removing at least one base metal using a base metal removal composition in a SPT base metal removal module (380), (ii) removing gold using a gold removal composition in a SPT gold removal module (400), (iii) removing silver using a silver removal composition in a SPT silver leaching module (420), (iv) any combination of (i)-(iii), and (v) the combination of each of (i)-(iii). Preferably, the process includes moving material within a module automatically or manually, and/or moving material from module to module, automatically or manually, using a moving means. The system may be controlled by one or more controlling device including, but not limited to, PLCs that coordinate and regulate one or more automated process steps in the apparatus.

In another aspect, a process of recycling material selected from the group consisting of PCBs, PCB components, materials comprising gold, and combinations thereof, is described. The process comprises removing precious metals from materials comprising gold that have been ashed, ground, and/or crushed in an SPT tool module (360), and optionally at least one additional step selected from the group consisting of:
(a) sorting PCBs in a pre-board clearing module (220), wherein the PCBs are sorted manually and/or automatically,
(b) removing PCB components in a pre-board clearing module (220), wherein the PCB components are removed manually and/or automatically,
(c) removing materials comprising gold from PCBs in a pre-board clearing module (220), wherein the PCBs are sorted and the PCB components and materials comprising gold are removed manually and/or automatically,
(d) removing PCB components and/or materials comprising gold from PCBs using heat and mechanical means in a Board clearing module (240),
(e) removing solder, PCB components, and/or materials comprising gold from PCBs using a solder removal composition in a desoldering module (260),
(f) removing base metals from PCBs, PCB components, and/or materials comprising gold using a base metal removal composition in a base metal removal module (261),
(g) leaching gold from materials comprising gold using a gold leaching composition in a gold leaching module (280),
(h) ashing PCB components and/or materials comprising gold in a solids processing technology (SPT) furnace module to yield a solid comprising ash,
(i) grinding PCB components and/or materials comprising gold in an SPT milling module (340) to yield a solid comprising ground materials,
(j) any combination of (a)-(i), and
(k) every process of (a)-(i),
   wherein the processes are operated in series with one another, with or without intervening processes. Processing using the SPT tool module (360) can comprise at least one process selected from the group consisting of (i) removing at least one base metal using a base metal removal composition in a SPT base metal removal module (380), (ii) removing gold using a gold removal composition in a SPT gold removal module (400), (iii) removing silver using a silver removal composition in a SPT silver leaching module (420), (iv) any combination of (i)-(iii), and (v) the combination of each of (i)-(iii). Preferably, the process includes moving material within a module automatically or manually, and/or moving material from module to module, automatically or manually, using a moving means. The system may be controlled by one or more controlling device including, but not limited to, PLCs that coordinate and regulate one or more automated-process steps in the apparatus.

In another aspect, an integrated, intelligent system for recycling material selected from the group consisting of PCBs, PCB components, materials comprising gold, and combinations thereof, is described, wherein the system efficiently recovers more than about 80%, preferably more than about 90%, and most preferably more than about 95% of the gold contained in the PCBs, PCB components and materials comprising gold, wherein the system comprises a SPT base metal removal module (380) and a SPT gold removal module (400), and optionally at least one additional module selected from the group consisting of:

(a) a SPT furnace module (320),

(b) a SPT milling module (340),

(c) a SPT silver leaching module (420),

(d) any combination of (a)-(c), and

(e) every module of (a)-(c),

wherein the modules are positioned and/or operated in series with one another, with or without intervening parts. Preferably, the system is designed such that the material to be recycled, whether batch or otherwise, moves within a module automatically or manually and/or can move from module to module, automatically or manually, using a moving means. The system may be controlled by one or more controlling device including, but not limited to, PLCs that coordinate and regulate one or more automated process steps in the apparatus.

In another aspect, a process of recycling material selected from the group consisting of PCBs, PCB components, materials comprising gold, and combinations thereof, is described, wherein the process efficiently recovers more than about 80%, preferably more than about 90%, and most preferably more than about 95% of the gold contained in the PCBs, PCB components and materials comprising gold. The process comprises removing at least one base metal from a solid using a base metal removal composition in a SPT base metal removal module (380) and removing gold from a solid using a gold removal composition in a SPT gold removal module (400), wherein the solid comprises materials comprising gold that have been ashed, ground, and/or crushed, and optionally at least one additional step selected from the group consisting of:
(a) ashing PCB components and materials comprising gold in a solids processing technology (SPT) furnace module to yield a solid comprising ash,
(b) grinding PCB components and materials comprising gold in an SPT milling module (340) to yield a solid comprising ground materials,
(c) removing silver from the solid using a silver removal composition in a SPT silver leaching module (420),
(d) any combination of (a)-(c), and
(e) every process of (a)-(g),
   wherein the processes are operated in series with one another, with or without intervening processes. Preferably, the process includes moving material within a module automatically or manually, and/or moving material from module to module, automatically or manually, using a moving means. The system may be controlled by one or more controlling device including, but not limited to, PLCs that coordinate and regulate one or more automated process steps in the apparatus.

In still another aspect, an integrated, intelligent system for recycling material selected from the group consisting of PCBs, PCB components, materials comprising gold, and combinations thereof, is described, wherein the system comprises a SPT furnace module (320).

In still another aspect, an integrated, intelligent system for recycling material selected from the group consisting of PCBs, PCB components, materials comprising gold, and combinations thereof, is described, wherein the system comprises a SPT furnace module (320) and a SPT gold removal module (400), and optionally at least one additional module selected from the group consisting of:

(a) a SPT milling module (340),

(b) a SPT base metal removal module (380)

(c) a SPT silver leaching module (420),

(d) any combination of (a)-(c), and

(e) every module of (a)-(c),

wherein the modules are positioned and/or operated in series with one another, with or without intervening parts. Preferably, the system is designed such that the material to be recycled, whether batch or otherwise, moves within a module automatically or manually and/or can move from module to module, automatically or manually, using a moving means. The system may be controlled by one or more controlling device including, but not limited to, PLCs that coordinate and regulate one or more automated process steps in the apparatus.

In another aspect, a process of recycling material selected from the group consisting of PCBs, PCB components, materials comprising gold, and combinations thereof, is described. The process comprises ashing PCB components and materials comprising gold in a solids processing technology (SPT) furnace module to yield a solid comprising ask

In another aspect, a process of recycling material selected from the group consisting of PCBs, PCB components, materials comprising gold, and combinations thereof, is described, wherein the process efficiently recovers more than about 80%, preferably more than about 90%, and most preferably more than about 95% of the gold contained in the PCBs, PCB components and materials comprising gold. The process comprises ashing PCB components and materials comprising gold in a solids processing technology (SPT) furnace module to yield a solid comprising ash, and removing gold from the solid using a gold removal composition in a SPT gold removal module (400), and optionally at least one additional step selected from the group consisting of:
(a) grinding PCB components and materials comprising gold in an SPT milling module (340) to yield a solid comprising ground materials,
(b) removing at least one base metal from a solid using a base metal removal composition in a SPT base metal removal module (380)
(c) removing silver from the solid using a silver removal composition in a SPT silver leaching module (420),
(d) any combination of (a)-(c), and
(e) every process of (a)-(c),
   wherein the processes are operated in series with one another, with or without intervening processes. Preferably, the process includes moving material within a module automatically or manually, and/or moving material from module to module, automatically or manually, using a moving means. The system may be controlled by one or more controlling device including, but not limited to, PLCs that coordinate and regulate one or more automated process steps in the apparatus.

In yet another aspect, an integrated, intelligent system for recycling material selected from the group consisting of PCBs, PCB components, materials comprising gold, and combinations thereof, is described, wherein the system efficiently recovers more than about 80%, preferably more than about 90%, and most preferably more than about 95% of the gold contained in the PCBs, PCB components and materials comprising gold, said system comprising a gold leaching module (280) and a SPT gold removal module (400), and optionally at least one additional module selected from the group consisting of:

(a) a pre-board clearing module (220),

(b) a board clearing module (240),

(c) a desoldering module (260),

(d) a base metal removal module (261),

(e) a SPT furnace module (320),

(f) a SPT milling module (340),

(g) a SPT base metal removal module (380),

(h) a SPT silver leaching module (420),

(i) any combination of (a)-(h), and

(j) every module of (a)-(h),

wherein the modules are positioned and/or operated in series with one another, with or without intervening parts. Preferably, the system is designed such that the material to be recycled, whether batch or otherwise, moves within a module automatically or manually and/or can move from module to module, automatically or manually, using a moving means. The system may be controlled by one or more controlling device including, but not limited to, PLCs that coordinate and regulate one or more automated process steps in the apparatus.

In another aspect, a process of recycling material selected from the group consisting of PCBs, PCB components, materials comprising gold, and combinations thereof, is described, wherein the process efficiently recovers more than about 80%, preferably more than about 90%, and most preferably more than about 95% of the gold contained in the PCBs, PCB components and materials comprising gold. The process comprises leaching gold from materials comprising gold using a gold leaching composition in a gold leaching module (280) and removing gold from a solid using a gold removal composition in a SPT gold removal module (400), wherein the solid comprises materials comprising gold that have been ached, ground, and/or crushed, and optionally at least one additional step selected from the group consisting of:
(a) sorting PCBs in a pre-board clearing module (220), wherein the PCBs are sorted manually and/or automatically,
(b) removing PCB components in a pre-board clearing module (220), wherein the PCB components are removed manually and/or automatically,
(c) removing materials comprising gold from PCBs in a pre-board clearing module (220), wherein the PCBs are sorted and the PCB components and materials comprising gold are removed manually and/or automatically,
(d) removing PCB components and/or materials comprising gold from PCBs using heat and mechanical means in a Board clearing module (240),
(e) removing solder, PCB components, and/or materials comprising gold from PCBs using a solder removal composition in a desoldering module (260),
(f) removing base metals from PCBs, PCB components, and/or materials comprising gold using a base metal removal composition in a base metal removal module (261),
(g) ashing PCB components and/or materials comprising gold in a solids processing technology (SPT) furnace module to yield a solid comprising ash,
(h) grinding PCB components and/or materials comprising gold in an SPT milling module (340) to yield a solid comprising ground materials,
(i) removing at least one base metal from the solid using a base metal removal composition in a SPT base metal removal module (380),
(j) removing silver from the solid using a silver removal composition in a SPT silver leaching module (420),
(k) any combination of (a)-(j), and
(l) every process of (a)-(j),
   wherein the processes are operated in series with one another, with or without intervening processes. Preferably, the process includes moving material within a module automatically or manually, and/or moving material from module to module, automatically or manually, using a moving means. The system may be controlled by one or more controlling device including, but not limited to, PLCs that coordinate and regulate one or more automated process steps in the apparatus.

The apparatuses and processes described herein preferably optimize energy utilization. For example, the apparatuses and processes may rely on a closed loop energy system to transfer energy from energy generators including, but not limited to, heat in exhaust, heat of dilution, exothermic chemical reactions, that can be captured in heat exchangers) to energy users including, but not limited to, heating compositions, heating solder, ashing materials, maintaining temperatures during endothermic processes).

The integrated, intelligent systems and processes can operate continuously (in batch or otherwise) twenty four hours a day, seven days a week, and process from 80 to 3000 metric tons of electronic waste a year with gold recovery efficiencies on the order of 85% to greater than 99%.

The systems described herein comprising one or more modules can include “kill switch” capabilities, wherein an Ethernet-based control system such as SCADA can shut down a module or a component within a module in the event that workers or the environment are at risk including, but not limited to, exposure to toxic fumes, out of control chemical reactions, computer or component malfunctions in the module.

The at least one PLC and the SCADA, when present, can be used for at least one of the following: data processing; managing and controlling module(s); storing of recipes; blending chemistries; separating materials; data archiving and reporting; controlling computer networks and systems; safety, efficiency, economic, and ecological operations; maintenance; leak detection and containment location and special requirements necessary; sampling and monitoring of a variable; and/or printing production reports.

### Real-Time Monitoring

To achieve the high metal removal and recovery efficiency described herein, the process(es), module(s), hardware in the module, evolved gas, boards, components, solids, removal composition, raw materials for removal composition, process composition and rinse liquid, process rinse liquid may be monitored in real-time and the data acquired sent to at least one PLC for analysis and further action as needed. The real-time monitoring can occur in any container in any module, within any of the lines, during any point in a process. For example, chemical reactions wherein a removal composition is used to remove at least one metal from boards, components, and/or a solid can be monitored whereby real-time sampling occurs and a concentration of one or more components determined. This allows the computer to make adjustments so that the removal composition remains at a steady concentration over time. Alternatively, once a certain concentration is achieved, the chemical reaction may be complete and/or the removal composition may be loaded and/or an endpoint may be reached. Similarly, real-time sampling of rinse liquids can occur, allowing the computer to determine the status of the rinse liquid. Often the pH of a removal composition or a rinse liquid must be adjusted and real-time sampling permits this action. The solids can be sampled in real-time as well. Real-time sampling also ensures that workers and the environment are not at risk by engaging the “kill switch” if some prespecified threshold is achieved. These are just a few examples of the advantages of real-time monitoring and sampling.

Real-time monitoring can include, but is not limited to: temperature; pressure; liquid and/or gas leak detection; and the monitoring of chemical constituents and/or pH values and/or oxidation reduction potentials and/or end points and/or conductivity in solids and/or liquids during mixing, storage, blending, agitation, reactions, recovery, reuse, feed and bleed, neutralization, buffering, diluting, pH adjustment, loading, NOx suppression, filtration, separation, centrifugation, precipitation, diffusion dialysis, resin-based acid recycle and metals recovery, electrowinning, wastewater treatment, and/or regeneration. The chemical constituents monitored can be raw chemical constituents or compositions comprising at least one chemical constituent. The real-time monitoring can occur in any container in any module, within any of the lines, during any point in a process. Process hardware can be monitored in real-time as well. Any of the gases evolved from any of the modules can be monitored in real-time. Real-time monitoring and analysis can be in-line, direct, indirect, continuous, scheduled and/or require sample preparation. The sampling can be manual or automatic. The analytical analysis to determine concentration can be manual or automatic. Concentrations can be determined using any “analytical techniques” or “sensing means” known in the art including, but not limited to, pH measurement, atomic absorption spectroscopy, atomic emission spectroscopy, inductively coupled plasma spectroscopy, inductively coupled plasma optical emission spectroscopy, UV-Vis spectrophotometry, UV spectrophotometry, titrations, infrared spectroscopy, temperature-controlled infrared spectroscopy, colorimetry, liquid chromatography, high performance liquid chromatography, refractive index sensor, optical sensors, chemical sensors, electrochemical techniques (e.g., pulsed cyclic galvanostatic analysis, multi-variate analysis, galvanostatic, potentiodynamic), cyclic voltammetry, linear polarization, radio frequency identification, and any other technique known by the skilled artisan to measure chemical concentrations.

Every module described hereinbelow preferably is monitored in real-time.

### Pre-BCM Processing

Printed circuit boards that require recycling and reclamation may include components and miscellaneous parts that should be removed from the PCB prior to further processing to enable processing of the PCBs and PCB components separately so as to increase the efficiency of the overall recycling and reclamation process. Further, by removing some of the PCB components and miscellaneous parts, the impact on the environment is lessened by reducing the volume of chemicals used, the waste stream as well as the operational (i.e., utility) and equipment (i.e., exchanger, scrubber, and wastewater treatment) costs. Moreover, some PCB components and miscellaneous parts will poison removal compositions and as such, must be removed from the PCBs prior to further processing. It should be understood by the person skilled in the art that the PCB components and other miscellaneous parts can be removed manually and/or automatically.

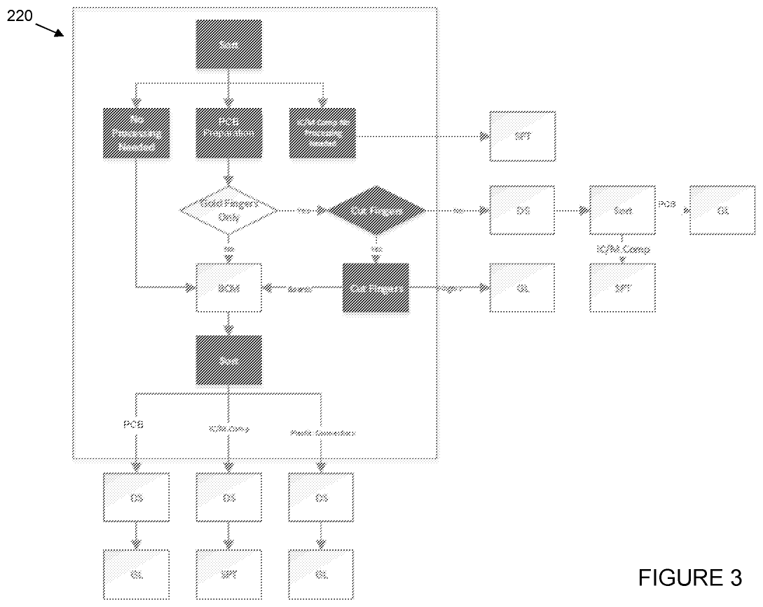

A schematic of the generalized pre-BCM process (220) is shown in FIG. 3. The PCB's can be sorted, manually or automatically, according to type, size, weight, e.g., motherboards, noteboards, TV boards, server boards, hard drive boards, SCSI cards, memory boards, and smartphones, into batches, because each type of PCB contains different components and different metal content and as such, may need to be processed differently for maximum efficiency. Automatic sorting means include means to detect the metals in the PCB and PCB components including, but not limited to, x-ray detection, vacuum technology, and creating magnetic eddy currents. Any PCBs that have no precious metal are scrapped. Following sorting, certain miscellaneous parts that are of no value, e.g., large plastic and metal parts (i.e., iron parts), should be removed (“PCB Preparation”). These miscellaneous parts may be removed manually or automatically or by a combination of both. Many of these miscellaneous parts are screwed or bolted to the boards and as such, require the use of screwdrivers to remove same. Alternatively, heat guns or grinders may be necessary to remove these large plastic and metal miscellaneous parts because they are adhered to the board. Stickers can be removed using razor knifes and tweezers. Chips, micro-components, connectors that contain gold, and/or gold fingers that can be easily removed from the board, e.g., using heat guns, tweezers, cutting means, and/or pliers, should be removed and sorted. For example, gold fingers can be removed by cutting means including, but not limited to, shearing, sawing, plasma cutting, water-jet cutting, oxyacetylene cutting, laser cutting, and electrical discharge machining. PCBs having visible surface dirt or dust are preferably washed, for example in dip tanks, conveyor spray systems, or the equivalent thereof, and dried prior to further processing. Safe ventilation, e.g., hood with scrubber, is recommended.

Subsequent to separation, for maximum efficiency, the PCBs and any recyclable PCB components that have been removed therefrom can be sorted into batches for further processing. For example, the PCBs may still have recyclable PCB components, e.g., surface mounted chips and micro-components, which can be sent to a BCM and/or a desoldering (DS) module, which comprise means of removing the rest of the PCB components, recyclable and otherwise, and solder from the PCBs and PCB components. Gold fingers and gold-containing connectors that have been removed can be sent to the desoldering (DS) module and/or gold leaching (GL) module, wherein the GL module comprises means of recovering gold from said fingers and connectors. Any recyclable PCB components that have been or will be separated from a PCB, e.g., IC chips and microcomponents, can be collected manually or automatically and can be sent to a solids processing technology (SPT) furnace module, SPT milling module (340), and/or SPT tool module (360), wherein the SPT furnace module (320) comprises a furnace to ash the components, the SPT milling module (340) includes a grinding or milling means, and the SPT tool module (360) comprises a series of individual modules for removing base metals and precious metals from the ashed and ground/milled components. To monitor metal removal efficiency, the PCBs and any recyclable PCB components are preferably weighed upon entrance into the pre-BCM and upon exit from the pre-BCM in the respective batches.

In one aspect, a process of preparing printed circuit boards for metal reclamation and recovery is described, said process comprising:
(a) sorting PCBs and PCB components into batches based on one or more of: PCBs that have no precious metal value (batch 1); PCBs that can be sent directly to a board clearing module (240) (BCM) to remove PCB components therefrom (batch 2); PCBs that require processing prior to BCM (batch 3), chips and micro-components (batch 4), and PCBs and PCB components that can be sent directly to a desoldering module (batch 5);
(b) removing miscellaneous parts and PCB components from the PCBs of batch 3, wherein the miscellaneous parts and PCB components are sorted into any one of batch 1, 4, or 5; and
(c) optionally, removing gold fingers from the PCBs of batch 3, wherein batch 4 can be further processed in a solid processing technology platform, the gold fingers can be further processed in a desoldering module (260) or a gold leaching module (280), the PCBs of batch 1 are disposed of, the PCBs in batch 2 are further processed in the BCM to remove PCB components from the PCBs, and the PCBs of batch 3 remaining following steps (b) and (c) are further processed in the BCM to remove PCB components from the PCBs.

### The BCM

Following the initial manual and/or automatic separation of easy to remove PCB components and miscellaneous parts, the PCBs will likely still have PCB components, recyclable and otherwise, attached to the PCB by a bonding agent, e.g., solder, adhesives, glues and/or epoxy. One way to remove the PCB components from the PCBs is to use a solder removal composition, however, in order to maximize the efficiency of the solder removal composition, preferably the PCB components are substantially removed by heating, mechanical and/or physical means, hereinafter referred to as a board clearing module (240) (BCM). “Substantial removal of the PCB components” by heating, mechanical and/or physical means corresponds to the removal of at least 85% of the PCB components and miscellaneous parts, preferably at least 90%.

PCB components are typically attached to the surface of PCBs with solder. Electronics solder generally is one of three types, a lead alloy solder, a lead-free solder or a silver alloy solder. Lead alloy solder is solder that is made from an alloy of tin and lead, sometimes with other metals as well. Lead alloy solder is often referenced by its alloy ratio such as 60/40 or 63/37 (w/w Sn/Pb). Lead alloy solder has been the standard solder used in electronics for decades, but the health issues associated with lead to move away from lead based solders. One of the most popular lead-free alloys is a Field Code Chan 96.5/3/0.5 alloy with 96.5% tin, 3% silver, and 0.5% copper. Silver alloy solder can be either lead-free or combined with lead, for example, 62/36/2 alloy solder with 2% silver, 62% tin, and 36% lead. Currently, PCB component removal involves heating the solder to melting temperature, whereby the liberated components separate from the PCB and the liquid solder is collected. This method applied for recycling PCBs has many disadvantages including, but not limited to, lead and tin are low-volatile metals and such heating and melting will create a high level of polluting emissions to the ambient air and liquid solder is not convenient to collect.

The BCM described herein includes “heating means,” include, but are not limited to, batch ovens or the equivalent thereof that utilize infrared heat, resistance heating coils, heat transfer fluid, fluid/vapor heat exchangers, which can be used to heat the PCB, and hence the solder, to a temperature where the solder is softened, thereby enabling the mechanical removal of the PCB components from the PCB using mechanical and/or physical means. In a particularly preferred embodiment, the PCBs are maintained at least 1° C. to about 30° C. below the melting point of the particular solder, epoxy, glue, and/or other adhesive means. The BCM includes moving means, as described herein, to move the PCBs and PCB components through the BCM. The mechanical and/or physical means are capable of ensuring that substantial removal of the PCB components from the PCBs occurs and can be collected for further processing. Mechanical and/or physical means contemplated include, but are not limited to, cutting blades, abrasive materials (e.g., bonded materials comprising aluminum oxide, silicon carbide, tungsten carbide, or garnet, or coated materials such as sandpaper), grinders, tumblers, heated air knifes, vibration forces, brushes, rakes or scrapers, augers (with speed control and/or variable speeds), high pressure gases, high pressure liquids, heat transfer fluids, supercritical fluids, hammers, hands, or any other means whereby the PCB components are mechanically and/or physically removed from the PCBs once the solder, epoxy, glue and/or other adhesive means are softened. It should be appreciated that although gravity is not a mechanical means, it is possible for the components to fall off the PCBs as a result of gravity. The BCM module (240) shall have appropriate venting and scrubbing because of the risk of polluting emissions. Preferably, the BCM module (240) further comprises containing means so that the PCB components and PCBs can be collected following passage through the heating, mechanical and/or physical means.

An example of a known BCM is described in International Patent Application No. PCT/US2012/069404 filed on Apr. 15, 2011 in the name of Tianniu CHEN et al. and entitled “Apparatus and Method for Stripping Solder Metals During the Recycling of Waste Electrical and Electronic Equipment,” which is hereby incorporated by reference herein in its entirety. Another example of a known BCM is described in U.S. patent application Ser. No. 14/273,797 filed on May 9, 2014 in the name of Cheng-yang Hsieh and entitled “Electronic Component Removal Apparatus for a Circuit Board,” which is hereby incorporated by reference herein in its entirety.

Another example of a known BCM is described in U.S. Pat. No. 7,703,197 issued on Apr. 27, 2010 in the name of James R. Moltion and entitled “Process for Depopulating a Circuit Board,” which is hereby incorporated by reference herein in its entirety. The U.S. Pat. No. 7,703,197 patent relates to an apparatus for removing an item soldered to a PCB. The apparatus comprises a transport mechanism configured to carry a PCB from a PCB entry port of the apparatus to a PCB exit port of the apparatus; a speed control coupled to the transport mechanism to control a travel speed of the PCB; a heat source configured to heat solder at a higher heating rate than the rate of heating applied to a board component of the PCB; a heat source control coupled to the heat source to control a rate of heating of solder; a vibrator configured to apply mechanical forces to the PCB situated between the PCB entry port of the apparatus and the PCB exit port of the apparatus; a vibrator control to control an amplitude of the mechanical forces applied to the PCB; and an inclined surface configured to catch at least one item that becomes disconnected from the PCB and to transport to a first collection location the disconnected item under the influence of gravity.

PCBs that are to be processed in the BCM are transported to the BCM by moving means. The moving means may be controlled by a PLC. In one embodiment, a batch of PCBs is transported automatically to the BCM for processing. The batch can comprise a series of PCBs conveyed to the BCM individually or together, e.g., in a container. The PCBs may be loaded into the BCM manually or automatically, individually or in batches by loading means, e.g., a chute or hopper, or loading onto a conveyor or other moving means.

Subsequent to passage through the BCM, the PCBs and PCB components can be sorted again, manually or automatically, and sent to one or more modules described herein. For example, PCBs containing gold, PCBs with PCB components still attached, ICs and microcomponents, and plastic connectors may be sent to the DS module (260) to remove solder and/or the remaining PCB components. PCBs containing no precious metals can be removed from further processing. PCBs containing gold, PCBs with PCB components still attached, ICs and microcomponents, and plastic connectors can be sorted by size and separated into batches to maximize efficiency during further processing. In one embodiment, sorting and/or separation can occur manually or automatically, using vibration means, agitation means, stirring, mixing, trommels, roll sorters, or any other sorting means that sorts the PCBs containing gold, PCBs with PCB components still attached, ICs and microcomponents, and plastic connectors by type and/or size and conveys species of similar size to a container and/or moving means. “Vibration means” include, but are not limited to, vibrating screens and vibrating sieves. In one embodiment, the container comprising species is weighed and when the container reaches a predetermined weight, the container is manually or automatically conveyed to the DS module (260) using a moving means.

It should be appreciated that PCBs that are to be recycled and reclaimed can be introduced directly to a BCM without the initial removal of miscellaneous parts, however, stickers on the PCBs will possibly jam the mechanical means and/or burn. Further, miscellaneous parts that are screwed to the PCBs will still have to be removed somehow. In addition, depending on the type of PCB or where it was manufactured, different kinds of solder may be used which may require different processing conditions, e.g., a different softening temperature.

To monitor metal removal efficiency, the PCBs and any recyclable PCB components are preferably weighed upon entrance into the BCM and/or upon exit from the BCM in the respective batches. Further, the BCM is preferably monitored in real-time, for example, to ensure that the temperature of the process does not exceed a prescribed threshold based on the batch of PCBs being processed. Further, evolved gases should be monitored to ensure worker and environmental safety. Additional real-time monitoring of the BCM module (240) is contemplated, including, but not limited to, the monitoring of hardware and software.

In one aspect, a Board clearing module (240) (BCM) to remove components from PCBs is described, said BCM comprising:
(a) heating means, wherein the temperature is raised to soften solder, epoxy, glue, and/or other adhesives used to connect a PCB component to a PCB;
(b) mechanical means to remove the PCB component from the PCB, wherein the mechanical means are selected from the group consisting of cutting blades, abrasive materials, grinders, tumblers, heated air knifes, vibration forces, brushes, rakes, scrapers, augers, high pressure gases, high pressure liquids, heat transfer fluids, hammers, and any combination thereof.
   The temperature within the heating means is preferably about 1° to 30° C. below the melting temperature of the solder, epoxy, glue, and/or other adhesives. Once the solder is softened, the mechanical means can remove the PCB component from the PCB. The BCM module (240) can further comprise at least one of: containing means to collect the PCBs and PCB components following removal of the PCB components from the PCB, for further processing; moving means for moving the PCBs and PCB components through the BCM module (240); loading means for introducing the PCBs into the heating and/or mechanical means; sorting means for sorting PCBs and PCB components into batch(s); and any combination thereof.

In another aspect, a process of removing components from PCBs in a board clearing module (240) (BCM) is described, said process comprising:
(a) heating a bonding agent that connects the components to the PCB, wherein the bonding agent is softened by heating to a temperature below the melting temperature of the bonding agent;
(b) removing the components from the PCB once the bonding agent is softened using mechanical means, wherein the mechanical means are selected from the group consisting of cutting blades, abrasive materials, grinders, tumblers, heated air knifes, vibration forces, brushes, rakes, scrapers, augers, high pressure gases, high pressure liquids, heat transfer fluids, hammers, and any combination thereof.
   The bonding agents can comprise any one of solder, adhesives, glues and/or epoxy. The temperature that the bonding agent is heated to is preferably about 1° to 30° C. below the melting temperature of the bonding agent. The mechanical means can be selected from the group consisting of cutting blades, abrasive materials, grinders, tumblers, heated air knifes, vibration forces, brushes, rakes, scrapers, augers, high pressure gases, high pressure liquids, heat transfer fluids, hammers, and any combination thereof. The process of removing components from PCBs in the BCM can further comprise at least one of: receiving the PCBs and PCB components in the BCM module; collecting the PCBs and PCB components in a containing means following removal of the PCB components from the PCB; moving the PCBs and PCB components through the BCM module (240) using moving means; introducing the PCBs into the heating and/or mechanical means using loading means; sorting PCBs and PCB components into batch(s) using sorting means, manually and/or automatically; moving/transferring the batch(s) to one or more modules manually and/or automatically; and any combination thereof

### The Desoldering Module

Although the boards to be recycled or reclaimed can be sent directly to a desoldering (DS) module (260), it should be understood by the person skilled in the art that any removal of components and other miscellaneous parts, either manually, automatically, in the pre-BCM (220), or in the BCM module (240), increases the efficiency of the overall desoldering process. Specifically, a desoldering module (260) relies on a solder removal composition and minimizing the total amount of chemicals needed as well as the waste stream on the back-end is advantageous. Further, without some pre-BCM and BCM removal, there is the risk that some materials will be sent to the desoldering module (260) that will poison the solder removal composition. Accordingly, the PCBs, PCB components, or both, that enter the desoldering module (260) preferably have undergone pre-BCM and BCM processing, or an equivalent thereof, to ensure the substantial majority of the components and other miscellaneous parts have been removed. Alternatively, the PCBs, PCB components, or both, that enter the desoldering module (260) may have undergone pre-BCM processing or the equivalent thereof. In yet another alternative, the PCBs, PCB components, or both, that enter the desoldering module (260) may have undergone BCM processing or an equivalent thereof to ensure the substantial majority of the PCB components and other miscellaneous parts have been removed.

An example of a known desoldering module (260) and known solder removal compositions are described in International Patent Application No. PCT/US2012/069404. Further, known solder removal compositions are described in International Patent Application No. PCT/US2011/032675 filed on Apr. 15, 2011 in the name of André Brosseau et al. and entitled “Method for Recycling of Obsolete Printed Circuit Boards,” which is hereby incorporated herein by reference in its entirety.

The PCBs, PCB components, or both, (e.g., connectors, IC chips, micro-components) that enter the DS module (260) may have solder, components, or both, attached thereto. The desoldering module (260) employs a solder removal composition, either proprietary or commercially known, to remove the solder from the boards and the components. The DS module may include any apparatus that exposes the PCBs, PCB components, or both, to a solder removal composition to effectuate the chemical removal of solder therefrom. Exposure of the PCBs, PCB components, or both, to the solder removal composition can be effectuated in any suitable manner, e.g., by spraying the solder removal composition on the PCBs, PCB components, or both, by dipping the PCBs, PCB components, or both, in a volume of the solder removal composition, by contacting the PCBs, PCB components, or both, with another material, e.g., a pad, or fibrous sorbent applicator element, that has the solder removal composition absorbed thereon, by contacting the PCBs, PCB components, or both, with a recirculating solder removal composition, or by any other suitable means, manner or technique, by which the solder removal composition is brought into contact with the PCBs, PCB components, or both. In a preferred embodiment, the PCBs, PCB components, or both, are dipped in a volume of the solder removal composition in a containing means, wherein the PCBs, PCB components, or both are fully or partially immersed in the solder removal composition. The DS module can further include means for moving and/or agitating the solder removal composition and/or PCBs, PCB components, or both, which assist in the removal of the solder and/or components from the PCBs.

In one embodiment the DS module comprises one or more chemical solder remover containers, optionally one or more drag-out containers, optionally one or more rinsing containers; and optionally one or more drying containers. In one embodiment, the DS module comprises one or more chemical solder remover containers; one or more rinsing containers; optionally one or more dragout containers; and optionally one or more drying containers. In another embodiment, the DS module comprises one or more chemical solder remover containers; one or more dragout containers; one or more rinsing containers; and optionally one or more drying containers. In yet another embodiment, the DS module comprises one or more chemical solder remover containers; one or more rinsing containers; one or more drying containers; and optionally one or more dragout containers. In still another embodiment, the DS module comprises one or more chemical solder remover containers; one or more dragout containers; one or more rinsing containers; and one or more drying containers. The PCBs, PCB components, or both, move automatically or manually, individually or in batches, from one container to the next container. In one embodiment, the PCBs, PCB components, or both, move manually or automatically, individually or in batches, from a chemical solder remover container to a rinsing container. In another embodiment, the PCBs, PCB components, or both, move manually or automatically, individually or in batches, from a chemical solder remover container to a dragout container to a rinsing container. In still another embodiment, the PCBs, PCB components, or both, move manually or automatically, individually or in batches, from a chemical solder remover container to a rinsing container to a dragout container. In yet another embodiment, the PCBs, PCB components, or both, move manually or automatically, individually or in batches, from a chemical solder remover container to a rinsing container to a drying container. In still another embodiment, the PCBs, PCB components, or both, move manually or automatically, individually or in batches, from a chemical solder remover container to a dragout container to a rinsing container to a drying container. The PCBs, PCB component, or both, move through the module from container to container via moving means, as defined herein. In one embodiment, the PCBs, PCB components, or both, are loaded in a drum that can be inserted in the one or more containers. For the purposes of this module, the “drying container” is not necessarily a container as defined herein, but can comprise means to dry the PCBs, PCB components, or both, including, but not limited to, blown air, blown hot air, rotating the container at high rpms, and/or vibration means.

For example, the PCBs, PCB components, or both (262), can be introduced, manually or automatically, to a containing means by any loading means, as defined herein, for example, chutes, conveyors, manually by hand, cranes or hoists, or any combination thereof. In one embodiment the containing means comprises one or more tanks, drums, baskets, barrels and/or combinations of the foregoing. In a preferred embodiment, the PCBs, PCB components, or both, are loaded manually or automatically into one or more drums.

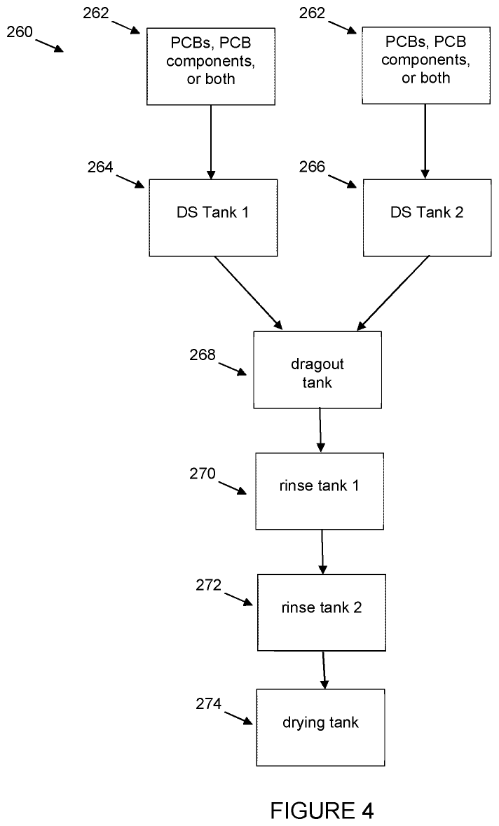

In one embodiment, the DS module comprises a drum-line comprising a tank comprising a solder removal composition (DS Tank 1 (264) or DS Tank 2 (266)), optionally a dragout tank (268), rinse tank 1 (270), optionally rinse tank 2 (272), and optionally a drying tank (274), for example, as shown in FIG. 4. A drum (500) holds the PCBs, PCB components, or both, and allows the solder removal composition (in DS Tank 1 (264) and DS Tank 2 (266)) and the rinse liquid (in rinse tank 1 (270) and rinse tank 2 (272)) to enter the drum for dissolution/solubilization and rinsing, as well as exit the drum during drainage, dragout and drying. In one embodiment, the module comprises DS Tank 1 and/or DS Tank 2, a dragout tank, rinse tank 1, rinse tank 2, and a drying tank Other combinations of tanks are contemplated. Preferably, the rinse liquid comprises water. Each tank has the volumetric capacity to contain the drum as well as the solder removal composition or rinse liquid.

Preferably, DS Tank 1 (264) or DS Tank 2 (266), rinse tank 1 (270), and rinse tank 2 (272) are continuously agitated using agitation means, as defined herein. The solder removal composition in DS Tank 1 or 2, and the rinse liquid in rinse tank 1 and rinse tank 2, can be continuously recirculated. When recirculation is used, filters may be necessary to eliminate particles prior to reentry of the composition or rinse into the tanks Concentration adjustment of one or more chemical constituents of the solder removal composition in DS Tank 1 and DS Tank 2 can occur based on real-time sampling data to extend the life of the solder removal composition. The dragout tank (268) is used to capture solder removal composition for reuse prior to dilution with rinse. Accordingly, the dragout tank (268) can be used to enhance the capture of the removal composition, e.g., using centrifugation, high pressure air, gravity, shaking, rotation, vibration, and/or quick rinse with rinse liquid from rinse tank 1. Rinse tank 1 is rinse liquid that can be reused, but when it is no longer viable for efficient rinsing, the rinse liquid in rinse tank 1 can be moved to wastewater treatment. When this occurs, the rinse liquid from rinse tank 2 can be moved to rinse tank 1 for more rinsing, and rinse tank 2 is filled with fresh rinse liquid. Periodically, DS Tank 1 or 2, rinse tank 1, and rinse tank 2 may have to be cleaned to remove precipitates and components that have fallen to the bottom of the tank during solder removal processing, depending on the design of the tank(s) The DS module is preferably controlled by a PLC to ensure worker safety and environmental rule compliance.

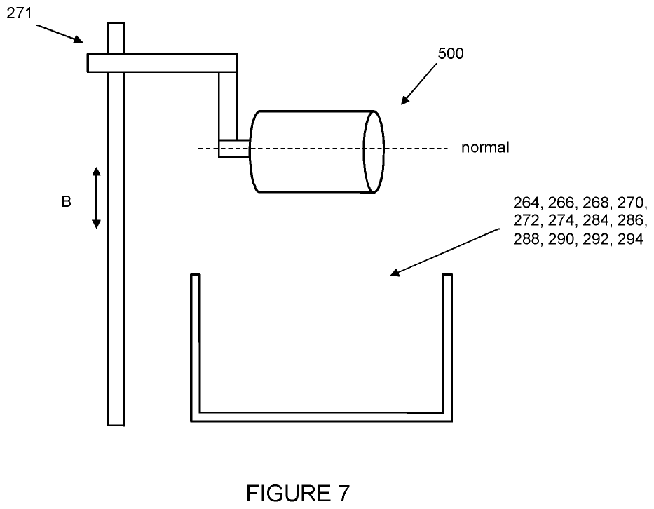

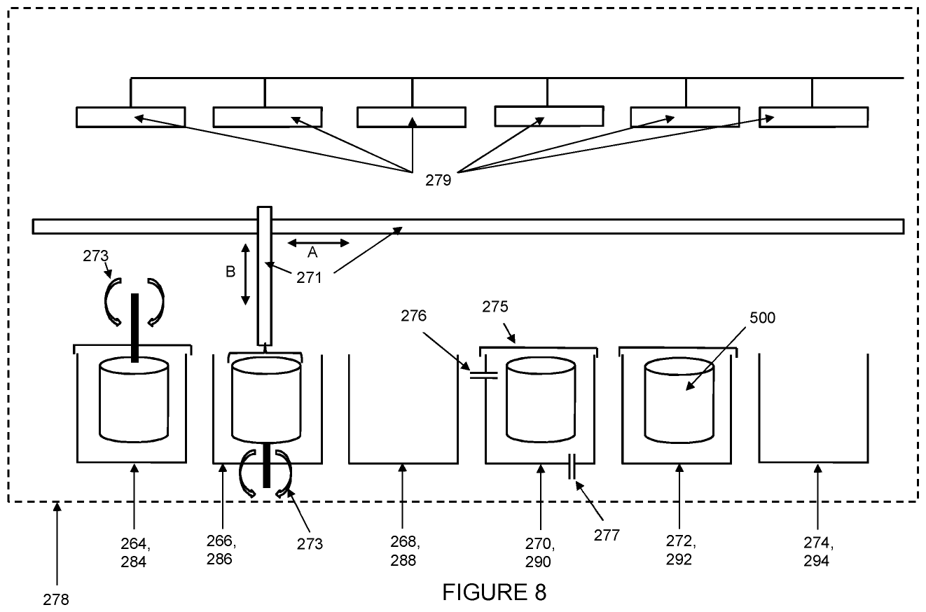

An example of a drum-line system of the desoldering module (260) is shown in FIG. 8, wherein six tanks are shown, four with drums contained therein. A loading system (271), e.g., a drum loading system, lowers and removes the drums from the tanks, whereby the drum loading system is capable of rotating the drum as well as providing an angle to the drum, as introduced below. The drum can be processed at an angle, for example any angle up to ±20° relative to normal, which can be understood better by referring to FIG. 7. Alternatively, the drum can be positioned 90° relative to normal with the open end up (not shown). It should be understood by the person skilled in the art that multiple drums may be going through the system and process simultaneously. In practice, DS Tank 1 (264) and DS Tank 2 (266) are filled with solder removal composition and rinse tank 1 (270) and rinse tank 2 (272) are filled with rinse liquid. A drum containing PCBs, PCB components, or both, is fully or partially submerged in DS Tank 1 (264) and/or DS Tank 2 (266), and optionally rotated (273) within the tanks (264, 266) at time and temperature necessary to effectuate dissolution of the solder, for example, for time in a range from about 1 minutes to about 80 minutes, preferably about 10 minutes to about 40 minutes, at temperature in a range from about room temperature to about 80° C., preferably about 30° C. to about 60° C. As shown in FIG. 8, the drum can be rotated from the top, the bottom, or from the side (not shown), depending on the mechanism, as understood by the person skilled in the art. Thereafter, the drum is moved (e.g., using a drum loading system (271), which is depicted in FIG. 8 as being able to move from tank to tank by arrow A as well as up and down within a tank by arrow B) to the dragout tank (268) to capture any excess solder removal composition for reuse in DS Tank 1 (264) or DS Tank 2 (266). The drum is then moved to rinse tank 1 (270), fully or partially submerged and optionally rotated within the tank, for time necessary to effectuate a first rinse, for example, for time in a range from about 1 minute to about 30 minutes, preferably about 1 minute to about 10 minutes. The drum is then moved to rinse tank 2 (272), fully or partially submerged and optionally rotated within the tank, for time necessary to effectuate a second rinse, for example, for time in a range from about 1 minute to about 30 minutes, preferably about 1 minute to about 10 minutes. Thereafter, the drum can be moved to a drying tank (274) to dry the boards and components contained therein. As described previously, the drying tank does not necessarily have to be a tank, but can comprise means to dry the PCBs, PCB components, or both, including, but not limited to, blown air, blown hot air, rotating the container at high rpms, and/or vibration means. All of the tanks are preferably covered (275) to minimize evaporation, e.g., the tanks can be comprised in one or more housings. As will be understood by the person skilled in the art, the drum (500), tanks (264, 266, 268, 270, 272, 274) and all lines (e.g., 277) feeding the tanks are preferably constructed from material that is compatible with the solder removal composition and temperatures used, and the tanks (264, 266, 268, 270, 272, 274) may also include heating/cooling means (not shown), air inputs (not shown), sensing means, and/or ventilation means (279). It should be appreciated that all of the tanks (264, 266, 268, 270, 272, 274) can include at least one of input/output line 277 and the depiction of input/output lines 277 in FIG. 8 is not intended to limit alternative embodiments. For example, there can be one, two, three, four, or more input/output lines into the tanks. The ventilation means (e.g., 276) can include the condensation of any of the chemical fumes for reintroduction back in the module as a viable liquid as well as monitors to ensure the safety of the personnel. The entire module can be contained within an enclosure (278). The module is preferably controlled by a PLC to ensure worker safety and environmental rule compliance.

Once the solder removal composition is loaded, as readily discernible by the person skilled in the art, it can be sent for post-DS processing. Post processing may include one or more of chemistry reclamation, regeneration or metal(s) separation whereby techniques such as diffusion dialysis (DD), lead electrowinning (EW), resin-based acid recycle and metals recovery, or any combination of these may be used. Following post-DS processing, some of the solder removal composition can be reclaimed and returned for blending of fresh solder removal composition. The remainder can be sent to wastewater treatment. A “feed and bleed” process may alternatively be used wherein clean solder removal composition is periodically introduced to the working solder removal composition with simultaneous withdrawal of some of the working solder removal composition for subsequent treatment.

Following processing in the DS module (260), the drum can be unloaded, manually or automatically, so that the PCBs, PCB components, or both, can be separated for further processing, as is appropriate based on the PCBs, PCB components, or both (see, e.g., FIG. 3). For example: chips and microcomponents can be sent to the SPT furnace module (320), the SPT milling module (340), or the SPT tool module (360); anything that has precious metal value such as memory boards, gold fingers, and connectors can be sent to the gold leaching (GL) module (280); and the remaining boards can be collected and further processed in house (e.g., in the base metal removal module) or off-site. Separation can occur manually or automatically, using vibration means, agitation means, stirring, mixing, trommels, shake tables, filters, or any other sorting means that separate the PCBs, PCB components, or both, that exit the drum following DS processing. In one embodiment, the PCBs, PCB components, or both, are sorted whereby ICs and microcomponents are sent to the SPT furnace module (320), SPT milling module (340), SPT tool module (360), or any two or all three of the foregoing. Gold fingers, plastic connectors and memory boards can be sorted and sent to the GL module (280).

Alternatively, following processing in the DS module (260), if the PCBs/components being processed comprise a batch of plastic connectors, the drum is not unloaded and instead is directed to a gold leaching module (280), as described below.

Although not wanting to be bound by numbers, a DS module (260) has been built to scale and preferably can process greater than 100 kg/h of PCBs, plastic connectors, ICs, and microcomponents, preferably greater than 150 kg/h, and most preferably greater than 200 kg/h.

The DS module (260) is preferably controlled by PLC and the particular recipe is selected when the PCBs, PCB components, or both, which preferably were previously sorted into batches, enter the DS process stream. As discussed hereinabove, the DS module (260) will be monitored in real-time, wherein the solder removal composition in both DS Tank 1 and DS Tank 2 can be sampled at least every one hour and the concentration of the chemical compounds determined, wherein the rinse water in both rinse water tank 1 and rinse water tank 2 can be sampled at least every three hours, and wherein the PCBs can be sampled at least every one hour and the concentration of specific chemicals determined following solid material digestion, as readily understood by the person skilled in the art. Further, the gases evolved and all of the hardware of the DS module (260) are monitored to ensure that the module is working efficiently and safely. Additional real-time monitoring of the DS module (260) is contemplated, including, but not limited to, the monitoring of hardware and software.

It should be appreciated that the embodiment described herein is just one embodiment envisioned. Instead of a drum, the PCBs, PCB components, or both, can be moved from tank to tank by some other containing and moving means, whether manually or automatically. Alternatively, the boards and/or components can be loaded into a tank and the process flow illustrated in FIG. 4 can be followed whereby the PCBs, PCB components, or both, are not removed from the tank until the completion of the process flow of FIG. 4. In this example, the solder removal composition and rinse liquids are introduced to and then removed from the tank. For example, a solder removal composition can be introduced to the tank comprising the PCBs, PCB components, or both, wherein the solder removal composition is removed from the tank following solder removal but the PCBs, PCB components, or both, remain in the tank. Thereafter, dragout or the equivalent thereof can occur, followed by the introduction of a first rinse liquid to the tank and removal of the first rinse liquid following the first rinse, and introduction of a second rinse liquid to the tank and removal of the second rinse liquid following the second rinse. Thereafter, the PCBs, PCB components, or both, can optionally be dried. Other embodiments can be envisioned by the person skilled in the art.

In one aspect, a desoldering (DS) module (260) to remove solder, PCB components, or both, from PCBs, PCB components, or both, is described, said DS module (260) comprising:
a system comprising at least at least one solder removal tank, at least one dragout tank, and at least one rinsing tank, wherein each tank has the volumetric capacity to contain a containing means, e.g., drum, therein,
   wherein the system comprises moving means to move the containing means, e.g., drum, from tank to tank, e.g., from the at least one solder removal tank to the at least one dragout tank to the at least one rinsing tank or any other order necessary to remove solder, PCB components, or both, from PCBs, PCB components, or both. In practice, the PCBs, PCB components, or both, are manually or automatically introduced to the containing means, e.g., drum, for processing. The containing means, e.g., drum, can be serially moved from tank to tank using moving means, complete with full or partial submersion of the containing means, e.g., drum, in the at least one solder removal tank and the at least one rinsing tank. The at least one solder removal tank can comprise a solder removal composition. Each tank can comprise one or more of: agitation means; at least one filter; real-time sampling and adjustment; a cover to minimize evaporation; heating/cooling means; air inputs; sensing means; ventilation means; and any combination thereof. The system can further comprise at least one drying tank. The DS module (260) can be controlled by a PLC.

In another aspect, a process of removing solder, PCB components, or both, from PCBs, PCB components, or both, is described, said process comprising:
(a) loading PCBs, PCB components, or both into a containing means, e.g., drum;
(b) removing the solder, PCB components, or both, from PCBs, PCB components, or both using a system, wherein the system comprises at least at least one solder removal tank, at least one dragout tank, and at least one rinsing tank,
wherein each tank has the volumetric capacity to contain a containing means, e.g., drum, therein, wherein the system comprises moving means to move the containing means, e.g., drum, from tank to tank, e.g., from the at least one solder removal tank to the at least one dragout tank to the at least one rinsing tank or any other order necessary to remove solder, PCB components, or both, from PCBs, PCB components, or both.
   The containing means, e.g., drum, can be serially moved from tank to tank using moving means, complete with full or partial submersion of the containing means, e.g., drum, in the at least one solder removal tank and the at least one rinsing tank. Each tank can comprise one or more of: agitation means; at least one filter; real-time sampling and adjustment; a cover to minimize evaporation; heating/cooling means; air inputs; sensing means; ventilation means; and any combination thereof. The system can further comprise at least one drying tank. The containing means, e.g., drum, can be fully or partially submerged in the at least one solder removal tank comprising a solder removal composition for time in a range from about 1 minute to about 80 minutes, preferably about 10 minutes to about 40 minutes, at temperature in a range from about room temperature to about 80° C., preferably about 30° C. to about 60° C. The containing means, e.g., drum, can be fully or partially submerged in the at least one rinsing tank for time in a range from about 1 minute to about 30 minutes, preferably about 1 minute to about 10 minutes. The DS module (260) can be controlled by a PLC and the process of removing solder, PCB components, or both, from PCBs, PCB components, or both, can be subject to a recipe specific to what is being processed, as dictated by the PLC.

### The Drum and the Drum Loading System

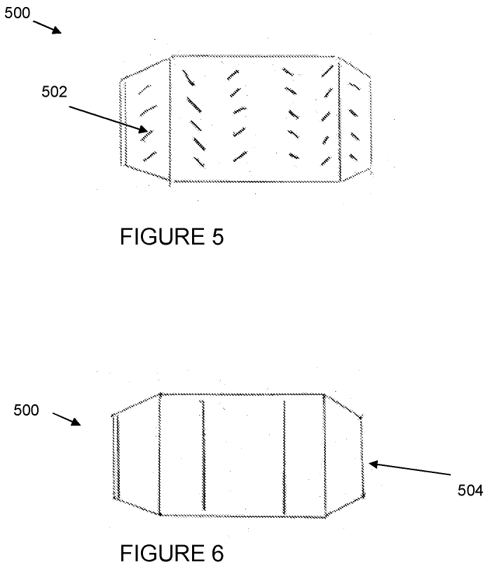

Two examples of drums (500) are shown in FIGS. 5 and 6. The drum (500) comprises a first end having an opening therein to receive PCBs, PCB components, or both, a second end, and a sidewall that connects the first end to the second end. The drum may vary in diameter along its length and can optionally include at least one interior “fin” (502) so that the PCBs, PCB components, or both, are agitated within the drum as rotation occurs. The drum (500) can be one monolithic piece or can comprise at least two pieces that can be attached together, e.g., with latches, nuts and bolts, and/or hooks and eyes, but also unattached for maintenance purposes. Advantageously, when the drum comprises at least two pieces, the pieces can be configured to allow for the assembly of different sized drums. The drum (500) is preferably sized and shaped to allow removal compositions to pass through and ensure complete mixing and full chemical exposure of the PCBs and/or PCB components contained inside. For example, the drum (500) may have custom curves, perforations, vanes, custom fluid channels, and bent slots which act like “mini-pumps” which ensure better chemical transfer throughout the inside of the drum, especially during drum rotation. Some components are very light and will float on the surface of the liquids and as such, the drums can have internal features such as fins to aid in submerging these components in the removal composition. The drum (500) can include at least one hole or opening sized to allow the removal composition and rinse to enter the drum. For example, the drum (500) may comprise one open end (504) for board loading which eliminates the cost and reliability problems of a door, although a door or screen may be included, wherein the door or screen does not restrict flow of removal composition or rinse but retains the boards and components in the drum, as readily understood by the person skilled in the art. The drums are preferably fabricated out of polyvinylidene fluoride (PVDF) and or polypropylene (PP) material. It should be appreciated by the person skilled in the art that the shape and structure of the drums depicted in FIGS. 5 and 6 is not intended to limit the drum in any way. Drums engineered in alternative shapes and structures are contemplated herein.

With regards to the loading system (271), e.g., a drum loading system, it can be adapted for manually or automatically handling and/or manually or automatically moving the at least one containing means from tank to tank, e.g., inserting into a tank and removing from a tank. Further, the loading system can be adapted to manually or automatically rotate or spin the containing means as well as manually or automatically move the containing means to any angle relative to normal. Preferably, the containing means, i.e., drum, rotates 360° or less using a variable speed drive. For example, the containing means, i.e., drum, can be processed at an angle, for example any angle up to ±20° relative to normal, which can be understood better by referring to FIG. 7. Alternatively, the containing means, i.e., drum, can be positioned 90° relative to normal with the first end up (not shown). In a preferred embodiment, the containing means comprise a drum. The loading system preferably supports the containing means, i.e., drum, from the first end, the second end or the sidewall. The loading system can comprise one or more of the moving means, as described herein, preferably robotic arms, loading arms, vertical lift guides, gantries and combinations thereof. The loading system is engineered to provide agitation to the containing means, i.e., drum, for example by rotating, vibrating and/or shaking the drum within the tank as well as above the tank, as necessary, to effectuate chemical metal removal, dragout, rinsing, and/or drying. Alternatively, agitation of the containing means is effectuated using the agitation means, as defined herein. Further, the loading system and the containing means are designed for circulating the removal composition.

FIG. 7 illustrates an embodiment of the drum loading system wherein the drum (500) can be raised and/or lowered according to arrow B. Further, the drum can be angled relative to normal (it is shown at an angle of 0°). FIG. 8 shows how a drum containing PCBs, PCB components or both, is picked up by the drum loading system. In one embodiment, a gantry comprising at least one coupling device such as a loading fork or carriage arm can be coupled to the drum along its first end, second end and/or sidewall and one or more moving means, e.g., lift devices, carry and/or move the drum into a position for processing through a module.

At multiple locations or “stations” along the drum-line, including drum filling stations, entry into and out tanks as well as drum holding, drying and dragout stations and drum-contents dump stations and drum cleaning stations, it is beneficial and desirable to rotate and or shake the drums. This includes empty as well as PCB and/or PCB component filled drums. Using a motor or engine as the source of energy, and any combination of direct gear, belt or friction contact with the drum, drum rotation is controlled with respect to direction (forward and/or reverse), speed and duration. The operator, through a computer, programmable controller or direct control of the drive motors, controls the various aspects of drum rotation with the intent of maximizing process efficiency at each “station” with respect to mixing, drying, chemical consumption, etch efficiency, parts separation, drum filling, emptying and cleaning. Discrete and rapid bursts of power to the drum drive system are also used to impose vibrational and impact energy to the drum and its contents.

In one aspect, a drum is described, said drum comprising an enclosure for containing PCBs, PCB components, or both, therein, wherein the enclosure comprises at least one of: at least one hole for allowing a liquid to enter and exit the drum; at least one interior fin for agitating the PCBs, PCB components, or both, contained within the drum; a rotating drive; and any combination thereof.

### The Base Metal Removal Module

In one embodiment, prior to gold leaching, the base metals are removed so that subsequent processing for the gold is more efficient. The PCBs, PCB components, or both, that exit the desoldering module (260), or an equivalent thereof, may be sent to a base metal removal (BMR) (261) module prior to the gold leaching module (280). Alternatively, the PCBs, PCB components, or both, that exit the BCM that have negligible or no solder may be sorted and sent to a BMR module (261) prior to the gold leaching module (280). In still another alternative, the BMR module (261) can be used to remove and recover copper and other base metals from the PCBs, PCB components, or both, that have no precious metal value following desoldering and/or gold leaching.

An example of a known base metal removal module (261) is described in International Patent Application No. PCT/US2012/069404. Further, known base metal removal compositions are described in International Patent Application No. PCT/US2011/032675 filed on Apr. 15, 2011 in the name of André Brosseau et al. and entitled “Method for Recycling of Obsolete Printed Circuit Boards,” which is hereby incorporated herein by reference in its entirety.

The BMR module (261) employs a base metal removal composition, either proprietary or commercially known, to remove one or more base metals from the PCBs, PCB components, or both, The BMR module may include any apparatus that exposes the PCBs, PCB components, or both, to a base metal removal composition to effectuate the chemical removal of at least one base metal therefrom. Exposure of the PCBs, PCB components, or both, to the base metal removal composition can be effectuated in any suitable manner, e.g., by spraying the base metal removal composition on the PCBs, PCB components, or both, by dipping the PCBs, PCB components, or both, in a volume of the base metal removal composition, by contacting the PCBs, PCB components, or both, with another material, e.g., a pad, or fibrous sorbent applicator element, that has the base metal removal composition absorbed thereon, by contacting the PCBs, PCB components, or both, with a recirculating base metal removal composition, or by any other suitable means, manner or technique, by which the base metal removal composition is brought into contact with the PCBs, PCB components, or both. In a preferred embodiment, the PCBs, PCB components, or both, are dipped in a volume of the base metal removal composition in a containing means, wherein the PCBs, PCB components, or both are fully or partially immersed in the base metal removal composition. The BMR module can further include means for moving and/or agitating the base metal removal composition and/or PCBs, PCB components, or both, which assist in the removal of at least one base metal from the PCBs, PCB components, or both

In one embodiment the BMR module comprises one or more chemical base metal remover containers, optionally one or more drag-out containers, optionally one or more rinsing containers; and optionally one or more drying containers. In one embodiment, the BMR module comprises one or more chemical base metal remover containers; one or more rinsing containers; optionally one or more dragout containers; and optionally one or more drying containers. In another embodiment, the BMR module comprises one or more chemical base metal remover containers; one or more dragout containers; one or more rinsing containers; and optionally one or more drying containers. In yet another embodiment, the BMR module comprises one or more chemical base metal remover containers; one or more rinsing containers; one or more drying containers; and optionally one or more dragout containers. In still another embodiment, the BMR module comprises one or more chemical base metal remover containers; one or more dragout containers; one or more rinsing containers; and one or more drying containers. The PCBs, PCB components, or both, move automatically or manually, individually or in batches, from one container to the next container. In one embodiment, the PCBs, PCB components, or both, move manually or automatically, individually or in batches, from a chemical base metal remover container to a rinsing container. In another embodiment, the PCBs, PCB components, or both, move manually or automatically, individually or in batches, from a chemical base metal remover container to a dragout container to a rinsing container. In still another embodiment, the PCBs, PCB components, or both, move manually or automatically, individually or in batches, from a chemical base metal remover container to a rinsing container to a dragout container In yet another embodiment, the PCBs, PCB components, or both, move manually or automatically, individually or in batches, from a chemical base metal remover container to a rinsing container to a drying container. In still another embodiment, the PCBs, PCB components, or both, move manually or automatically, individually or in batches, from a chemical base metal remover container to a dragout container to a rinsing container to a drying container. The PCBs, PCB component, or both, move through the module from container to container via moving means, as defined herein. In one embodiment, the PCBs, PCB components, or both, are loaded in a drum that can be inserted in the one or more containers. For the purposes of this module, the “drying container” is not necessarily a container as defined herein, but can comprise means to dry the PCBs, PCB components, or both, including, but not limited to, blown air, blown hot air, rotating the container at high rpms, and/or vibration means.

For example, the PCBs, PCB components, or both can be introduced, manually or automatically, to a containing means by any loading means, as defined herein, for example, chutes, conveyors, manually by hand, cranes or hoists, or any combination thereof. In one embodiment the containing means comprises one or more tanks, drums, baskets, barrels and/or combinations of the foregoing. In a preferred embodiment, the PCBs, PCB components, or both, are loaded manually or automatically into one or more drums.

In one embodiment, the BMR module comprises a drum-line comprising a tank comprising a base metal removal composition (BMR Tank 1 or 2), optionally a dragout tank, rinse tank 1, optionally a rinse tank 2, and optionally a drying tank, for example, analogous to the desoldering module (260) shown in FIG. 4. A drum holds the PCBs, PCB components, or both, and allows the base metal removal composition (in BMR Tank 1 and 2) and the rinse liquid (in rinse tank 1 and rinse tank 2) to enter the drum for dissolution/solubilization and rinsing, as well as exit the drum during drainage, dragout and drying. In one embodiment, the module comprises BMR Tank 1 and/or BMR Tank 2, a dragout tank, rinse tank 1, rinse tank 2, and a drying tank. Other combinations of tanks are contemplated. Preferably, the rinse liquid comprises water. Each tank has the volumetric capacity to contain the drum as well as the solder removal composition or rinse liquid.

Preferably, BMR Tank 1 or 2, rinse tank 1, and rinse tank 2 are continuously agitated using agitation means, as defined herein. The base metal removal composition in BMR Tank 1 or 2, and the rinse liquid in rinse tank 1 and rinse tank 2, can be continuously recirculated. When recirculation is used, filters may be necessary to eliminate particles prior to reentry of the composition or rinse into the tanks Concentration adjustment of one or more chemical constituents of the base metal removal composition in BMR Tank 1 and BMR Tank 2 can occur based on real-time sampling data to extend the life of the base metal removal composition. The dragout tank is used to capture base metal removal composition for reuse prior to dilution with rinse. Accordingly, the dragout tank can be used to enhance the capture of the removal composition, e.g., using centrifugation, high pressure air, gravity, shaking, rotation, vibration, and/or quick rinse with rinse liquid from rinse tank 1. Rinse tank 1 is rinse liquid that can be reused, but when it is no longer viable for efficient rinsing, the rinse liquid in rinse tank 1 can be moved to wastewater treatment. When this occurs, the rinse liquid from rinse tank 2 can be moved to rinse tank 1 for more rinsing, and rinse tank 2 is filled with fresh rinse liquid. Periodically, BMR Tank 1 or 2, rinse tank 1, and rinse tank 2 may have to be cleaned to remove precipitates and components that have fallen to the bottom of the tank during base metal removal processing, depending on the design of the tank(s). The module BMR is preferably controlled by a PLC to ensure worker safety and environmental rule compliance.

An example of a drum-line system of the BMR module (261) is shown in FIG. 8, for example as described hereinabove for the desoldering module (260), wherein six tanks are shown, four with drums contained therein. A loading system (271), e.g., a drum loading system, lowers and removes the drums from the tanks, whereby the drum loading system is capable of rotating the drum as well as providing an angle to the drum. The drum can be processed at an angle, for example any angle up to ±20° relative to normal, which can be understood better by referring to FIG. 7. Alternatively, the drum can be positioned 90° relative to normal with the open end up (not shown). It should be understood by the person skilled in the art that multiple drums may be going through the system and process simultaneously. In practice, BMR Tank 1 and BMR Tank 2 are filled with base metal removal composition and rinse tank 1 and rinse tank 2 are filled with rinse liquid. A drum containing PCBs, PCB components, or both, is fully or partially submerged in BMR Tank 1 and/or BMR Tank 2, and optionally rotated within the tanks, at time and temperature necessary to effectuate dissolution of at least one base metal, for example, for time in a range from about 1 minute to about 80 minutes, preferably about 10 minutes to about 40 minutes, at temperature in a range from about room temperature to about 80° C., preferably about 30° C. to about 60° C. As shown in FIG. 8, the drum can be rotated from the top, the bottom, or from the side (not shown), depending on the mechanism, as understood by the person skilled in the art. Thereafter, the drum is moved (e.g., using a drum loading system, which is depicted in FIG. 8 as being able to move from tank to tank (arrow A) as well as up and down (arrow B) within a tank) to the dragout tank to capture any excess base metal removal composition for reuse in BMR Tank 1 or BMR Tank 2. The drum is then moved to rinse tank 1, fully or partially submerged and optionally rotated within the tank, for time necessary to effectuate a first rinse, for example, for time in a range from about 1 minute to about 30 minutes, preferably about 1 minute to about 10 minutes. The drum is then moved to rinse tank 2 for time, fully or partially submerged and optionally rotated within the tank, necessary to effectuate a second rinse, for example, for time in a range from about 1 minute to about 30 minutes, preferably about 1 minute to about 10 minutes. Thereafter, the drum can be moved to a drying tank to dry the boards and components contained therein. As described previously, the drying tank does not necessarily have to be a tank, but can comprise means to dry the PCBs, PCB components, or both, including, but not limited to, blown air, blown hot air, rotating the container at high rpms, and/or vibration means. All of the tanks are preferably covered to minimize evaporation, e.g., the tanks can be comprised in one or more housings. As will be understood by the person skilled in the art, the drum, tanks and all lines feeding the tanks are preferably constructed from material that is compatible with the base metal removal composition and temperatures used and the tanks may also include heating/cooling means; air inputs, sensing means, and/or ventilation means. It should be appreciated that all of the tanks can include at least one input/output line and the depiction of input/output lines in FIG. 8 is not intended to limit alternative embodiments. For example, there can be one, two, three, four, or more input/output lines into the tanks. The ventilation means can the condensation of any of the chemical fumes for reintroduction back in the module as a viable liquid as well as monitors to ensure the safety of the personnel. The entire module can be contained within an enclosure. The module is preferably controlled by a PLC to ensure worker safety and environmental rule compliance.

Once the base metal removal composition is loaded, as readily discernible by the person skilled in the art, it can be sent for post-BMR processing. Post processing may include one or more of chemistry reclamation, regeneration or metal(s) separation whereby techniques such as diffusion dialysis (DD), electrowinning (EW), resin-based acid recycle and metals recovery, or any combination of these may be used. Following post-BMR processing, some of the base metal removal composition can be reclaimed and returned for blending of fresh base metal removal composition. The remainder can be sent to wastewater treatment. A “feed and bleed” process may alternatively be used wherein clean base metal removal composition is periodically introduced to the working base metal removal composition with simultaneous withdrawal of some of the working base metal removal composition for subsequent treatment.

Following processing in the BMR module (261), the drum is unloaded, manually or automatically, so that the PCBs, PCB components, or both, can be separated for further processing, as is appropriate based on the PCBs, PCB components, or both, (see, e.g., FIG. 3). For example: chips and microcomponents can be sent to the SPT furnace module (320), the SPT milling module (340), or the SPT tool module (360); anything that has precious metal value such as memory boards, gold fingers, and connectors can be sent to the gold leaching (GL) module (280); and the remaining boards can be collected and further processed in house or off-site. Separation can occur manually or automatically, using vibration means, agitation means, stirring, mixing, trommels, shake tables, filters, or any other sorting means that separate the PCBs, PCB components, or both, that exit the drum following BMR module (261) processing. In one embodiment, the PCBs, PCB components, or both, are sorted whereby ICs and microcomponents are sent to the SPT furnace module (320), SPT milling module (340), SPT tool module (360), or any two or all three of the foregoing. Gold fingers, plastic connectors and memory boards can be sorted and sent to the GL module (280).

The BMR module (261) is preferably controlled by PLC and the particular recipe is selected when the PCBs, PCB components, or both, which preferably were previously sorted into batches, enter the BMR process stream. As discussed hereinabove, the BMR module (261) will be monitored in real-time, wherein the base metal removal composition in both BMR Tank 1 and BMR Tank 2 can be sampled at least every one hour and the concentration of the chemical compounds determined, wherein the rinse water in both rinse water tank 1 and rinse water tank 2 can be sampled at least every one hour, and wherein the boards and/or components can be sampled at least every one hour and the concentration of specific chemicals determined following solid material digestion, as readily understood by the person skilled in the art. Further, the gases evolved and all of the hardware of the BMR module are monitored to ensure that the module is working efficiently and safely. Additional real-time monitoring of the BMR module (261) is contemplated, including, but not limited to, the monitoring of hardware and software.

It should be appreciated that the embodiment described herein is just one embodiment envisioned. Instead of a drum, the PCBs, PCB components, or both, can be moved from tank to tank by some other containing and moving means, whether manually or automatically. Alternatively, the boards and/or components can be loaded into a tank and the process flow illustrated in FIG. 4 can be followed whereby the PCBs, PCB components, or both, are not removed from the tank until the completion of the process flow of FIG. 4. In this example, the base metal removal composition and rinse liquids are introduced to, and then removed from, the tank. For example, a base metal removal composition can be introduced to the tank comprising the PCBs, PCB components, or both, wherein the base metal removal composition is removed from the tank following base metal removal but the PCBs, PCB components, or both, remain in the tank. Thereafter, dragout or the equivalent thereof can occur, followed by the introduction of a first rinse liquid to the tank and removal of the first rinse liquid following the first rinse, and introduction of a second rinse liquid to the tank and removal of the second rinse liquid following the second rinse. Thereafter, the PCBs, PCB components, or both, can optionally be dried. Other embodiments can be envisioned by the person skilled in the art.

In one aspect, a base metal removal (BMR) module (261) to remove at least one base metal from PCBs, PCB components, or both, is described, said BMR module comprising:
a system comprising at least at least one base metal removal tank, at least one dragout tank, and at least one rinsing tank, wherein each tank has the volumetric capacity to contain a containing means, e.g., drum, therein,
   wherein the system comprises moving means to move the containing means, e.g., drum, from tank to tank, e.g., from the at least one base metal removal tank to the at least one dragout tank to the at least one rinsing tank or any other order necessary to remove at least one base metal from PCBs, PCB components, or both. In practice, the PCBs, PCB components, or both, are manually or automatically introduced to the containing means, e.g., drum, for processing. The containing means, e.g., drum, can be serially moved from tank to tank using moving means, complete with full or partial submersion of the containing means, e.g., drum, in the at least one base metal removal tank and the at least one rinsing tank. The at least one base metal removal tank can comprise a base metal removal composition. Each tank can comprise one or more of: agitation means; at least one filter; real-time sampling and adjustment; a cover to minimize evaporation; heating/cooling means; air inputs; sensing means; ventilation means; and any combination thereof. The system can further comprise at least one drying tank. The BMR module (261) can be controlled by a PLC.

In another aspect, a process of removing at least one base metal from PCBs, PCB components, or both is described, said process comprising:
(a) loading PCBs, PCB components, or both into a containing means, e.g., drum;
(b) removing at least one base metal from PCBs, PCB components, or both using a system, wherein the system comprises at least at least one base metal removal tank, at least one dragout tank, and at least one rinsing tank,
wherein each tank has the volumetric capacity to contain a containing means, e.g., drum, therein, wherein the system comprises moving means to move the containing means, e.g., drum, from tank to tank, e.g., from the at least one base metal removal tank to the at least one dragout tank to the at least one rinsing tank or any other order necessary to remove at least one base metal from PCBs, PCB components, or both.
   The containing means, e.g., drum, can be serially moved from tank to tank using moving means, complete with full or partial submersion of the containing means, e.g., drum, in the at least one base metal removal tank and the at least one rinsing tank. Each tank can comprise one or more of: agitation means; at least one filter; real-time sampling and adjustment; a cover to minimize evaporation; heating/cooling means; air inputs; sensing means; ventilation means; and any combination thereof. The system can further comprise at least one drying tank. The containing means, e.g., drum, can be fully or partially submerged in the at least one base metal removal tank comprising a base metal removal composition for time in a range from about 1 minute to about 80 minutes, preferably about 10 minutes to about 40 minutes, at temperature in a range from about room temperature to about 80° C., preferably about 30° C. to about 60° C. The containing means, e.g., drum, can be fully or partially submerged in the at least one rinsing tank for time in a range from about 1 minute to about 30 minutes, preferably about 1 minute to about 10 minutes. The BMR module (261) can be controlled by a PLC and the process of removing at least one base metal from PCBs, PCB components, or both can be subject to a recipe specific to what is being processed, as dictated by the PLC.

### The Gold Leaching Module

Although the boards to be recycled or reclaimed can be sent directly to a gold leaching (GL) module, it should be understood by the person skilled in the art that any removal of components and other miscellaneous parts, either manually, automatically, in the pre-BCM (220), in the BCM module (240), and/or in the DS module (260), increases the efficiency of the gold leaching process. Specifically, a GL module (280) relies on a gold removal composition and thus minimizing the total amount of chemicals needed as well as the waste stream on the back-end is advantageous. Further, without component removal, the gold removal process may be less efficient. Accordingly, the material that enters the GL module (280) preferably has undergone pre-BCM, BCM processing, and/or desoldering, or the equivalent thereof, and has been selected, manually or automatically, specifically for GL processing. For example, gold fingers, connectors comprising gold, memory boards, and any other components having gold value, hereinafter referred to as “materials comprising gold,” have preferably been selected specifically for GL processing from any or all of the upstream processes.

An example of a known gold leaching module (280) is described in International Patent Application No. PCT/US2012/069404. Further, known gold removal compositions are described in International Patent Application No. PCT/US2011/032675 filed on Apr. 15, 2011 in the name of André Brosseau et al. and entitled “Method for Recycling of Obsolete Printed Circuit Boards,” and International Patent Application No. PCT/US2015/017088 filed on Feb. 23, 2015 in the name of Tianniu Chen et al. and entitled “Wet Based Formulations for the Selective Removal of Noble Metals,” both of which are hereby incorporated by reference herein in its entirety.

The GL module (280) employs a gold removal composition, either proprietary or commercially known, to remove the gold from the materials comprising gold introduced to the module. The gold removal composition can be used in an electrolytic system or in a non-electrolytic leaching system, preferably the latter. The GL module may include any apparatus that exposes the materials comprising gold to a gold removal composition to effectuate the chemical removal of gold therefrom. Exposure of the materials comprising gold to the gold removal composition can be effectuated in any suitable manner, e.g., by spraying the gold removal composition on the materials comprising gold by dipping the materials comprising gold in a volume of the gold removal composition, by contacting the materials comprising gold with another material, e.g., a pad, or fibrous sorbent applicator element, that has the gold removal composition absorbed thereon, by contacting the materials comprising gold with a recirculating gold removal composition, or by any other suitable means, manner or technique, by which the gold removal composition is brought into contact with the materials comprising gold. In a preferred embodiment, the materials comprising gold are dipped in a volume of the gold removal composition in a containing means, wherein the materials comprising gold are fully or partially immersed in the gold removal composition. The GL module can further include means for moving and/or agitating the gold removal composition and/or materials comprising gold which assist in the removal of gold from the materials comprising gold.

In one embodiment the GL module comprises one or more chemical gold remover containers, optionally one or more drag-out containers, optionally one or more rinsing containers; and optionally one or more drying containers. In one embodiment, the GL module comprises one or more chemical gold remover containers; one or more rinsing containers; optionally one or more dragout containers; and optionally one or more drying containers. In another embodiment, the GL module comprises one or more chemical gold remover containers; one or more dragout containers; one or more rinsing containers; and optionally one or more drying containers. In yet another embodiment, the GL module comprises one or more chemical gold remover containers; one or more rinsing containers; one or more drying containers; and optionally one or more dragout containers. In still another embodiment, the GL module comprises one or more chemical gold remover containers; one or more dragout containers; one or more rinsing containers; and one or more drying containers. The materials comprising gold move automatically or manually, individually or in batches, from one container to the next container. In one embodiment, the materials comprising gold move manually or automatically, individually or in batches, from a chemical gold remover container to a rinsing container. In another embodiment, the materials comprising gold move manually or automatically, individually or in batches, from a chemical gold remover container to a dragout container to a rinsing container. In still another embodiment, the materials comprising gold move manually or automatically, individually or in batches, from a chemical gold remover container to a rinsing container to a dragout container. In yet another embodiment, the materials comprising gold move manually or automatically, individually or in batches, from a chemical gold remover container to a rinsing container to a drying container. In still another embodiment, the materials comprising gold move manually or automatically, individually or in batches, from a chemical gold remover container to a dragout container to a rinsing container to a drying container. The materials comprising gold move through the module from container to container via moving means, as defined herein. In one embodiment, the materials comprising gold are loaded in a drum that can be inserted in the one or more containers. For the purposes of this module, the “drying container” is not necessarily a container as defined herein, but can comprise means to dry the PCBs, PCB components, or both, including, but not limited to, blown air, blown hot air, rotating the container at high rpms, and/or vibration means.

For example, the materials comprising gold may be introduced, manually or automatically, to a containing means by any loading means, as defined herein, for example, chutes, conveyors, manually by hand, cranes or hoists, or any combination thereof. In one embodiment the containing means comprises one or more tanks, drums, baskets, barrels and/or combinations of the foregoing. In a preferred embodiment, the PCBs, PCB components, or both, are loaded manually or automatically into one or more drums.

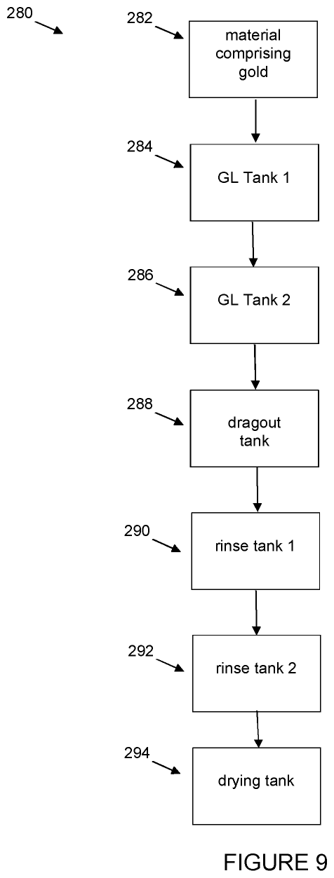

In one embodiment, the GL module comprises a drum-line comprising a tank comprising gold removal composition (GL Tank 1 (284) and GL Tank 2 (286)), optionally a dragout tank (288), rinse tank 1 (290), optionally rinse tank 2 (292), and optionally a drying tank (294), for example, as shown in FIG. 9. A drum (500) holds the materials comprising gold (282) and allows the gold removal composition (in GL Tank 1 (284) and 2 (286)) and the rinse liquid (in rinse tank 1 (290) and rinse tank 2 (292)) to enter the drum for dissolution/solubilization of the gold into gold ions and subsequent rinsing of the non-dissolved materials to capture any gold ions not previously collected, as well as exit the drum during drainage, dragout and drying. Other combinations of tanks are contemplated. For example, the drum may be dipped in just one GL Tank (i.e., GL Tank 1 or 2) for a longer period of time, as understood by the person skilled in the art, followed by dragout, two rinses, and drying. Preferably the rinse liquid comprises water. Each tank has the volumetric capacity to contain the drum as well as the gold removal composition or rinse liquid.

Preferably, GL Tank 1 (284), GL Tank 2 (286), rinse tank 1 (290), and rinse tank 2 (292) are continuously agitated using agitation means, as defined herein. The gold removal composition in GL Tank 1 (284) and GL Tank 2 (286), or the rinse liquid in rinse tank 1 (290) and rinse tank 2 (292) can be continuously recirculated. When recirculation is used, filters may be necessary to eliminate particles prior to reentry of the composition or rinse into the tanks Concentration adjustment of one or more chemical constituents of the gold removal composition in GL Tank 1 (284) and GL Tank 2 (286) can occur based on real-time sampling data to extend the life of the solder removal composition. The dragout tank (288) is used to capture gold removal composition for reuse prior to dilution with rinse. Accordingly, the dragout tank (288) can be used to enhance the capture of the removal composition, e.g., using centrifugation, high pressure air, gravity, shaking, rotation, vibration, and/or quick rinse with rinse liquid from rinse tank 1. Rinse tank 1 is rinse liquid that can be reused, but when is no longer viable for efficient rinsing, the rinse liquid in rinse tank 1 can be moved to electrowinning or resin-based acid recycle and metals recovery. When this occurs, the rinse liquid from rinse tank 2 can be moved to rinse tank 1 for more rinsing, and rinse tank 2 is filled with fresh rinse liquid. The GL module is preferably controlled by a PLC to ensure worker safety and environmental rule compliance.

An example of a drum-line system of the GL module (280) is shown in FIG. 8, wherein six tanks are shown, four with drums contained therein. A loading system (271), e.g., a drum loading system, lowers and removes the drums from the tanks, whereby the drum loading system is capable of rotating the drum as well as providing an angle to the drum. The drum can be processed at an angle, for example any angle up to ±20° relative to normal, which can be understood better by referring to FIG. 7. Alternatively, the drum can be positioned 90° relative to normal with the open end up (not shown). It should be understood by the person skilled in the art that multiple drums may be going through the system and process simultaneously. In practice, GL Tank 1 (284) and GL Tank 2 (286) are filled with gold removal composition and rinse tank 1 (290) and rinse tank 2 (292) are filled with rinse liquid. A drum containing materials comprising gold is fully or partially submerged in GL Tank 1, and optionally rotated within the tanks, for time and temperature necessary to effectuate dissolution of the gold, for example, for time in a range from about 1 minute to about 60 minutes, preferably about 10 minutes to about 40 minutes, at temperature in a range from about room temperature to about 80° C., preferably about 30° C. to about 55° C. As shown in FIG. 8, the drum can be rotated from the top, the bottom, or from the side (not shown), depending on the mechanism, as understood by the person skilled in the art. The drum containing materials comprising gold is moved (e.g., using a drum loading system, which is depicted in FIG. 8 as being able to move from tank to tank (arrow A) as well as up and down (arrow B) within a tank) to GL Tank 2 (286), fully or partially submerged and optionally rotated within the tank, for time and temperature necessary to effectuate further dissolution of the gold, for example, for time in a range from about 1 minute to about 60 minutes, preferably about 10 minutes to about 40 minutes, at temperature in a range from about room temperature to about 80° C., preferably about 30° C. to about 55° C. Thereafter, the drum is moved to the dragout tank (288) to capture any excess gold removal composition for reuse in GL Tank 1 (284) or GL Tank 2 (286). The drum is then moved to rinse tank 1 (290), fully or partially submerged and optionally rotated within the tank, for time necessary to effectuate a first rinse, for example, for time in a range from about 1 minute to about 30 minutes, preferably about 1 minute to about 10 minutes. The drum is then moved to rinse tank 2 (292), fully or partially submerged and optionally rotated within the tank, for time necessary to effectuate a second rinse, for example, for time in a range from about 1 minute to about 30 minutes, preferably about 1 minute to about 10 minutes Thereafter, the drum can be moved to a drying tank (294) to dry the materials (previously) comprising gold contained therein. As described previously, the drying tank does not necessarily have to be a tank, but can comprise means to dry the materials comprising gold including, but not limited to, blown air, blown hot air, rotating the container at high rpms, and/or vibration means. All of the tanks are preferably covered (275) to minimize evaporation, e.g., the tanks can be comprised in one or more housings. As will be understood by the person skilled in the art, the drum (500), tanks (284, 286, 288, 290, 292, 294) and all lines (e.g., 277) feeding the tanks are preferably constructed from material that is compatible with the solder removal composition and temperatures used, and the tanks (284, 286, 288, 290, 292, 294) may also include heating/cooling means (not shown), air inputs (not shown), sensing means, and/or ventilation means (279). It should be appreciated that all of the tanks (284, 286, 288, 290, 292, 294) can include at least one of input/output line 277 and the depiction of input/output lines 277 in FIG. 8 is not intended to limit alternative embodiments. For example, there can be one, two, three, four, or more input/output lines into the tanks. The ventilation means (e.g., 276) can be used to condense any of the chemical fumes for reintroduction back in the module as a viable liquid as well as monitors to ensure the safety of the personnel. The entire module can be contained within an enclosure (278). The module is preferably controlled by a PLC to ensure worker safety and environmental rule compliance.

When the gold removal composition in GL Tank 1 (284) is loaded, it can be sent to electrowinning or resin-based acid recycle and metals recovery. Fresh gold removal composition can be added to GL Tank 1 (284). Preferably, when this happens, the drum is dipped in GL Tank 2 (286) prior to dipping in GL Tank 1 (284), until GL Tank 2 (286) is loaded and sent to electrowinning or resin-based acid recycle and metals recovery, at which point the order of dipping switches back to GL Tank 1 (284) and GL Tank 2 (286). A “feed and bleed” process may alternatively be used wherein clean gold removal composition is periodically introduced to the working gold removal composition with simultaneous withdrawal of some of the working gold removal composition for subsequent treatment, e.g., EW or resin-based acid recycle and metals recovery. Periodically, GL Tank 1 (284) and GL Tank 2 (286), rinse tank 1 (290), and rinse tank 2 (292) will have to be cleaned to remove precipitates and components that have fallen to the bottom of the tank during gold removal processing.

Following processing in the GL module (280), the drum is unloaded and the material that previously included gold can be collected for further processing, in house or off-site. The loaded gold removal composition and the rinse liquids that are no longer viable can be sent to electrowinning or resin-based acid recycle and metals recovery to recover the gold ions for subsequent reduction to gold metal.

Although not wanting to be bound by specifics, the GL module (280) has been built to scale and preferably can process greater than 100 kg/h of depopulated gold fingers/plastic connectors/memory boards, preferably greater than 150 kg/h, and most preferably greater than 200 kg/h

The GL module (280) is preferably controlled by PLC and the particular recipe may be selected when the materials comprising gold, which preferably were previously sorted into batches, leave the pre-sorting area or enter the GL process stream. As discussed hereinabove, the GL module (280) will be monitored in real-time, wherein the gold removal composition in both GL Tank 1 and GL Tank 2 can be sampled at least every one hour and the concentration of the chemical compounds determined, wherein the rinse water in both rinse water tank 1 and rinse water tank 2 can be sampled at least every one hour, and wherein the materials comprising gold can be sampled at least every one hour and the concentration of specific chemicals determined following solid material digestion, as readily understood by the person skilled in the art. Further, the gases evolved and all of the hardware of the GL module (280) are monitored to ensure that the module is working efficiently and safely. Additional real-time monitoring of the GL module (280) is contemplated, including, but not limited to, the monitoring of hardware and software.

It should be appreciated that the embodiment described herein is just one embodiment envisioned. Instead of a drum, the materials comprising gold can be moved from tank to tank by some other containing and moving means, whether manually or automatically. Alternatively, the materials comprising gold can be loaded into a tank and the process flow illustrated in FIG. 9 can be followed whereby the materials comprising gold are not removed from the tank until the completion of the process flow of FIG. 9. In this example, the gold removal composition and rinse liquids are introduced to, and then removed from, the tank. For example, a first gold removal composition can be introduced to the tank comprising the materials comprising gold, and then the first gold removal composition is removed from the tank following first gold removal and a second gold removal composition can be introduced to the tank and removed from the tank following second gold removal, while the materials comprising gold remain in the tank. Thereafter, dragout or the equivalent thereof can occur, followed by the introduction of a first rinse liquid to the tank and removal of the first rinse liquid following the first rinse, and introduction of a second rinse liquid to the tank and removal of the second rinse liquid following the second rinse. Thereafter, the materials (previously) comprising gold can optionally be dried. Other embodiments can be envisioned by the person skilled in the art.

In one aspect, a gold leaching (GL) module to remove gold from materials comprising gold is described, said GL module (280) comprising:
a system comprising at least at least one gold removal tank, at least one dragout tank, and at least one rinsing tank, wherein each tank has the volumetric capacity to contain a containing means, e.g., drum, therein,
   wherein the system comprises moving means to move the containing means, e.g., drum, from tank to tank, e.g., from the at least one gold removal tank to the at least one dragout tank to the at least one rinsing tank or any other order necessary to remove gold from materials comprising gold, wherein the materials comprising gold are selected from the group consisting of gold fingers, connectors comprising gold, memory boards, any other components having gold value, and any combination thereof. In practice, the materials comprising gold are manually or automatically introduced to the containing means, e.g., drum, for processing. The containing means, e.g., drum, can be serially moved from tank to tank using moving means, complete with full or partial submersion of the containing means, e.g., drum, in the at least one gold removal tank and the at least one rinsing tank. The at least one gold removal tank can comprise gold removal composition. Each tank can comprise one or more of: agitation means; at least one filter; real-time sampling and adjustment; a cover to minimize evaporation; heating/cooling means; air inputs; sensing means; ventilation means; and any combination thereof. The system can further comprise at least one drying tank. The GL module (280) can be controlled by a PLC.

In another aspect, a process of removing gold from materials comprising gold is described, said process comprising:
(a) loading materials comprising gold into a containing means, e.g., drum;
(b) removing gold from materials comprising gold using a system, wherein the system comprises at least at least one gold removal tank, at least one dragout tank, and at least one rinsing tank,
wherein each tank has the volumetric capacity to contain a containing means, e.g., drum, therein, wherein the system comprises moving means to move the containing means, e.g., drum, from tank to tank, e.g., from the at least one gold removal tank to the at least one dragout tank to the at least one rinsing tank or any other order necessary to remove gold from materials comprising gold, and
wherein the materials comprising gold are selected from the group consisting of gold fingers, connectors comprising gold, memory boards, any other components having gold value, and any combination thereof.
   The containing means, e.g., drum, can be serially moved from tank to tank using moving means, complete with full or partial submersion of the containing means, e.g., drum, in the at least one gold removal tank and the at least one rinsing tank. Each tank can comprise one or more of: agitation means; at least one filter; real-time sampling and adjustment; a cover to minimize evaporation; heating/cooling means; air inputs; sensing means; ventilation means; and any combination thereof. The system can further comprise at least one drying tank. The containing means, e.g., drum, can be fully or partially submerged in the at least one gold removal tank comprising a gold removal composition for time in a range from about 1 minute to about 60 minutes, preferably about 10 minutes to about 40 minutes, at temperature in a range from about room temperature to about 80° C., preferably about 30° C. to about 55° C. The containing means, e.g., drum, can be fully or partially submerged in the at least one rinsing tank for time in a range from about 1 minute to about 30 minutes, preferably about 1 minute to about 10 minutes. The GL module (280) can be controlled by a PLC and the process of removing gold from materials comprising gold can be subject to a recipe specific to what is being processed, as dictated by the PLC.

### SPT Furnace Module

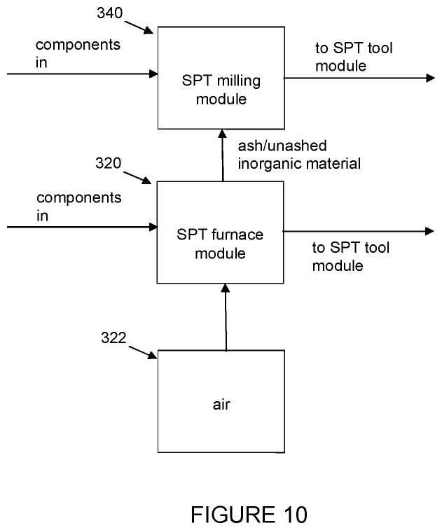

Recyclable components and/or memory boards that have been manually or automatically removed from the PCBs (e.g., the pre-BCM and/or BCM) and/or have been removed in the DS module (260) can be further processed to remove precious metals. In one embodiment, the recyclable components and/or memory boards may be collected and can be sent to a SPT furnace module (320) (see, FIG. 10) to ash the components, thereby increasing the surface area of the recyclable components and/or memory boards that is exposed to further processing in the SPT tool module (360) or equivalent thereof. This has the benefit of higher metal removal efficiencies, particularly precious metal from the recyclable components and/or memory boards. The recyclable components include, but are not limited to, IC chips, microcomponents, and combinations thereof.

In one embodiment, the SPT furnace module (320) comprises a furnace or some other heating means, and means to control the air input into the furnace. In a further embodiment, the SPT furnace module (320) may operate in a continuous and/or batch mode and comprises a furnace, means to feed and/or load the furnace with recyclable components and/or memory boards, and means to control the air input (322) into the furnace. Regardless of the embodiment, the recyclable components and/or memory boards may be crushed prior to or after introduction to the furnace. The type, size and/or capacity of the furnace can be readily determined by one skilled in the art based on factors including, but not limited to, operating temperature, footprint, throughput, capacity, weight, type of material to be ashed and combinations of the foregoing. The furnace comprises one or more heating elements. Preferably, the heating element is electric and comprises one or more materials including, but not limited to, metal, metal alloys, metal superalloys, ceramics, composites and combinations of the foregoing. More preferably, the heating element comprises one or more alloy materials including, but not limited to, Inconel, Monel, Hastelloy, Incoloy, Waspaloy, Rene, Haynes, MP98T, TMS, CMSX Field Code Chan and combinations of the foregoing. Examples of useful furnaces include, but are not limited to, top loading furnaces, bottom loading furnaces, front loading furnaces, continuous furnaces, bench furnaces, batch furnaces, truck in furnaces, box furnaces, belt furnace, shelf furnaces, truck in furnaces, elevator furnaces, tunnel furnaces, bell furnaces, pusher furnaces, tube furnaces, shaker furnaces and combinations of the foregoing. The furnace may comprise fixed and/or adjustable parameters that may operate manually or automatically including, but not limited to, throughput, weight, capacity, temperature, temperature ramp rate, time, air flow, pressure, ventilation and combinations of the foregoing.

In an embodiment, the furnace includes means to control the air input into the furnace because the furnace ashes the recyclable components and/or memory boards at high temperatures, e.g., in a range from about 500° C. to about 800° C., preferably about 600° C. to about 700° C. For example, the furnace may require a supply of air provided at a known minimum airflow. If the airflow is too low combustible gases may build up and/or the casings on the recyclable components and/or memory boards may become brittle and remain intact, which will impact the efficiency of recovery. Accordingly, the SPT furnace may comprise means to control the direction, rate and/or flow of air through the furnace including, but not limited to, one or more blowers, fans, dampers, ducts, air curtains, air guides, baffles and combinations of the foregoing. Further, pressure sensors, flow sensors, gas sensors (e.g., O₂ sensor), and/or temperature sensors can be included to control and regulate one or more components in the effluent.

The furnace preferably includes a ventilation and/or abatement system to handle combustible gases and any ash material that may become airborne. In one embodiment, the ventilation system can or may include an electrostatic precipitator or some filtering system. Further, the furnace shall be in compliance with local fire and air quality codes.

The means to feed the furnace with recyclable components and/or memory boards may be automatic or manual and may include at least one of the moving means described herein. Further, the recyclable components and/or memory boards may be fed individually or in one or more batches into the furnace. Batches of recyclable components and/or memory boards may be formed in the furnace as the recyclable components and/or memory boards are fed into the furnace. The recyclable components and/or memory boards may be fed into the furnace on one or more support surfaces that support the individual or batch of recyclable components and/or memory boards or the recyclable components and/or memory boards may be fed onto one or more support surfaces already in the furnace. “Support surfaces” include, but are not limited to, racks, shelves, trays, containers and combinations of the foregoing. Preferably, the recyclable components and/or memory boards are arranged on one or more trays having a base surface and a sidewall having a height that extends above the base surface. Further the one or more trays may be solid and/or perforated. The height of the tray sidewall is selected so as to maximize the efficiency of the ashing process and may be selected based on one or more process parameters including but not limited to weight, capacity, temperature, time, air flow, pressure, ventilation and combinations of the foregoing. In one embodiment, the tray sidewall height is from between about 1 mm and about 15 cm. Preferably, the furnace is a batch furnace that includes one or more racks and can accommodate one or more trays. The recyclable components and/or memory boards are manually or automatically placed on/in the trays and the trays can be manually or automatically loaded in the furnace. In one embodiment, the depth of recyclable components and/or memory boards in the trays is from about 1 mm to about 10 cm, preferably about 1 cm to about 3 cm. The furnace and trays should be constructed from a material that will withstand the temperatures, pressures, and VOCs of the ashing process and will not be a source of contamination during the heating/cooling processes.

The furnace can be cooled to ambient temperatures following ashing, either with the assistance of refrigeration, the introduction of air to the furnace, by uncontrolled cooling to ambient temperature, or any other means of cooling, as understood by the person skilled in the art.

Preferably, the SPT furnace module ashes the recyclable components and/or memory boards based on at least one process recipe that is based on one or more parameters that may be manually or automatically input including, but not limited to, throughput, weight of recyclable components and/or memory boards, capacity of the furnace, temperature, temperature ramp rate, cycle time, air flow, pressure, ventilation and combinations of the foregoing, Preferably the process recipe is selected by a PLC that controls one or more functions of the SPT furnace module to ash greater than 80%, preferably greater than 95%, of the ashable content of the recyclable components and/or memory boards. In one embodiment, the process recipe includes a programmable temperature/time profile that is based on one or more of type, weight and amount of recyclable components and/or memory boards to be ashed. The temperature/time profile for the SPT furnace process may include, but is not limited to, preheating, the rate of continuous temperature ramping, ramp/hold, the rate of stepped temperature ramping, the rate of staged temperature ramping, and combinations of the foregoing. In one embodiment, the ashing process operates at a temperature from about 250° C. to about 800° C. from about 1 hour to about 8 hours.

Preferably, the ashed materials have size in a range from about 1 to about 3000 microns. That said, it should be appreciated that there will be circumstances where not all of the recyclable components and/or memory boards will be reduced to ash in the furnace. Some recyclable components and/or memory boards include non-ashable inorganic materials. The material remaining following processing in the SPT furnace module (320) can be sent to further processing in the SPT tool module (360) or can be sent to the SPT milling module (340), or eventually both, as readily determinable by the person skilled in the art. The material can be moved to the next module in a container, automatically or manually, on a one or more moving means. In one embodiment, no separation of the inorganic materials from the ash occurs prior to further processing. In another embodiment, the inorganic materials are separated from the ash prior to further processing.

In one aspect, a SPT furnace module (320) is described, said SPT furnace module (320) comprising (a) a furnace and (b) means to control the air input into the furnace, wherein the SPT furnace module converts recyclable components and/or memory boards into ash or powder. The furnace is capable of ashing the recyclable components and/or memory boards at high temperatures, e.g., in a range from about 250° C. to about 800° C. The furnace preferably includes a ventilation system to handle combustible gases and any ash that may become airborne. The SPT furnace module can further include support surfaces, e.g., racks, shelves, trays, containers and combinations of the foregoing within the furnace as well as moving means as defined herein. Preferably, the SPT furnace module converts at least about 80% of the ashable content of the recyclable components and/or memory boards should have been reduced to ask More preferably, the SPT furnace module converts at least about 95% of the ashable content of the recyclable components and/or memory boards to ash.

In another aspect, a process of converting recyclable components and/or memory boards to ash in a SPT furnace module is described, said process comprising:
(a) feeding the recyclable components and/or memory boards into a furnace; and
(b) heating the recyclable components and/or memory boards in the furnace to a temperature of from about 250° C. to about 800° C. until from about 80% to greater than 95% of the ashable content of the recyclable components and/or memory boards has been reduced to ask
   The furnace can comprise means to control the air input into the furnace and optionally a ventilation system. The furnace can heat to at least about 250° C. to about 800° C. The furnace can be fed with recyclable components and/or memory boards using support surfaces, e.g., racks, shelves, trays, containers and combinations of the foregoing. Alternatively, or in addition, the furnace can be fed with recyclable components and/or memory boards using moving means as defined herein.

### SPT Milling Module

As previously introduced, not all of the components and memory boards are reduced to ash in the SPT furnace module (320). Some components and memory boards will include inorganic materials that are not combustible in the furnace. Further, there are instances where chips and microcomponents, e.g., from the pre-BCM module (220), from the BCM module (240), and/or from the DS module (260), do not require ashing for efficient processing of same to extract precious metals. Accordingly, grinding or milling means can be used to prepare the components and memory boards, or ash from the SPT furnace module (320), for further processing. The grinding means include, but are not limited to, an industrial grinder. The milling means include, but are not limited to, a hammermill, a wet ball mill, etc. The grinding or milling means preferably include a dust recovery system. The components and memory boards, or cooled ash material which comprises unashed inorganic material, is introduced to a grinding or milling means and the materials are ground into smaller pieces, for example, less than 10 mesh (1.70 mm), more preferably less than 20 mesh (0.85 mm), and most preferably less than 30 mesh (0.60 mm). The grinding or milling means should be equipped with a dust recovery system because of the ash that can be stirred up during the grinding or milling process. Preferably the dust recovery system is capable of capturing dust so that it can be collected and processed. In addition, the grinding or milling means preferably includes means to load and unload solids therein, e.g., containing means and/or moving means. For example, the components and memory boards, or cooled ash material comprising unashed inorganic particles may be loaded into the grinding or milling means using a conveyor or screw feed.

The material remaining following processing in the SPT milling module (340) can be sent to further processing in the SPT tool. The material can be moved to the next module in a container, e.g., a hopper, automatically or manually, on one or more moving means.

### SPT Tool Module

Following processing in the SPT furnace module (320) and/or the SPT milling module (340), the material, hereinafter the solid, can enter an SPT tool module (360). The SPT tool module (360) is preferably in series with the SPT furnace module (320), and/or the SPT milling module (340), with or without intervening processing, as readily understood by the person skilled in the art. The SPT tool module (360) is designed to remove metals, e.g., base metals and precious metals, from the solid. In one embodiment, the SPT tool module (360) removes one or more base metals from the solid. In another embodiment, the SPT tool module (360) removes one or more precious metals from the solid. In another embodiment, the SPT tool module (360) removes gold from the solid. In still another embodiment, the SPT tool module (360) removes one or more base metals and one or more precious metals from the solid. In a further embodiment, the SPT tool module (360) removes one or more base metals and gold from the solid. In another embodiment, the SPT tool module (360) removes one or more base metals and silver from the solid. In still another embodiment, the SPT tool module (360) removes one or more base metals, gold and silver from the solid. Any combination of metals is contemplated herein. In one embodiment, the base metals are selectively removed so that subsequent processing for the precious metals is more efficient. It should be appreciated that solids can be sent to the SPT tool module (360) for processing even if the solids were not previously processed in the SPT furnace and/or SPT milling module (340). For example, the solids could have been ashed, milled and/or ground in an earlier step, or milled and/or ground off site. Alternatively, or in addition to, the solids correspond to whole components that have been crushed or treated in any manner that exposes the one or more base metals and/or one or more precious metals of the interior of the component to the removal composition. Accordingly, as defined herein, the “solid” referred to in the SPT tool module (360) corresponds to material from the SPT furnace module (320), the SPT milling module (340), some other ashing process, some other grinding/milling process, components that have been crushed, or material that has been through one SPT tool module (360) (e.g., SPT base metal removal module (380), SPT gold removal module (400), SPT silver leaching module (420)) and is intended to be processed in at least one of the remaining SPT tool module (360).

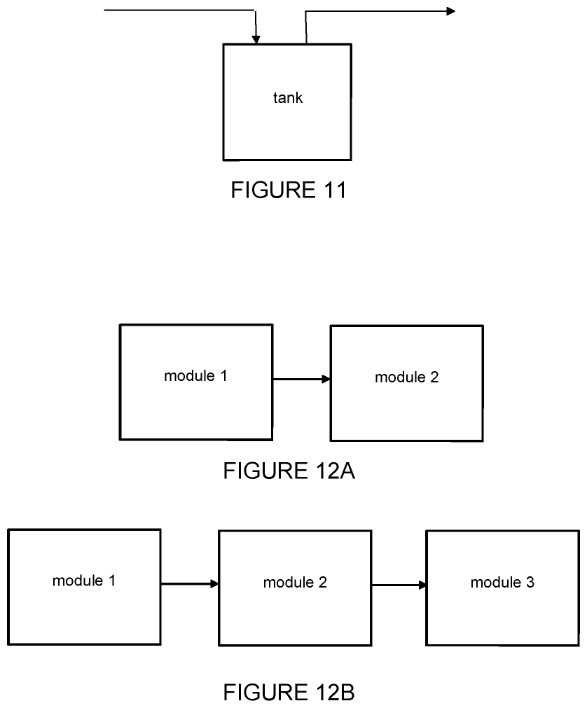

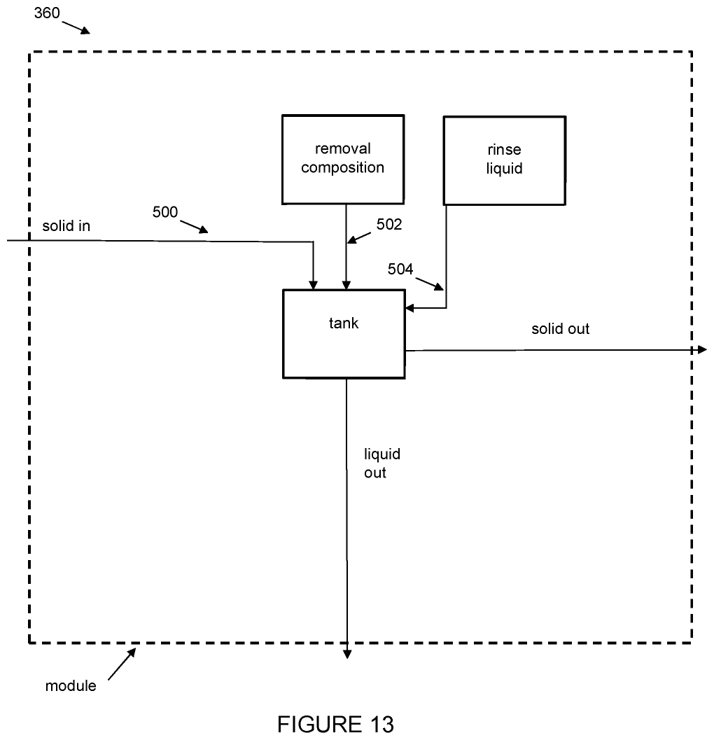

A general schematic of the SPT tool module is illustrated in FIG. 11. The SPT tool module requires at least one tank where a solid comprising metals to be removed is contacted with a removal composition to form a slurry and a chemical reaction occurs to remove at least one metal from the solid. Rinsing can also occur within this at least one tank. The SPT tool module relies on dissolution or solubilization of at least one metal in a removal composition and the subsequent treatment of the removal composition and/or rinse liquid to convert metal ions contained therein to solid metal. The at least one tank must be adapted for receiving solid and at least one removal composition. Preferably the tank comprises one or more lines for the passage of liquid and/or solids into and/or out of the tank, a heating/cooling system, air inputs, ventilation means, sensing means, and optionally agitation means. In one embodiment, the at least one tank can have at least one input line for the passage of liquid and/or solids into the tank, at least one output line for the passage of liquid and/or solids out of the tank, a heating/cooling system, air inputs, sensing means, ventilation means, and optionally agitation means. The at least one line can have a pump associated with it to assist with the movement of liquids, solids, a slurry, or any combination thereof. The system can be computer operated, e.g., using a PLC, so that the timing of the solids and liquids into and out of the tank can be carefully controlled. It is contemplated that all solids and liquids go into the at least one tank via the same input line, wherein there are valves, lines, sensors, and/or other containers upstream that allow for the controlled introduction of solid, removal composition and rinse solutions, as needed, via the input line. Alternatively, there can be more than one input line into the at least one tank, for example, a removal composition line (500), at least one rinse line (502), and/or a solid introduction line (504) (see, e.g., FIG. 13). It is also contemplated that all liquids exit the at least one tank via the same output line, wherein there may be valves, lines, and other containers downstream that allow for the direction of loaded reaction solution, rinse solutions, and solid into containers. Alternatively, there can be more than one output line from the at least one tank, for example, a loaded removal composition line, at least one rinse line, and/or at least one solid removal line. Regardless of the number of input and output lines, any or all of them can have a pump associated therewith. The at least one tank is preferably enclosed in one or more housings.

In one embodiment, the at least one tank of FIG. 11 is used to remove gold from a solid. It is contemplated that the removal composition may remove multiple metals at once, in addition to gold. Accordingly, downstream processing to separate the gold ions from the other metal ions in the loaded removal composition would have to be used. For example, EW, DD, resin-based acid recycle and metals recovery (e.g., ISE), precipitation, pH adjustment, cementation, and/or extraction are contemplated to remove the gold ions from the loaded removal composition.

It is further contemplated that the at least one tank of FIG. 11 can be used to remove and/or reclaim more than one metal. For example, the solid can be contacted with a removal composition to remove at least one base metal, followed by rinsing, and thereafter the solid can be contacted with a removal composition to remove a precious metal, e.g., using a gold removal composition and/or a silver removal composition, followed by more rinsing. It is contemplated that the at least one tank can be used to remove at least any two or three of base metals, gold, and silver. Again, all liquids and/or solids can enter the at least one tank via at least one line for the passage of liquid and/or solids into and/or out of the tank. Alternatively, all liquids and/or solids can enter the at least one tank via at least one input line and out via at least one output line. The SPT tool module (360) is preferably controlled by PLC and the particular processing recipe used may be selected based on the solid (e.g., what components were converted to ash and/or ground material) introduced, which preferably are introduced to the SPT tool module (360) in batches.

### Individual Metal Removal Modules

Although simple in theory, the SPT tool module (360) of FIG. 11 is not as efficient or cost effective relative to the following to reclaim precious metals. Firstly, the removal composition often depends on the metal to be removed and/or reclaimed, and may comprise one or more chemical constituents that are corrosive and/or hazardous. Accordingly, the reaction tank and system components upstream and/or downstream of the reaction tank preferably comprise materials of construction that are different from other components in the system. In one embodiment, one or more reaction tanks is/are constructed from one or more materials that are compatible with the most demanding, e.g., corrosive, removal composition. In another embodiment, one or more reaction tanks is constructed from one or more materials that are compatible with the most demanding removal composition, and further comprises one or more of heating and/or cooling means, agitation means, ventilation means, sensing means, and air input means. Secondly, one removal composition may not be compatible with another removal composition and any risk of interaction should be eliminated Thirdly, for maximum efficiency, certain reactions may have a holding period to enable complete reaction, leaching, and/or dissolution, and as such the at least one tank must be rated to accommodate this reaction, however, it is a waste of resources to carry out the complete reaction, leaching, dissolution, rinsing, in the reaction tank. Fourthly, to maximize efficiency of the metal reclamation process, the solid and respective removal composition should be separated, e.g., using liquid-solid separation means, after contact. The solid and rinse compositions should be separated using liquid-solid separation means as well. Accordingly, preferably the SPT tool module (360) comprises individual metal removal modules, for example, a SPT base metal removal module (380), a SPT gold removal module (400), and/or a SPT silver leaching module (420). The individual metal removal modules can be operated in series (for example, as shown in FIGS. 12A and 12B) and/or in parallel, with or without intervening processing, processing different batches of e-waste concurrently, as readily understood by the person skilled in the art. The solid can be moved from one module to another and/or within a module using one or more containing means, as defined herein, coupled with one or more moving means, as defined herein. Alternatively, the solid can be moved from module to module and/or within a module using containing means in combination with loading means, in combination with moving means, as described herein.

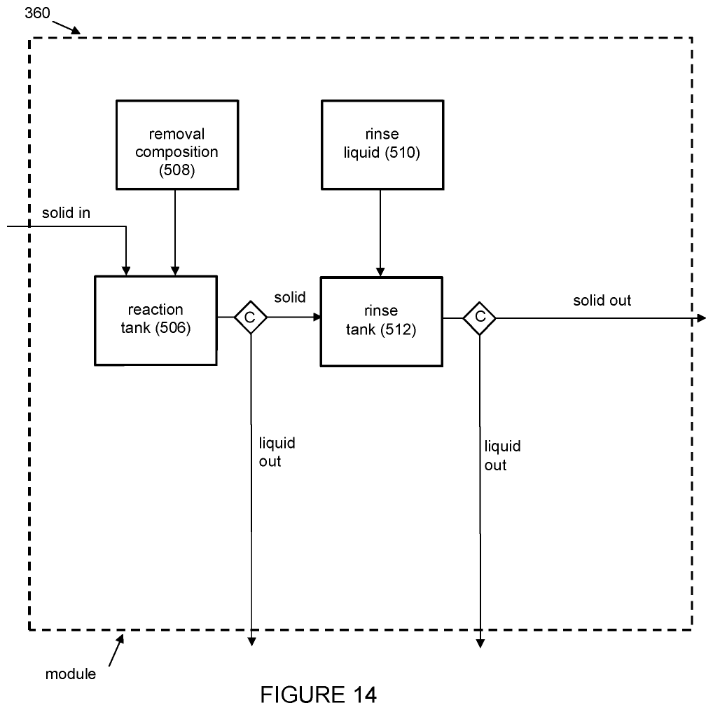

An example of a module (e.g., a SPT base metal removal module (380), a SPT gold removal module (400), a SPT silver leaching module (420)) is shown in FIG. 14. In this module, there are four tanks shown; a reaction tank (506), a rinse tank (512), a removal composition tank (508), and a rinse liquid tank (510). One or more tanks may comprise at least one of a heating/cooling system, air inputs, ventilation means, sensing means, and agitation means. The solid and the removal composition (508) are introduced to the reaction tank (506) via input lines, to form a slurry, and after the reaction is complete, the slurry comprising the removal composition and reacted solid is moved to a centrifuge, as depicted by the “C.” The time of a complete reaction is dependent on several factors including, but not limited to, the solids being processed (e.g., which components made up the solids being processed), the temperature of processing, the weight of the solid being processed, and the amount and concentration of removal composition needed to extract or remove about 65-100% of the particular metal in the solid. Using centrifugation, the removal composition is separated from the reacted solid and the reacted solid is introduced into a rinse tank (512). The removal composition can be sent to processing or can be reused, which is dependent on the metal ions removed and the respective removal composition, as described herein below. A rinse liquid (510), e.g., water, is also introduced to the rinse tank (512) and the reacted solid is rinsed using the rinse liquid. Once the rinse is complete, as readily determined by the person skilled in the art, the slurry comprising the rinsed solid and the rinse liquid is moved to a centrifuge, either a different centrifuge or the previously used centrifuge, for separation of the rinsed solid from the rinse liquid. Following centrifugation, the rinse liquid is separated from the rinsed solid and the rinsed solid can exit the specific module. The rinse liquid can be sent to processing or can be reused, which is dependent on the metal ions removed, as described herein below. In one embodiment, a letdown chute, with split control or rotatable, coupled to a centrifuge may be used to move the solid from tank to tank and a PLC or other computer means may be used to automatically move the chute as needed. It should be understood by the person skilled in the art that the materials of construction of the tanks, input lines, output lines, centrifuge, and other tool components should be rated to ensure that the materials do not react with the respective removal composition. Advantageously, this means that the rinse tank (512) and all associated lines may be comprised of the same or different material than the reaction tank (506) and all associated lines, given the potentially less corrosive environment of the rinse tank (512). One or more tanks can include agitation means as previously described. Regardless of the number of input and output lines, any or all of them can have a pump associated therewith. In a preferred embodiment, the tanks are enclosed in one or more housings. The SPT tool module (360) of FIG. 14 is preferably controlled by PLC and a particular processing recipe used based on the solid introduced as well as the metal being removed.

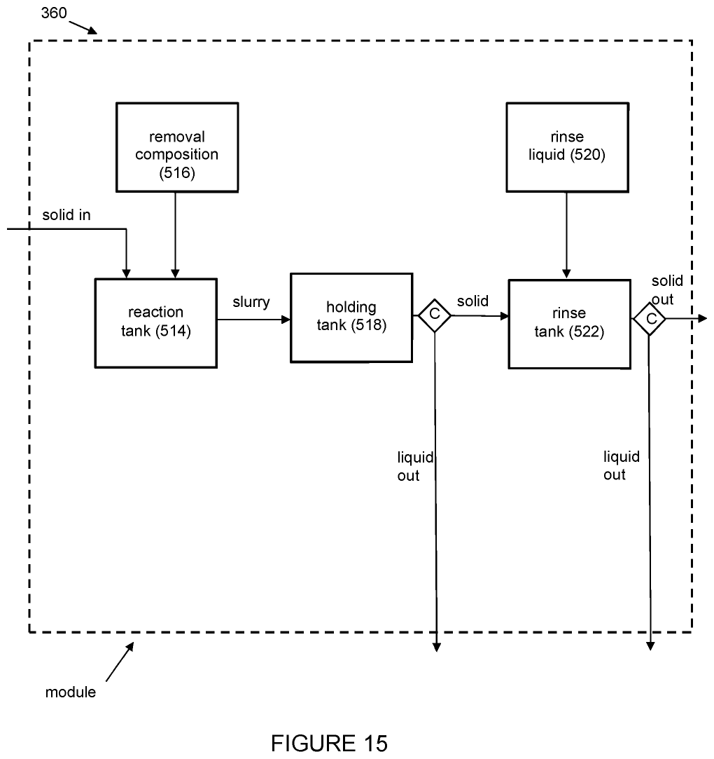

Another example of a module (e.g., a SPT base metal removal module (380), a SPT gold removal module (400), a SPT silver leaching module (420) is shown in FIG. 15. In this module, there are at least five tanks; a reaction tank (514), a holding tank (518), a rinse tank (522), a removal composition tank (516), and a rinse liquid tank (520). The tanks may be constructed from the same or different materials. In one embodiment, the reaction tank (514) preferably comprises materials of construction that are compatible with the most demanding, e.g., corrosive, removal composition. In another embodiment, the reaction tank (514) is constructed from one or more materials that are compatible with the most demanding removal composition, and further comprises at least one of heating and/or cooling means, agitation means, ventilation means, sensing means, and air input means. The solid and the reaction composition (516) are introduced to the reaction tank (514) via one or more input lines and after time x, which corresponds to a point where the substantial majority of the reaction has occurred, as readily determined by the person skilled in the art, the slurry comprising the solid and removal composition is moved to the holding tank (518). In one embodiment, time x may be determined based on a reaction tank temperature measured, a certain amount of time passed, a measurement of a concentration of a consumed chemical constituent, visual inspection, end point detection, a pH value measured, to name a few. The determination of time x can be controlled by a PLC, with or without a specific process recipe. The chemical reaction between the solid and the removal composition is completed in the holding tank (518). Following substantial completion of the chemical reaction, the slurry comprising the removal composition and reacted solid is moved to a centrifuge. The time of a complete reaction is dependent on several factors including, but not limited to, the solids being processed (e.g., which components made up the solids being processed), the temperature of processing, the weight of the solid being processed, and the amount and concentration of removal composition needed to extract or remove about 65-100% of the particular metal in the solid. Using centrifugation, the removal composition is separated from the reacted solid and the reacted solid is introduced into a rinse tank. The removal composition can be sent to processing or can be reused, which is dependent on the metal ions removed and the respective removal composition, as described herein below. A rinse liquid (520), e.g., water, is also introduced to the rinse tank (522) and the reacted solid is rinsed using the rinse liquid. Once the rinse is complete, as readily determined by the person skilled in the art, the slurry comprising the rinsed solid and the rinse liquid is moved to a centrifuge, either a new centrifuge or the previously used centrifuge. Following centrifugation, the rinse liquid is separated from the rinsed solid and the rinsed solid can exit the specific module. The rinse liquid can be sent to processing or can be reused, which is dependent on the metal ions removed, as described herein below. It is contemplated herein that a letdown chute, with split control or rotatable, coupled to a centrifuge may be used to move the solid from tank to tank and a PLC or other computer means may be used to automatically move the chute as needed. It should be understood by the person skilled in the art that the materials of construction of the tanks, input lines, output lines, and centrifuge should be rated to ensure that the materials do not react with the removal composition. Advantageously, this means that the rinse tank (522) and all associated lines may be comprised of the same or different material than the reaction (514) and holding tank (518) and all associated lines given the potentially less corrosive environment of the rinse tank. One or more tanks can include agitation means as previously described. Regardless of the number of input and output lines, any or all of them can have a pump associated therewith. In a preferred embodiment, the tanks are enclosed in one or more housings. The SPT tool module (360) of FIG. 15 is preferably controlled by PLC and a particular processing recipe used based on the solid introduced as well as the metal being removed.

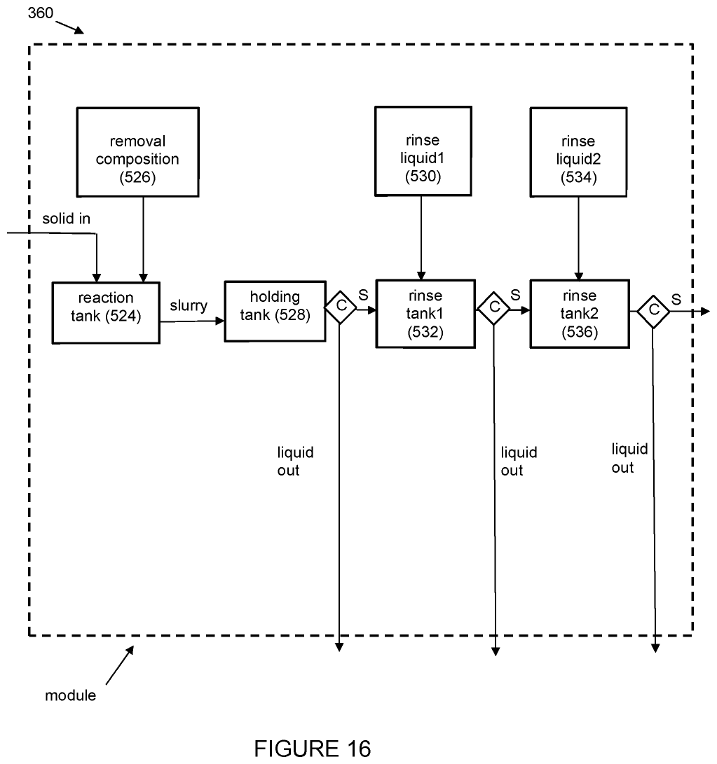

Another example of a module is shown in FIG. 16. In this module, there are seven tanks; a reaction tank (524), a holding tank (528), two rinse tanks (532,536), a removal composition tank (526), and two rinse liquid tanks (530, 534). The solid and the reaction composition (526) are introduced to the reaction tank (524) via one or more input lines and after time x, which corresponds to a point where the substantial majority of the reaction has occurred, as readily determined by the person skilled in the art, the slurry comprising the solid and removal composition is moved to the holding tank (528). In one embodiment, time x may be determined based on a reaction tank temperature measured, a certain amount of time passed, a measurement of a concentration of a consumed chemical constituent, visual inspection, end point detection, a pH value measured, to name a few. The determination of time x can be controlled by a PLC, with or without a specific process recipe. The chemical reaction between the solid and the removal composition is completed in the holding tank (528). Following substantial completion of the chemical reaction, the slurry comprising the removal composition and reacted solid is moved to a centrifuge. The time of a complete reaction is dependent on several factors including, but not limited to, the solids being processed (e.g., which components made up the solids being processed), the temperature of processing, the weight of the solid being processed, and the amount and concentration of removal composition needed to extract or remove about 65-100% of the particular metal in the solid. Using centrifugation, the removal composition is separated from the reacted solid and the reacted solid is introduced into rinse tank 1 (532). The removal composition can be sent to processing or can be reused, which is dependent on the metal ions removed and the respective removal composition, as described herein below. Rinse liquid 1 (530), e.g., water, is also introduced to the rinse tank 1 (532) and the reacted solid is rinsed using the first rinse liquid. Once the first rinse is complete, as readily determined by the person skilled in the art, the slurry comprising the first rinsed solid and the first rinse liquid is moved to a centrifuge, either a new centrifuge or the previously used centrifuge. Using centrifugation, the first rinse liquid is separated from the first rinsed solid and the first rinsed solid is introduced into a second rinse tank. A rinse liquid 2 (534), e.g., water, which may be the same as or different from rinse liquid 1, is also introduced to the rinse tank 2 (536) and the first rinsed solid is rinsed using the second rinse liquid. Once the second rinse is complete, as readily determined by the person skilled in the art, the slurry comprising the second rinsed solid and the second rinse liquid is moved to a centrifuge, either a new centrifuge or the previously used centrifuge. Following centrifugation, the second rinse liquid is separated from the second rinsed solid and the second rinsed solid can exit the specific module. The first and second rinse liquid can be sent to processing or can be reused, which is dependent on the metal ions removed, as described herein below. It is contemplated herein that a letdown chute, with split control or rotatable, coupled to a centrifuge may be used to move the solid from tank to tank and a PLC or other computer means may be used to automatically move the chute as needed. It should be understood by the person skilled in the art that the materials of construction of the tanks, input lines, output lines, and centrifuge should be rated to ensure that the materials do not react with the respective removal composition. Advantageously, this means that the rinse tanks (532, 536) and all associated lines may be comprised of the same or different material than the reaction (524) and holding tank (528) and all associated lines, given the potentially less corrosive environment of the rinse tanks Each tank can include agitation means as previously described. Regardless of the number of input and output lines, any or all of them can have a pump associated therewith. In a preferred embodiment, the tanks are enclosed in one or more housings. The SPT tool module (360) of FIG. 16 is preferably controlled by PLC and a particular processing recipe used based on the solid introduced as well as the metal being removed.

It is contemplated that the module can comprise at least one reaction tank, at least one holding tank, and at least one rinse tank, in any iteration, as understood by the person skilled in the art. For example, in addition to FIGS. 13-16, the module can comprise one reaction tank, two holding tanks, and one rinse tank in addition to the removal composition tank(s) and the rinse liquid tank(s). Further, as will be discussed next, the module can comprise one reaction tank, two holding tanks, and two rinse tanks in addition to the removal composition tank(s) and the rinse liquid tank(s). An embodiment will be discussed that includes one reaction tank, two holding tanks, and three rinse tanks in addition to the removal composition tank(s) and the rinse liquid tank(s).

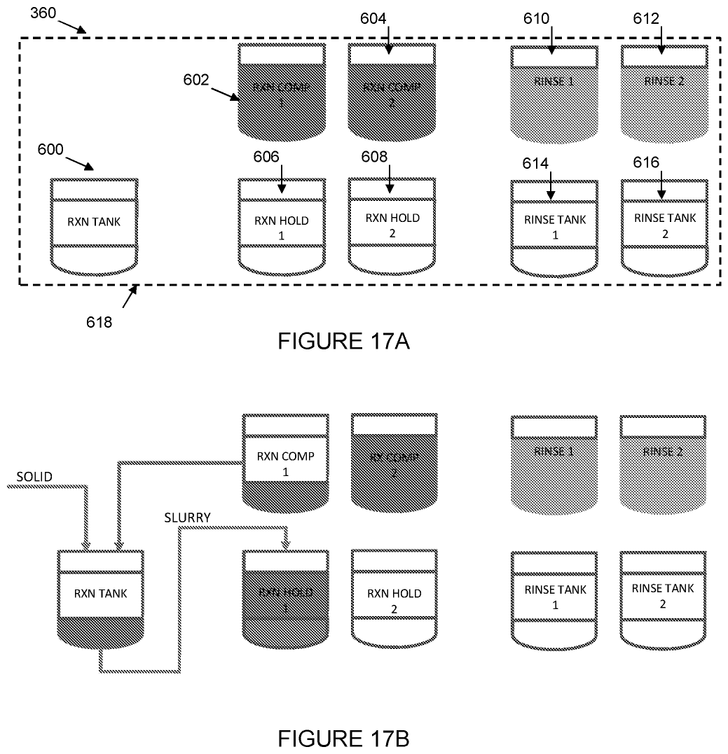

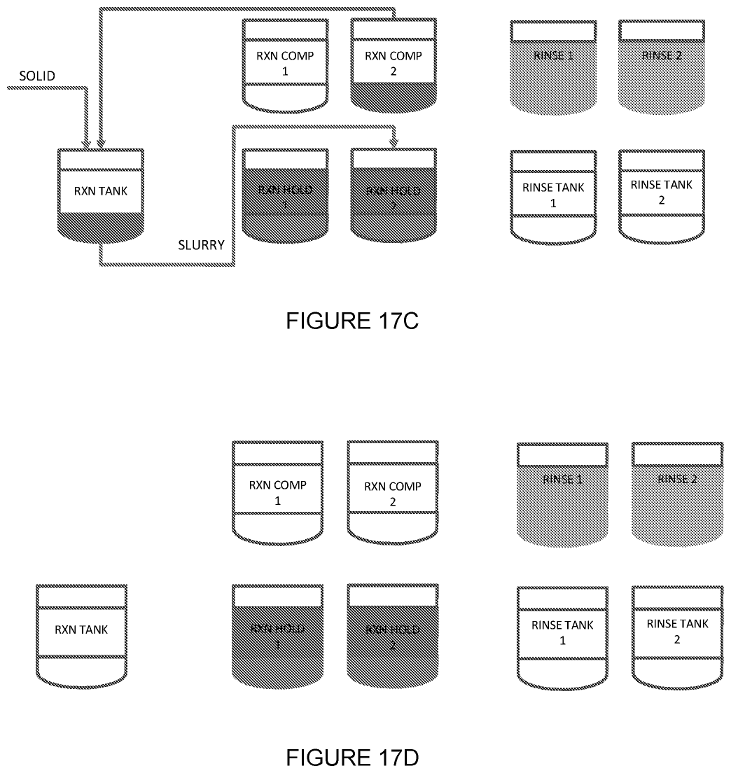

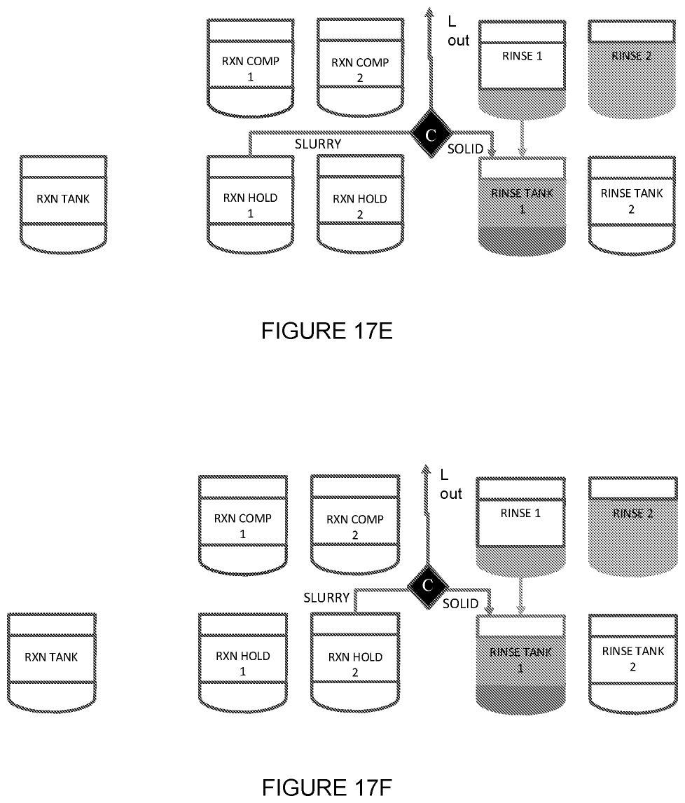

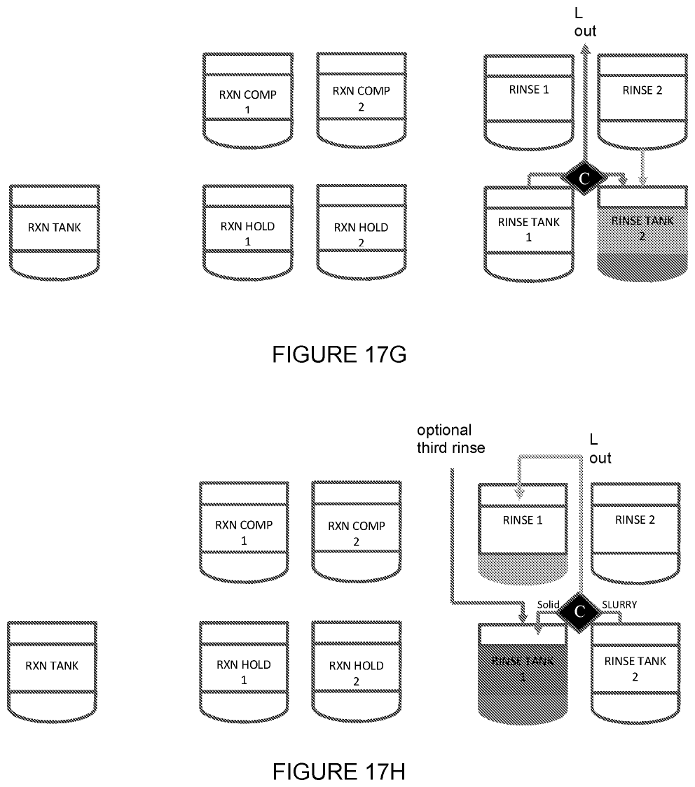

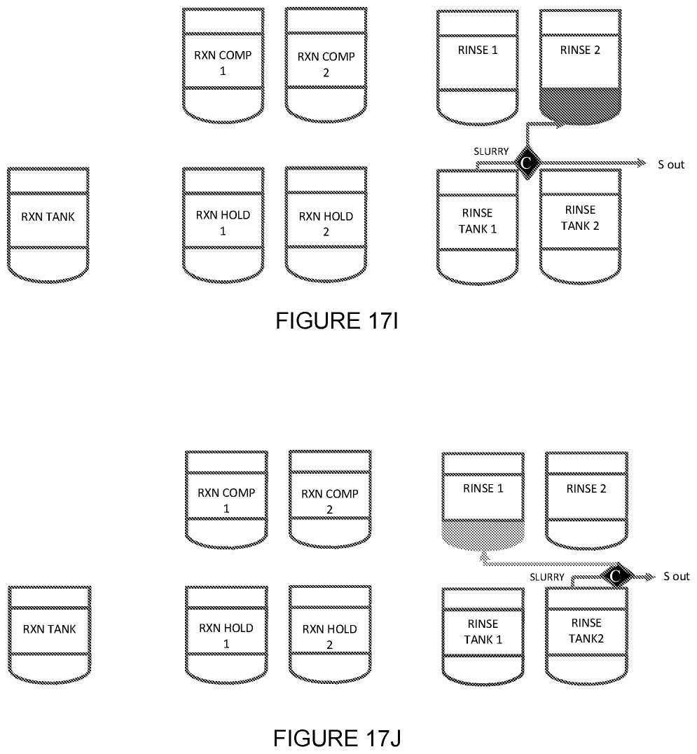

A specific embodiment of an SPT tool module (360) is shown in FIGS. 17A-17J. In this embodiment, each module has a total of at least nine tanks, as shown in FIG. 17A, wherein the reaction tank is labeled “RXN TANK” (600), a first holding tank is labeled “RXN HOLD 1” (606), a second holding tank is labeled “RXN HOLD 2” (608), a first amount of removal composition tank is labeled “RXN COMP 1” (602), a second amount of removal composition tank is labeled “RXN COMP 2” (604), a first rinse tank is labeled “RINSE TANK 1” (614), a second rinse tank is labeled “RINSE TANK 2” (616), a first rinse liquid is labeled “RINSE 1” (610) and a second rinse liquid is labeled “RINSE 2” (612). One or more tanks may be interconnected, wherein any or all of the interconnecting lines can have a pump associated therewith. In a preferred embodiment, the tanks are enclosed in one or more housings (618). The removal composition in RXN COMP 1 and the removal composition in RXN COMP 2 may be substantially the same, meaning that they may be intended to remove the same metal(s) and hence comprise the same chemical constituents. Differences between the two removal compositions may be based on factors including, but not limited to, the number of times of reuse and/or the pH adjustments, chemical constituent spiking and hence how fresh the removal composition chemistry is. In one embodiment, a volume of removal composition is divided such that half the volume goes to RXN COMP1 and the other half goes to RXN COMP2. In another embodiment, a volume of removal composition is prepared and introduced into RXN COMP1 and a separate volume of removal composition is prepared and introduced into RXN COMP2. In still another embodiment, a volume of reusable removal composition is divided such that half the volume goes to RXN COMP1 and the other half goes to RXN COMP2. In another embodiment, a volume of reusable removal composition is sent to RXN COMP1 and a separate volume of reusable composition is sent to RXN COMP2. The SPT tool module (360) of FIGS. 17A-17J is preferably controlled by PLC and a particular processing recipe used based on the solid introduced as well as the metal being removed.

In practice,
a. An amount of solid (S1) and RXN COMP 1 enters the RXN TANK (see, FIG. 17B). The solid (S1) and RXN COMP 1 are mixed to form a slurry. Following the appropriate time, i.e., time x1, the slurry comprising the solid S1 and the removal composition is moved to RXN HOLD 1 for substantial completion of the chemical reaction (see, FIG. 17D). In the meantime, an amount of solid (S2) and RXN COMP 2 are added to the RXN TANK (see, FIG. 17C). The solid (S2) and RXN COMP 2 are mixed to form a slurry. In one embodiment, an amount of solid is divided such that half the solid is S1 and the other half is S2. In another embodiment, an amount of solid S1 and an amount of solid S2 are manually or automatically weighed from a larger batch of solid for processing. Following the appropriate time, i.e., time x2, the slurry comprising the solid S2 and the removal composition is moved to RXN HOLD 2 for substantial completion of the chemical reaction (see, FIG. 17D). In one embodiment, time x1 and x2 may be determined based on several factors including, but not limited to, a reaction tank temperature measured, a certain amount of time passed, a composition of solid being processed, the weight of solid being processed, a ratio of the weight of solid to RXN COMP 1, a measurement of a concentration of a consumed chemical constituent, visual inspection, end point detection, a pH value measured, a concentration of one or more metal ions, a concentration of one or more by-products or chemical species, and combinations thereof. The determination of time x1 and x2 can be controlled by a PLC, with or without a specific process recipe.
b. Following the substantial completion of the chemical reaction, the slurry in RXN HOLD 1 comprising the solid S1 and the removal composition is moved to a centrifuge, depicted by the “C” in FIG. 17E, where the removal composition is separated from the reacted solid S1. Other separation means are contemplated. The reacted solid S1 is moved to RINSE TANK 1. The removal composition (“L out’) can be sent to processing or can be reused, which is dependent on the metal ions removed and the respective removal composition, as described hereinbelow. Following the substantial completion of the other chemical reaction, the slurry in RXN HOLD 2 comprising the reacted solid S2 and the removal composition is moved to a centrifuge, depicted by the “C” in FIG. 17F, where the removal composition is separated from the reacted solid S2. Other separation means are contemplated. The reacted solid S2 is moved to RINSE TANK 1 which already comprises reacted solid S1. The accumulated reacted solid S1 plus reacted solid S2 is hereinafter referred to as solid S3. The removal composition (“L out’) can be sent to processing or can be reused, which is dependent on the metal ions removed and the respective removal composition, as described hereinbelow. The time of a complete reaction is dependent on several factors including, but not limited to, the composition of the solids being processed (e.g., which components made up the solids being processed), the temperature of processing, the weight of the solid being processed, the amount and concentration of removal composition needed to extract or remove about 65-100% of the particular metal in the solid, the concentration of a consumed chemical constituents, visual inspection, end point detection, the pH value of the slurry, the concentration of one or more metal ions, the concentration of one or more by-products or chemical species, and combinations thereof
c. First rinse liquid from RINSE 1 is introduced into RINSE TANK 1 (see, FIGS. 17E and 17F). Following a period of time to effectuate a first rinse, i.e., time r1, the slurry comprising the solid S3 and the first rinse liquid is moved to a centrifuge, where the first rinse liquid is separated from the solid S3. Other separation means are contemplated. In one embodiment, time r1 may be determined based on a rinse tank temperature measured, a certain amount of time passed, a measurement of a concentration of a chemical from the removal composition, a measurement of the concentration of one or more metal ions, visual inspection, end point detection, a pH value measured, the concentration of one or more by-products or chemical species, and combinations thereof. The determination of time r1 can be controlled by a PLC, with or without a specific process recipe.
d. Following centrifugation the solid is moved to RINSE TANK 2 (see, FIG. 17G). The first rinse liquid can be sent to processing or can be reused, which is dependent on the metal ions removed, as described herein below.
e. Second rinse liquid from RINSE 2 is introduced into RINSE TANK 2. Following a period of time to effectuate a second rinse, i.e., time r2, the slurry comprising the solid S3 and the second rinse liquid is moved to a centrifuge, where the second rinse liquid is separated from the solid S3. Other separation means are contemplated. In one embodiment, time r2 may be determined based on a rinse tank temperature measured, a certain amount of time passed, a measurement of a concentration of a chemical from the removal composition, a measurement of the concentration of one or more metal ions, visual inspection, end point detection, a pH value measured, the concentration of one or more by-products or chemical species, and combinations thereof. The determination of time r2 can be controlled by a PLC, with or without a specific process recipe.
f. Following centrifugation the solid S3 can be either (i) moved to the next metal removal module or is disposed of (see, FIG. 17J, “S out”) or (ii) if a third rinse is necessary, the solid S3 is sent to RINSE TANK 1 (see, FIG. 17H). In FIG. 17H, a third rinse solution is introduced to RINSE TANK 1. Following a period of time to effectuate a third rinse, i.e., time r3, the slurry comprising the solid S3 and the third rinse liquid is moved to a centrifuge, where the third rinse liquid is separated from the solid S3. Other separation means are contemplated. In one embodiment, time r3 may be determined based on a rinse tank temperature measured, a certain amount of time passed, a measurement of a concentration of a chemical from the removal composition, a measurement of the concentration of one or more metal ions, visual inspection, end point detection, a pH value measured, the concentration of one or more by-products or chemical species, and combinations thereof. The determination of time r3 can be controlled by a PLC, with or without a specific process recipe. The third rinse liquid can be sent to RINSE TANK 2. The solid S3 can either be moved to the next metal removal module or is disposed of (see, FIG. 17I, “S out”).

As shown in FIGS. 17H and 17J, the second rinse liquid can be directed to RINSE 1 to act as the first rinse liquid in the next cycle through the module. As shown in FIG. 17I, the third rinse liquid, when utilized, can be directed to RINSE 2 to act as the second rinse liquid in the next cycle through the module.

As mentioned, depending on the metal removal composition present, the liquid out (L out) between RXN HOLD 1 and RINSE TANK 1 (see, FIG. 17E), and the liquid out (L out) between RXN HOLD 2 and RINSE TANK 1 (see, FIG. 17F) may be directed to a specific tank. For example, the inventors discovered that when the removal composition is a base metal removal composition, the loaded removal composition may be sent, after just one cycle, to further processing to reclaim silver and/or some other precious metal that can be present in the loaded base metal removal composition. In addition, the loaded removal composition can be treated using resin-based acid recycle and metals recovery and/or sent to wastewater treatment. When the removal composition is intended to remove gold or silver, the loaded removal composition can be reused for a number of times and as such the liquid out (L out) can be sent to RXN COMP 1 or RXN COMP 2. When the metal removal compositions are reused, some modification of the compositions is sometimes necessary, e.g., pH adjustment, and/or concentration readjustment, as readily understood by the person skilled in the art.

The liquid out (L out) between RINSE TANK 1 and RINSE TANK 2 (see, FIG. 17G) may also be directed to a specific tank. For example, when the removal composition is the base metal removal composition, the liquid out (L out) can be used to formulate or supplement RXN COMP 1 or RXN COMP 2. When the removal composition is the gold removal composition, the liquid out (L out) can be sent to electrowinning or resin-based acid recycle and metals recovery, as discussed hereinabove for the GL module (280) to capture and convert the gold ions contained therein to metal. When the removal composition is the silver removal composition, the liquid out (L out) can be sent back into RINSE TANK 1 for reuse until it is loaded, at which time it can be sent to electrowinning or resin-based acid recycle and metals recovery, as discussed hereinabove to capture and convert the silver ions contained therein to metal.

It is understood by the person skilled in the art that one, two, three, four, five, six, seven, eight, or nine of the tanks in each module of any of the embodiments described herein may be the same as or different from one another and can include agitation means, heating/cooling means; ventilation means, sensing means, and/or gas input means. The ratio of solid to removal composition and solid to rinse liquid can be readily determined by the person skilled in the art. It is known that upon contact of the solid with removal composition, there tends to be an exothermic reaction which must be controlled. Accordingly, the ratio of solid to removal composition will be dependent on the removal composition, the metals content in the solid, as well as the heating and cooling options available in the reaction tank.

In a particularly preferred embodiment, the system and process for base metal removal is as follows:
a. The SPT base metal removal module (380) can include at least the nine tanks of FIGS. 17A-17J. A proprietary or commercially available base metal removal composition can be used in SPT base metal removal module (380). A preferred embodiment of the base metal removal composition is described hereinbelow. It is noted that the base metal removal composition used in the BMR module described hereinabove can be the same as or different than the base metal removal composition used in the SPT base metal removal module (380), i.e., the same chemical constituents and/or concentration of chemical constituents. The base metal removal composition from RXN COMP 1 is combined with the solid, e.g., RXN COMP 1 can be introduced to RXN TANK followed by the introduction of solid S1, as defined above, to the base metal removal composition to form a slurry. The weight percent ratio of the amount of base metal removal composition relative to the amount of solid may be in a range from about 1:1 to about 30:1, preferably about 4:1 to about 12:1. Following time x1, as described above and specific to base metal removal, the slurry comprising the base metal removal composition and solid S1 can be moved to RXN HOLD 1 for processing at time and temperature necessary to effectuate the substantial completion of the chemical reaction, i.e., base metal removal from the solid S1, for example, time in a range from about 10 minutes to about 300 minutes, preferably about 70 minutes to about 130 minutes, and temperature in a range from room temperature to about 80° C., preferably about 45° C. to about 70° C. Base metal removal composition from RXN COMP 2 is added to RXN TANK followed by the introduction of solid S2 to the base metal removal composition to form a slurry. Following time x2, which is specific to base metal removal, the slurry comprising the base metal removal composition and solid S2 can be moved to RXN HOLD 2 for processing for time and temperature necessary to effectuate the substantial completion of the chemical reaction, i.e., base metal removal from the solid S2, e.g., as described for RXN HOLD 1.
b. Following the substantial completion of the chemical reaction, i.e., base metal removal from the solid S1, the slurry from RXN HOLD 1 can be moved to a centrifuge and the reacted solid S1 separated from the base metal removal composition (e.g., see FIG. 17E). The base metal removal composition is preferably only used once and as such, may be sent for further processing to remove silver and/or some other precious metal therefrom (e.g., “L out” in FIG. 17E). Silver can be reclaimed from the base metal removal composition by reacting same with NaCl or some other chloride-containing salt to form silver chloride, which can be collected with a filter and sent to the SPT silver leaching module (420), as discussed below, for silver reclamation. The reacted solid S1 from the centrifuge can be moved to RINSE TANK 1 (see, e.g., FIG. 17E). The same process occurs to separate the slurry in RXN HOLD 2 into a base metal removal composition, which can be processed for silver and/or some other precious metal, and a reacted solid S2, wherein the reacted solid S2 can be moved to RINSE TANK 1 (which already comprises reacted solid S1). The accumulated reacted solid S1 plus reacted solid S2 is hereinafter referred to as solid S3.
c. First rinse liquid from RINSE 1 is moved to RINSE TANK 1 and rinsing occurs for time r1 necessary to effectuate a first rinse, for example, time in a range from about 1 minute to about 30 minutes, preferably about 2 minutes to about 10 minutes. Following the time r1 of rinsing, the slurry from RINSE TANK 1 can be moved to a centrifuge and the rinsed solid S3 is separated from the first rinse liquid. The rinsed solid S3 can be moved to RINSE TANK 2 (see, FIG. 17G). The first rinse liquid can preferably be used to make or supplement new base metal removal composition (e.g., for RXN COMP 1 or RXN COMP 2).
d. Second rinse liquid from RINSE 2 can be moved to RINSE TANK 2 and rinsing occurs at time r2 necessary to effectuate a second rinse, for example, time in a range from about 1 minute to about 30 minutes, preferably about 2 minutes to about 10 minutes. Following the time r2 of rinsing, the slurry from RINSE TANK 2 can be moved to a centrifuge and the solid S3 is separated from the second rinse liquid. The solid S3 can be moved to the SPT gold removal module (400), the SPT silver leaching module (420), or can be moved to a container for further processing in house or off-site. The second rinse liquid can become the first rinse liquid for the next cycle (see, FIG. 17J).

When the base metal removal composition comprises nitric acid or at least one nitrate salt, gases comprising nitrogen and oxygen (e.g., NO and NO₂), hereinafter “NOx,” are generated, which are preferably abated because of their toxicity. As introduced hereinbelow, a preferred base metal removal composition can comprise at least one NOx suppressing agent when the at least one oxidizing agent comprises nitric acid and/or at least one nitrate salt. In one embodiment, the NOx suppressing agent comprises hydrogen peroxide or other oxidizing agent that has a higher oxidizing potential than nitric acid and/or at least one nitrate salt, wherein the hydrogen peroxide or other oxidizing agent can be added upstream of the reaction tank, introduced directly into the reaction tank just prior to the introduction of solid, introduced directly into the reaction tank at the same time that the solid is introduced, or introduced directly into the reaction tank after the solid is introduced. In another embodiment, the NOx suppressing agent comprises one or more azoles, as described herein. Although not wishing to be bound by theory, it is thought that the azole(s) act to chelate the NOx, wherein the azole can be added upstream of the reaction tank, introduced directly into the reaction tank just prior to the introduction of solid, introduced directly into the reaction tank at the same time that the solid is introduced, or introduced directly into the reaction tank after the solid is introduced.

In a particularly preferred embodiment, the system and process for gold removal is as follows:
a. The SPT gold removal module (400) can include at least the nine tanks of FIGS. 17A-17J. A proprietary or commercially available gold removal composition can be used in SPT gold removal module (400). A preferred embodiment of the gold removal composition is described hereinbelow. It is noted that the gold removal composition used in the GL module (280) described hereinabove can be the same as or different than the gold removal composition used in the SPT tool module (360), i.e., the same chemical constituents and/or concentration of chemical constituents. The gold removal composition from RXN COMP 1 is combined with the solid, e.g., RXN COMP 1 can be introduced to the RXN TANK followed by the introduction of solid S1 to the gold removal composition to form a slurry. In one embodiment, the solid S1 was previously processed in the SPT base metal removal module (380) of the SPT Tool. In one embodiment, the solid S1 was previously processed in the SPT silver leaching module (420) of the SPT Tool. In another embodiment, the solid S1 was not previously processed in either the SPT base metal removal module (380) or the SPT silver leaching module (420) of the SPT Tool. The weight percent ratio of the amount of gold removal composition relative to the amount of solid may be in a range from about 1:1 to about 30:1, preferably about 4:1 to about 12:1. Following time x1, as described above and specific to gold removal, the slurry comprising the gold removal composition and solid S1 can be moved to RXN HOLD 1 for processing at time and temperature necessary to effectuate the substantial completion of the chemical reaction, i.e., gold removal from the solid S1 as gold ions dissolved/solubilized in the gold removal composition, for example, time in a range from about 10 minutes to about 200 minutes, preferably about 40 minutes to about 110 minutes, and temperature in a range from room temperature to about 80° C., preferably about 45° C. to about 70° C. Gold removal composition from RXN COMP 2 is added to RXN TANK followed by the introduction of solid S2 to the gold removal composition to form a slurry. Following time x2, which is specific to gold removal, the slurry comprising the gold removal composition and solid can be moved to RXN HOLD 2 for processing for time and temperature necessary to effectuate the substantial completion of the chemical reaction, i.e., gold removal from the solid S2 as gold ions dissolved/solubilized in the gold removal composition, e.g., as described for RXN HOLD 1.
b. Following the substantial completion of the chemical reaction, i.e., gold removal from the solid S1 as gold ions dissolved/solubilized in the gold removal composition, the slurry from RXN HOLD 1 can be moved to a centrifuge and the reacted solid S1 separated from the gold removal composition (e.g., see FIG. 17E). The gold removal composition can be used several times but once loaded, as readily discernible by the skilled person, can be processed to remove gold ions therefrom, e.g., using diffusion dialysis, electrowinning, pH adjustment, cementation, and/or resin-based acid recycle and metals recovery. The reacted solid S1 from the centrifuge can be moved to RINSE TANK 1 (see, e.g., FIG. 17E). The same process occurs to separate the slurry in RXN HOLD 2 into a gold removal composition, which can be reused several times, and a reacted solid S2, wherein the reacted solid S2 can be moved to RINSE TANK 1 (which already comprises reacted solid S1). The accumulated reacted solid S1 plus reacted solid S2 is hereinafter referred to as solid S3.
c. First rinse liquid from RINSE 1 is moved to RINSE TANK 1 and rinsing can occur for time r1 necessary to effectuate a first rinse to remove residual gold ions from the solid. The time of rinsing can be in a range from about 1 minute to about 30 minutes, preferably about 2 minutes to about 10 minutes. Following the time r1 of rinsing, the slurry from RINSE TANK 1 can be moved to a centrifuge and the rinsed solid S3 is separated from the first rinse liquid. The rinsed solid S3 can be moved to RINSE TANK 2 (see, FIG. 17G) and the first rinse liquid can preferably be sent for processing to separate, remove and/or recover gold ions therefrom, e.g., using diffusion dialysis, electrowinning, pH adjustment, cementation, and/or resin-based acid recycle and metals recovery.
d. Second rinse liquid from RINSE 2 can be moved to RINSE TANK 2 and rinsing can occur for time r2 necessary to effectuate a second rinse, for example, time in a range from about 1 minute to about 30 minutes, preferably about 2 minutes to about 10 minutes. Following the time r2 of rinsing, the slurry from RINSE TANK 2 can be moved to a centrifuge and the solid S3 is separated from the second rinse liquid. The solid S3 can be moved to RINSE TANK 1 (see, FIG. 17H) and the second rinse liquid can become the first rinse liquid for the next cycle of solids through the SPT gold removal module (400). Alternatively, the second rinse liquid can be used to make new gold removal composition.
e. A third rinse liquid (see, FIG. 17H) can be moved to RINSE TANK 1 and rinsing can occur for time r3 necessary to effectuate a third rinse, for example, time in a range from about 1 minute to about 30 minutes, preferably about 2 minutes to about 10 minutes. The pH can be adjusted during the third rinse to a range of about 4.5 to about 7 if the solid will be sent to the SPT silver leaching module subsequent to rinsing. Following the time r3 of rinsing, the slurry from RINSE TANK 1 can be moved to a centrifuge and the solid S3 is separated from the third rinse liquid. The solid S3 can be moved to the SPT silver leaching module (420), the SPT base metal removal module (380), or can be moved to a container for further processing in house or off-site. The third rinse liquid can become the second rinse liquid for the next cycle of solids through the SPT gold removal module (400) (see, FIG. 17I). Alternatively, the third rinse liquid can be used to make new gold removal composition.

In a particularly preferred embodiment, the system and process for silver removal is as follows:
a. The SPT silver leaching module (420) includes at least the nine tanks of FIGS. 17A-17J. A proprietary or commercially available silver removal composition can be used in SPT silver leaching module (420). A preferred embodiment of the silver removal composition is described hereinbelow. The silver removal composition from RXN COMP 1 is combined with the solid, e.g., RXN COMP 1 can be introduced to RXN TANK followed by the introduction of solid S1 to the silver removal composition to form a slurry. In one embodiment, the solid 51 was previously processed in the SPT gold removal module (400) of the SPT Tool. In another embodiment, the solid 51 was previously processed in the SPT base metal removal module (380) of the SPT Tool. In another embodiment, the solid 51 was not previously processed in either the SPT gold removal module (400) or the SPT base metal removal module (380) of the SPT Tool. The weight percent ratio of the amount of silver removal composition relative to the amount of solid may be in a range from about 1:1 to about 30:1, preferably about 4:1 to about 12:1. Following time x1, which is specific to silver removal, the slurry comprising the silver removal composition and solid 51 can be moved to RXN HOLD 1 for processing at time and temperature necessary to effectuate the substantial completion of the chemical reaction, i.e., silver removal from the solid 51, for example, time in a range from about 10 minutes to about 200 minutes, preferably about 40 minutes to about 110 minutes, and temperature in a range from room temperature to about 60° C., preferably about room 30° C. to about 50° C. Silver removal composition from RXN COMP 2 is added to RXN TANK followed by the introduction of solid S2 to the silver removal composition to form a slurry. Following time x2, which is specific to silver removal, the slurry comprising the silver removal composition and solid can be moved to RXN HOLD 2 for processing for time and temperature necessary to effectuate the substantial completion of the chemical reaction, i.e., silver removal from the solid S2, e.g., as described for RXN HOLD 1.
b. Following the substantial completion of the chemical reaction, i.e., silver removal from the solid 51, the slurry from RXN HOLD 1 can be moved to a centrifuge and the reacted solid 51 is separated from the silver removal composition (e.g., see FIG. 17E). The silver removal composition can be used several times but once loaded, can be processed to remove silver therefrom, e.g., using diffusion dialysis, electrowinning, pH adjustment, cementation, and/or resin-based acid recycle and metals recovery. The reacted solid 51 from the centrifuge can be moved to RINSE TANK 1 (see, e.g., FIG. 17E). The same process occurs to separate the slurry in RXN HOLD 2 into a silver removal composition, which can be reused several times, and a reacted solid S2, wherein the reacted solid S2 can be moved to RINSE TANK 1 (which already comprises reacted solid 51). The accumulated reacted solid 51 plus reacted solid S2 is hereinafter referred to as solid S3.
c. First rinse liquid from RINSE 1 can be moved to RINSE TANK 1 and rinsing occurs at time r1 necessary to effectuate a first rinse, for example, time in a range from about 1 minute to about 30 minutes, preferably about 2 minutes to about 10 minutes. Following the time r1 of rinsing, the slurry from RINSE TANK 1 can be moved to a centrifuge and the rinsed solid S3 is separated from the liquid. The rinsed solid S3 can be moved to RINSE TANK 2 (see, FIG. 17G). The first rinse liquid can be moved back to RINSE 1 for reuse several times before being sent for processing to separate, remove and/or recover silver therefrom, e.g., using diffusion dialysis, electrowinning, pH adjustment, cementation, and/or resin-based acid recycle and metals recovery.
d. Second rinse liquid from RINSE 2 can be moved to RINSE TANK 2 and rinsing occurs at time r2 necessary to effectuate a second rinse, for example, time in a range from about 1 minute to about 30 minutes, preferably about 2 minutes to about 10 minutes. Following the time r2 of rinsing, the slurry from RINSE TANK 2 can be moved to a centrifuge and the solid S3 is separated from the second rinse liquid. The solid can be moved to the SPT base metal removal module (380), the SPT gold removal module (400), or a container for further processing in house or off-site. The second rinse liquid can be moved back to RINSE 2 for reuse several times before being sent for processing to separate, remove and/or recover silver therefrom, e.g., using diffusion dialysis, electrowinning, pH adjustment, cementation, and/or resin-based acid recycle and metals recovery.

It should be appreciated by the person skilled in the art that any combination of the SPT base metal removal module (380), the SPT gold removal module (400) and the SPT silver leaching module (420) may be present in the SPT tool module (360). For example, the SPT tool module (360) may include only one of the three metal modules. Alternatively, the SPT tool module (360) can comprise a SPT base metal removal module (380) and a SPT silver leaching module (420), wherein the modules are in series with one another, without or without intervening processes, and wherein either module can be the first one in the series. Alternatively, the SPT tool module (360) can comprise a SPT base metal removal module (380) and a SPT gold removal module (400), wherein the modules are in series with one another, without or without intervening processes, and wherein either module can be the first one in the series. In another alternative, the SPT tool module (360) can comprise a SPT silver leaching module (420) and a SPT gold removal module (400), wherein the modules are in series with one another, without or without intervening processes, and wherein either module can be the first one in the series. In a preferred embodiment, the SPT tool module (360) can comprise a SPT base metal removal module (380), a SPT silver leaching module (420) and a SPT gold removal module (400), wherein the modules are in series with one another, without or without intervening processes, and wherein either module can be the first one in the series. In a particularly preferred embodiment, the SPT tool module (360) comprises a SPT base metal removal module (380), a SPT silver leaching module (420) and a SPT gold removal module (400) (see, e.g., FIG. 12), wherein the modules are in series with one another, without or without intervening processes.

Although other embodiments can be envisioned, the embodiments disclosed herein have been perfected to maximize the efficiency of the reclamation of precious metals as well as minimize the amount of chemicals needed and the waste stream produced.

The SPT tool module (360) is preferably controlled by at least one PLC and the particular recipe for each module may be selected when the boards and/or components, which preferably are sorted into batches, enter the SPT process stream. As discussed hereinabove, the SPT module will be monitored in real-time, wherein the respective removal compositions are sampled at least every fifteen minutes and the concentration of the chemical constituents determined, wherein the rinse liquid can be sampled, and wherein the solids undergoing base metal removal and gold removal are monitored at the substantial completion of the chemical reaction and the solids undergoing silver removal are sampled at 60 minutes. Further, the gases evolved and all of the hardware of the SPT tool module (360) are monitored to ensure that the module is working efficiently and safely.

In one aspect, a SPT tool module (360) is described, said SPT tool module (360) comprising at least one module selected from the group consisting of (i) a SPT base metal removal module (380), (ii) a SPT gold removal module (400), (iii) a SPT silver leaching module (420), (iv) any combination of one or two of (i)-(iii), and (v) the combination of each of (i)-(iii), wherein the SPT tool module is capable of removing at least one precious metal from PCBs, PCB components, materials comprising gold, or any combination thereof.

In one aspect, a SPT tool module (360) is described, said SPT tool module (360) comprising at least one module selected from the group consisting of (i) a SPT base metal removal module (380), (ii) a SPT gold removal module (400), (iii) a SPT silver leaching module (420), (iv) any combination of one or two of (i)-(iii), and (v) the combination of each of (i)-(iii), wherein the SPT tool module is capable of removing at least one precious metal from solid as defined herein. The solid preferably comprises materials comprising gold that have been ashed, ground, and/or crushed.

In another aspect, a process of recycling material selected from the group consisting of PCBs, PCB components, materials comprising gold, and combinations thereof, is described, wherein the process efficiently recovers more than about 80%, preferably more than about 90%, and most preferably more than about 95% of the gold contained in the PCBs, PCB components and materials comprising gold. The process comprises at least one of (a) removing at least one base metal from a solid using a base metal removal composition in a solids processing technology (SPT) base metal removal module (380) (b) removing gold from the solid using a gold removal composition in a SPT gold removal module (400), and/or (c) removing silver from the solid using a silver removal composition in a SPT silver leaching module (420), wherein the processes are operated in series with one another, with or without intervening processes. The solid preferably comprises materials comprising gold that have been ashed, ground, and/or crushed.

In one aspect, a SPT base metal removal module (380) is described, said SPT base metal removal module comprising:

(a) at least one reaction tank,

(b) at least one holding tank in liquid communication with the at least one reaction tank,

(c) at least one rinse tank in liquid communication with the at least one holding tank,

wherein said SPT base metal removal module is capable of removing at least one base metal from a solid, wherein the solid comprises materials comprising gold that have been ashed, ground, and/or crushed. The SPT base metal removal module can further comprise at least one of: at least one base metal removal composition tank in liquid communication with the at least one reaction tank; at least one rinse liquid tank in liquid communication with the at least one rinse tank; at least one centrifuge; agitation means in at least one of the reaction tank, the at least one holding tank, and/or the at least one rinse tank; at least one pump; heating/cooling means for at least one of the reaction tank, the at least one holding tank, and/or the at least one rinse tank; at least one air input for at least one of the reaction tank, the at least one holding tank, and/or the at least one rinse tank; real-time sampling and adjustment; sensing means for at least one of the reaction tank, the at least one holding tank, and/or the at least one rinse tank; and ventilation means for at least one of the reaction tank, the at least one holding tank, and/or the at least one rinse tank. The at least one reaction tank and the at least one holding tank can comprise a base metal removal composition. The SPT base metal removal module is preferably enclosed in one or more housings and controlled by a programmable logic controller.

In another aspect, a process of removing at least one base metal from material selected from the group consisting of PCBs, PCB components, materials comprising gold, and combinations thereof, is described, said process comprising removing at least one base metal from a solid using a base metal removal composition in a solids processing technology (SPT) base metal removal module (380), wherein the SPT base metal removal module comprises (a) at least one reaction tank, (b) at least one holding tank in liquid communication with the at least one reaction tank, and (c) at least one rinse tank in liquid communication with the at least one holding tank, wherein the solid comprises materials comprising gold that have been ashed, ground, and/or crushed.

In yet another aspect, a process of removing at least one base metal from material selected from the group consisting of PCBs, PCB components, materials comprising gold, and combinations thereof, is described, said process comprising:
(a) producing a first slurry in a reaction tank, wherein the first slurry comprises at least a solid and a base metal removal composition, wherein the first slurry undergoes a reaction for a time x;
(b) moving the first slurry from the reaction tank to a holding tank after time x to effectuate the substantial completion of the chemical reaction;
(c) moving the first slurry from the holding tank to a centrifuge to separate the solid from the base metal removal composition;
(d) moving the solid from centrifuge to a first rinse tank, wherein first rinse liquid is introduced to the solid to produce a second slurry, wherein the second slurry is rinsed for a time r1;
(e) moving the second slurry from the first rinse tank to a centrifuge to separate the solid from the first rinse liquid;
and optionally:
(f) moving the solid from centrifuge to a second rinse tank, wherein second rinse liquid is introduced to the solid to produce a third slurry, wherein the third slurry is rinsed for a time r2; and
(g) moving the third slurry from the second rinse tank to a centrifuge to separate the solid from the second rinse liquid.
   In one embodiment, the slurry is produced by adding the base metal removal composition to the reaction tank, followed by introduction of the solid and at least one NOx suppressing agent to the reaction tank at approximately the same time. Preferably, the substantial completion of the chemical reaction takes from about 10 minutes to about 300 minutes, preferably about 70 minutes to about 130 minutes, at temperature in a range from room temperature to about 80° C., preferably about 45° C. to about 70° C. In one embodiment, the base metal removal composition is used only once.

In one aspect, a SPT gold removal module (400) is described, said SPT gold removal module comprising:

(a) at least one reaction tank,

(b) at least one holding tank in liquid communication with the at least one reaction tank,

(c) at least one rinse tank in liquid communication with the at least one holding tank,

wherein said SPT gold removal module is capable of removing gold from a solid, wherein the solid comprises materials comprising gold that have been ashed, ground, and/or crushed. The SPT gold removal module can further comprise at least one of: at least one gold removal composition tank in liquid communication with the at least one reaction tank; at least one rinse liquid tank in liquid communication with the at least one rinse tank; at least one centrifuge; agitation means in at least one of the reaction tank, the at least one holding tank, and/or the at least one rinse tank; at least one pump; heating/cooling means for at least one of the reaction tank, the at least one holding tank, and/or the at least one rinse tank; at least one air input for at least one of the reaction tank, the at least one holding tank, and/or the at least one rinse tank; real-time sampling and adjustment; sensing means for at least one of the reaction tank, the at least one holding tank, and/or the at least one rinse tank; and ventilation means for at least one of the reaction tank, the at least one holding tank, and/or the at least one rinse tank. The at least one reaction tank and the at least one holding tank can comprise a gold removal composition. The SPT gold removal module is preferably enclosed in one or more housings and controlled by a programmable logic controller.

In another aspect, a process of removing gold from material selected from the group consisting of PCBs, PCB components, materials comprising gold, and combinations thereof, is described, said process comprising removing gold from a solid using a gold removal composition in a solids processing technology (SPT) gold removal module (400), wherein the SPT gold removal module comprises (a) at least one reaction tank, (b) at least one holding tank in liquid communication with the at least one reaction tank, and (c) at least one rinse tank in liquid communication with the at least one holding tank, wherein the solid comprises materials comprising gold that have been ashed, ground, and/or crushed.

In yet another aspect, a process of removing gold from material selected from the group consisting of PCBs, PCB components, materials comprising gold, and combinations thereof, is described, said process comprising:
(a) producing a first slurry in a reaction tank, wherein the first slurry comprises at least a solid and a gold removal composition, wherein the first shiny undergoes a reaction for a time x;
(b) moving the first slurry from the reaction tank to a holding tank after time x to effectuate the substantial completion of the chemical reaction;
(c) moving the first slurry from the holding tank to a centrifuge to separate the solid from the gold removal composition;
(d) moving the solid from centrifuge to a first rinse tank, wherein first rinse liquid is introduced to the solid to produce a second slurry, wherein the second slurry is rinsed for a time r1;
(e) moving the second slurry from the first rinse tank to a centrifuge to separate the solid from the first rinse liquid;
and optionally:
(f) moving the solid from centrifuge to a second rinse tank, wherein second rinse liquid is introduced to the solid to produce a third slurry, wherein the third slurry is rinsed for a time r2;
(g) moving the third slurry from the second rinse tank to a centrifuge to separate the solid from the second rinse liquid;
and optionally
(h) moving the solid from centrifuge to the first rinse tank, wherein third rinse liquid is introduced to the solid to produce a fourth slurry, wherein the fourth slurry is rinsed fora time r3; and
(g) moving the fourth slurry from the first rinse tank to a centrifuge to separate the solid from the third rinse liquid.
   Preferably, the substantial completion of the chemical reaction takes from about 10 minutes to about 200 minutes, preferably about 40 minutes to about 110 minutes, at temperature in a range from room temperature to about 80° C., preferably about 40° C. to about 70° C. In one embodiment, the gold removal composition is used several times before processing (e.g., electrowinning and/or resin-based acid recycle and metals recovery).

In one aspect, a SPT silver leaching module (400) is described, said SPT silver leaching module comprising:

(a) at least one reaction tank,

(b) at least one holding tank in liquid communication with the at least one reaction tank,

(c) at least one rinse tank in liquid communication with the at least one holding tank,

wherein said SPT silver leaching module is capable of removing silver from a solid, wherein the solid comprises materials comprising silver that have been ashed, ground, and/or crushed. The SPT silver leaching module can further comprise at least one of: at least one silver leaching composition tank in liquid communication with the at least one reaction tank; at least one rinse liquid tank in liquid communication with the at least one rinse tank; at least one centrifuge; agitation means in at least one of the reaction tank, the at least one holding tank, and/or the at least one rinse tank; at least one pump; heating/cooling means for at least one of the reaction tank, the at least one holding tank, and/or the at least one rinse tank; at least one air input for at least one of the reaction tank, the at least one holding tank, and/or the at least one rinse tank; real-time sampling and adjustment; sensing means for at least one of the reaction tank, the at least one holding tank, and/or the at least one rinse tank; and ventilation means for at least one of the reaction tank, the at least one holding tank, and/or the at least one rinse tank. The at least one reaction tank and the at least one holding tank can comprise a silver leaching composition. The SPT silver leaching module is preferably enclosed in one or more housings and controlled by a programmable logic controller.

In another aspect, a process of removing silver from material selected from the group consisting of PCBs, PCB components, materials comprising gold, and combinations thereof, is described, said process comprising removing silver from a solid using a silver leaching composition in a solids processing technology (SPT) silver leaching module (420), wherein the SPT silver leaching module comprises (a) at least one reaction tank, (b) at least one holding tank in liquid communication with the at least one reaction tank, and (c) at least one rinse tank in liquid communication with the at least one holding tank, wherein the solid comprises materials comprising gold that have been ashed, ground, and/or crushed.

In yet another aspect, a process of removing silver from material selected from the group consisting of PCBs, PCB components, materials comprising gold, and combinations thereof, is described, said process comprising:
(a) producing a first slurry in a reaction tank, wherein the first slurry comprises at least a solid and a silver leaching composition, wherein the first slurry undergoes a reaction for a time x;
(b) moving the first slurry from the reaction tank to a holding tank after time x to effectuate the substantial completion of the chemical reaction;
(c) moving the first slurry from the holding tank to a centrifuge to separate the solid from the silver leaching composition;
(d) moving the solid from the centrifuge to a first rinse tank, wherein first rinse liquid is introduced to the solid to produce a second slurry, wherein the second slurry is rinsed for a time r1;
(e) moving the second slurry from the first rinse tank to a centrifuge to separate the solid from the first rinse liquid;
and optionally:
(f) moving the solid from centrifuge to a second rinse tank, wherein second rinse liquid is introduced to the solid to produce a third slurry, wherein the third slurry is rinsed for a time r2; and
(g) moving the third slurry from the second rinse tank to a centrifuge to separate the solid from the second rinse liquid.
   Preferably, the substantial completion of the chemical reaction takes from about 10 minutes to about 200 minutes, preferably about 40 minutes to about 110 minutes, at temperature in a range from room temperature to about 60° C., preferably about 30° C. to about 50° C. In one embodiment, the base metal removal composition is used only once.

### Processing Compositions Subsequent to Use

As discussed herein, once a removal composition is loaded, or otherwise no longer useful for metal removal, and once a rinse liquid is no longer useful for rinsing, they can be sent to at least one processing system including, but not limited to, electrowinning, diffusion dialysis, pH adjustment, cementation, wastewater treatment, resin-based acid recycle and metals recovery, and any combination thereof, depending on the removal composition or rinse liquid, as disclosed hereinabove.

With regards to wastewater treatment, the wastewater typically has a very low pH and the pH can be adjusted with a strong base to initiate precipitation of metal ions in the wastewater, for example as metal hydroxides. Following precipitation of a substantial amount of the metal ions from the wastewater, the pH of the wastewater can be adjusted to a value closer to neutral and the neutralized water can be sent through a reverse osmosis system to yield water that can be recycled back into one or more modules (e.g., the DS module, the BMR module, the GL module, the SPT base metal removal module, the SPT gold removal module, the SPT silver leaching module) for reuse. Accordingly, the wastewater recovery system can comprise at least one waste tank adapted to hold wastewater from the process modules described herein, at least one neutralization tank, at least one pH adjusting agent, at least one filter press, a salt removal system (e.g., reverse osmosis and crystallizer), tubular ultrafiltration, an ion exchanger to remove trace amounts of metal, and at least one return line adapted to return recycled water to at least one process module.

The electrowinning (EW) system can be chosen to effectively convert at least one metal ion from a loaded removal composition and/or rinse liquid into metal using one or more electrode cells. In a preferred embodiment, the EW system uses one or more cylindrical electrode cells comprising at least one cathode element and at least one anode element. When the solutions to be electrowon comprise chemicals that may cause unwanted reactions at the anode (e.g., metal etchants, metal complexing agents, and chloride ions), the EW system may further comprise a divided electrode cell, for example, a RenoCell as described in U.S. Pat. No. 6,162,333 issued on Dec. 19, 2000 in the name of Charles E. Lemon et al. and entitled “Electrochemical Cell for Removal of Metals from Solutions,” which is hereby incorporated herein by reference in its entirety. In the divided electrode cell at least one divider assembly is used to separate at least one catholyte chamber (comprising at least one cathode element and a catholyte solution) and at least one anolyte chamber (comprising at least one anode element and anolyte solution). The divider assembly may comprise one or more porous membranes including one or more cation and/or anion exchange membranes. In a preferred embodiment, the divider assembly is one or more porous cation exchange membranes. Although the anode and cathode elements may comprise one or more materials, as readily determined by one skilled in the art, in a preferred embodiment the EW system comprises a porous carbon and/or graphite cathode element and a titanium and/or titanium oxide anode element. In one embodiment, the catholyte solution comprises one or more loaded removal compositions and/or rinse liquids, as described herein, and the anolyte solution comprises one or more compatible acids and/or salt solutions including, but not limited to, Na₂SO₄ and H₂SO₄ (wherein H₂SO₄ is not compatible with the silver leaching solutions). The anolyte solution and catholyte solution comprising the metal ion circulate through their respective chambers in the divided electrode cell and metal ion from the loaded removal composition and/or rinse liquid is reduced and deposits on the cathode, wherein the metal reduced and deposited is dependent on the current of the EW system.

In one embodiment, the anolyte solution and catholyte solution comprising at least one metal ion are recirculated through their respective chambers in the divided electrode cell and metal ion from the loaded removal composition and/or rinse liquid is reduced and deposits on the cathode until greater than 80, 90, 95, 99% of the metal ion is removed from the solution. In a further embodiment, the concentration of the metal ion or precious metal ion in the catholyte solution is monitored manually or automatically until greater than 80, 90, 95, 99% of the metal is removed from the solution. In a preferred embodiment, the catholyte solution comprising the metal ion is recirculated through the EW system until less than 10 ppm, and more preferably less than 5 ppm of the metal ion is detected in the catholyte solution.

The at least one metal ion in the catholyte solution is monitored directly or indirectly, optionally in real-time, manually or automatically using one or more analytical techniques described hereinabove. Further, the EW system comprises means for monitoring one or more chemical constituents in the loaded removal composition and/or rinse liquid, directly or indirectly, optionally in real-time, manually or automatically, before and/or during the EW process using one or more analytical techniques described hereinabove.

In a further embodiment the EW system described herein efficiently recovers greater than 85, 90, 95, 99% of the target metal in the loaded removal composition and/or rinse liquid by monitoring directly or indirectly, optionally in real-time, manually or automatically, at least one system parameter before and/or during the EW process, wherein the at least one system parameter is selected from the group consisting of catholyte solution flow, catholyte inlet and/or outlet pressure, anolyte solution flow, anolyte inlet and/or outlet pressure, differential pressure across the divided cell assembly, electrode cell current, electrode cell voltage, pH, oxidation-reduction potential, and temperature.

When the EW system comprises a divided electrode cell, the system may further comprise means to maintain a minimal differential pressure across the divider assembly thereby maintaining the shape of membrane. Accordingly, in a further embodiment, the EW system comprises means to monitor and control the differential pressure between the anolyte solution in the anolyte chamber and the catholyte solution in the catholyte chamber including, but not limited to, one or more pressure sensors, variable speed pumps, pressure control valves, pressure regulators, pressure relief valves, and back pressure regulators. Preferably, the pressure on the catholyte side is the same as or slightly greater than the pressure on the anolyte side of the membrane.

Preferably the EW system comprises a PLC that monitors, adjusts and controls process parameters including, but not limited to, electrode cell current and voltage, pH, oxidation-reduction potential, temperature, flow rates, and pressures that are based in part on one or more process recipes that may be manually or automatically selected based on parameters including, but not limited to, targeted metal, targeted metal concentration and concentration of one or more chemical constituents in the loaded removal composition and/or rinse liquid. The process times are based on a number of parameters including, but not limited to, current, current/voltage switching, final metal concentration to be achieved, and safety considerations.

In one embodiment, EW is used to separate the gold from a loaded gold removal composition and/or rinse liquid using the divided cell, wherein urea, sodium hydroxide, or both, are added to the loaded gold removal composition to improve current efficiency during electrowinning. If urea is used, urea solution is pre-mixed with process water or GL module rinse water in a separate tank. After urea and process water or GL module rinse water are properly mixed, the solution will be pumped to the EW Feed Tank for mixing with the loaded gold removal composition. If NaOH is used, the NaOH solution can be mixed directly with loaded gold removal composition in an EW Feed Tank. A pump may be used to circulate the solution through tank eductors to blend the solution. Once the solution in the EW Feed Tank is properly blended and at the prescribed temperature, it is pumped from the EW Feed Tank through the EW Tool and can be recirculated back to the EW Feed Tank. Once the gold has been recovered, the post-EW solution can be pumped to the wastewater treatment system. Preferably, the EW process used to recover gold utilizes urea, which can improve the efficiency of the entire process and can be recycled in the wastewater treatment system for reuse.

Advantageously, electrowinning permits the recovery of one metal at a time, depending on the current. It should be appreciated that the current of the electrowinning process can be maintained at a constant current, changed over time, or both. It should also be appreciated that the voltage of the electrowinning process can be maintained at a constant current, constant voltage, changed over time, or all of the above.

Alternatively, or in addition to electrowinning, a resin-based acid recycle and metals recovery system can be used to process the removal compositions and/or rinse liquids, wherein the resin-based acid recycle and metals recovery system utilizes a column comprising a resin having absolute pore diameters, for example, ion size exclusion, as understood by the person skilled in the art. As the composition travels through the column, the ions are separated by size which allows for the capture of the metal ions as well as the recycling of aqueous compositions. An example of resin-based acid recycle and metals recovery is a system and process using an ionic size exclusion resin or standard resin. Ionic size exclusion polymeric resins have a specific surface area, pore volume, and pore diameter and can be used to separate two or more ionic species having different size radii from an aqueous composition. The ionic species may comprise cations, anions, complex cations, complex anions, and/or combinations thereof. For the present disclosure, ionic size exclusion resins may be used to separate metal ions from acid-containing compositions for recovery of the metal ions and/or reuse of the acid. Further, ionic size exclusion resins may be used to separate two or more different metal ions from acid-containing compositions for recovery of the metal ions and/or reuse of the acid, wherein the two or more metal ions are further separated from one another and/or from the acid. The captured metal ions can be reduced to metal, as understood by the person skilled in the art. Resin materials useful for separating ions include, but are not limited to, polystyrene and/or divinylbenzene polystyrene.

It should be appreciated that regardless of whether wastewater treatment, EW, DD or resin-based acid recycle and metals recovery is used to treat the compositions and rinse liquids described herein, any materials that can be recycled back through any of the processes should be, e.g., reclaimed acidic solutions. For example, following wastewater treatment, EW, DD, or resin-based acid recycle and metals recovery, there may be a liquid that has been treated such that it can be used as a rinse liquid or alternatively in a new metal removal composition. Advantageously, this ensures that the waste stream is minimized.

### Gold Removal Compositions

One embodiment of a gold removal composition comprises, consists of, or consists essentially of at least one oxidizing agent, optionally at least one halide, optionally at least one acid, and optionally at least one solvent. In another embodiment, the gold removal composition comprises, consists of, or consists essentially of at least one oxidizing agent, at least one halide salt, optionally at least one acid, and optionally at least one solvent. In one embodiment, the gold removal composition comprises, consists of, or consists essentially of at least one oxidizing agent, at least one halide, at least one acid, and at least one solvent. In one embodiment, the gold removal composition comprises, consists of, or consists essentially of at least one oxidizing agent, at least one chloride salt, at least one acid, and at least one solvent. In another embodiment, the gold removal composition comprises, consists of, or consists essentially of at least one oxidizing agent, at least one chloride salt, at least one sulfur-containing acid, and at least one solvent. In still another embodiment, the gold removal composition comprises, consists of, or consists essentially of at least one oxidizing agent, at least one alkaline chloride salt, at least one sulfur-containing acid, and at least one solvent. In yet another embodiment, the gold removal composition comprises, consists of, or consists essentially of at least one nitrate salt oxidizing agent, at least one alkaline chloride salt, at least one sulfur-containing acid, and at least one solvent. The gold removal composition is aqueous in nature and has a pH less than about 2, more preferably less than about 1. The weight percent ratio of the at least one oxidizing agent to at least one acid is in a range from about 0.1:1 to about 5:1, preferably about 1:1 to about 3:1. The weight percent ratio of the at least one halide to at least one acid is in a range from about 0.1:1 to about 5:1, preferably about 0.5:1 to about 2:1.

Oxidizing agents are included in the composition to oxidize the metals to be removed into an ionic form and accumulate highly soluble salts of dissolved metals. Oxidizing agents contemplated herein include, but are not limited to, ozone, nitric acid (HNO₃), bubbled air, cyclohexylaminosulfonic acid, hydrogen peroxide (H₂O₂), oxone (potassium peroxymonosulfate, 2KHSO₅.KHSO₄K₂SO₄), ammonium polyatomic salts (e.g., ammonium peroxomonosulfate, ammonium chlorite (NH₄ClO₂), ammonium chlorate (NH₄ClO₃), ammonium iodate (NH₄IO₃), ammonium perborate (NH₄BO₃), ammonium perchlorate (NH₄ClO₄), ammonium periodate (NH₄IO₃), ammonium persulfate ((NH₄)₂S₂O₈), ammonium hypochlorite (NH₄ClO)), sodium polyatomic salts (e.g., sodium persulfate (Na₂S₂O₈), sodium hypochlorite (NaClO)), potassium polyatomic salts (e.g., potassium iodate (KIO₃), potassium permanganate (KMnO₄), potassium persulfate, potassium persulfate (K₂S₂O₈), potassium hypochlorite (KClO)), tetramethylammonium polyatomic salts (e.g., tetramethylammonium chlorite ((N(CH₃)₄)ClO₂), tetramethylammonium chlorate ((N(CH₃)₄)ClO₃), tetramethylammonium iodate ((N(CH₃)₄)IO₃), tetramethylammonium perborate ((N(CH₃)₄)BO₃), tetramethylammonium perchlorate ((N(CH₃)₄)ClO₄), tetramethylammonium periodate ((N(CH₃)₄)IO₄), tetramethylammonium persulfate ((N(CH₃)₄)S₂O₈), tetramethylammonium nitrate), tetrabutylammonium polyatomic salts (e.g., tetrabutylammonium peroxomonosulfate, tetrabutylammonium nitrate), peroxomonosulfuric acid, urea hydrogen peroxide ((CO(NH₂)₂)H₂O₂), peracetic acid (CH₃(CO)OOH), sodium nitrate, potassium nitrate, ammonium nitrate, and combinations thereof. Most preferably, the oxidizing agent comprises a nitrate ion including, but not limited to, nitric acid, sodium nitrate, potassium nitrate, ammonium nitrate, tetraalkylammonium nitrate, and combinations thereof.

The at least one halide is preferably a chloride-containing compound including, but not limited to, hydrochloric acid, and alkaline chlorides (e.g., sodium chloride, potassium chloride, rubidium chloride, cesium chloride, magnesium chloride, calcium chloride, strontium chloride, ammonium chloride, quaternary ammonium chloride salts), and combinations thereof, with the proviso that the chloride-containing compound cannot include copper chloride, chlorine gas, or a second, different halide. Preferably, the at least one halide comprises an alkaline chloride, even more preferably an alkali metal chloride such as sodium chloride. The at least one halide can also include salts and/or acids comprising bromide and iodide including, but not limited to, sodium bromide, sodium iodide, potassium bromide, potassium iodide, rubidium bromide, rubidium iodide, cesium bromide, cesium iodide, magnesium bromide, magnesium iodide, calcium bromide, calcium iodide, strontium bromide, strontium iodide, ammonium bromide, ammonium iodide, quaternary ammonium bromide salts, and quaternary ammonium bromide salts.

The at least one acid is preferably a sulfur-containing species such as sulfuric acid, sulfate salts (e.g., sodium sulfate, potassium sulfate, rubidium sulfate, cesium sulfate, magnesium sulfate, calcium sulfate, strontium sulfate, barium sulfate), sulfonic acid, sulfonic acid derivatives, and combinations thereof. Sulfonic acid derivatives contemplated include methanesulfonic acid (MSA), ethanesulfonic acid, 2-hydroxyethanesulfonic acid, n-propanesulfonic acid, isopropanesulfonic acid, isobutenesulfonic acid, n-butanesulfonic acid, n-octanesulfonic acid), benzenesulfonic acid, benzenesulfonic acid derivatives, and combinations thereof. Preferably, the at least one acid comprises sulfuric acid, preferably concentrated sulfuric acid.

The at least one solvent includes, but is not limited to, water, methanol, ethanol, isopropanol, butanol, pentanol, hexanol, 2-ethyl-1-hexanol, heptanol, octanol, ethylene glycol, propylene glycol, butylene glycol, tetrahydrofurfuryl alcohol (THFA), butylene carbonate, ethylene carbonate, propylene carbonate, dipropylene glycol, diethylene glycol monomethyl ether, triethylene glycol monomethyl ether, diethylene glycol monoethyl ether, triethylene glycol monoethyl ether, ethylene glycol monopropyl ether, ethylene glycol monobutyl ether, diethylene glycol monobutyl ether, triethylene glycol monobutyl ether, ethylene glycol monohexyl ether, diethylene glycol monohexyl ether, ethylene glycol phenyl ether, propylene glycol methyl ether, dipropylene glycol methyl ether (DPGME), tripropylene glycol methyl ether (TPGME), dipropylene glycol dimethyl ether, dipropylene glycol ethyl ether, propylene glycol n-propyl ether, dipropylene glycol n-propyl ether (DPGPE), tripropylene glycol n-propyl ether, propylene glycol n-butyl ether, dipropylene glycol n-butyl ether, tripropylene glycol n-butyl ether, propylene glycol phenyl ether, 2,3-dihydrodecafluoropentane, ethyl perfluorobutylether, methyl perfluorobutylether, alkyl carbonates, alkylene carbonates, 4-methyl-2-pentanol, tetramethylene glycol dimethyl ether, and combinations thereof. Preferably, the at least one solvent comprises water.

In a particularly preferred embodiment, the gold removal composition comprises, consists of, or consists essentially of sodium chloride, sulfuric acid or a salt thereof (e.g., sodium sulfate), nitric acid or a salt thereof (i.e., sodium nitrate), and water.

The gold removal composition can further comprise at least one complexing agent (e.g., a noble metal complexing agent), at least one buffering agent, at least one corrosion inhibitor, at least one NOx suppressing agent, at least one surfactant, at least one anti-foaming agent, at least one passivating agent, and any combination thereof.

It will be appreciated by the person skilled in the art that the gold removal composition can be prepared upstream and stored in a tank for use, prepared upstream in the lines for introduction into the reaction tank, or prepared directly in the reaction tank by introducing the chemicals therein. Further, it is contemplated that a concentrate can be prepared and stored for dilution with a diluent (e.g., water) prior to, or in, the reaction tank

In one embodiment, the gold removal composition is used until loaded with dissolved/solubilized gold ions. In one embodiment, one or more constituents of the gold removal composition is a regenerated and/or recycled constituent from one or more effluent waste streams within the e-waste facility.

### Solder Removal Compositions

The solder removal composition preferably removes solder metals selectively relative to precious metals, in particular gold, thereby increasing the loading of the bath for the solder and increasing the bath-life of the solder removal composition. In one embodiment, the solder removal composition comprises, consists of, or consists essentially of at least one oxidizing agent and water. The first composition may further comprise at least one lead and/or tin complexing agent, at least one organic solvent, and/or at least one passivating agent for passivating the precious metals and/or base metals. In another embodiment, the solder removal composition comprises, consists of, or consists essentially of at least one lead and/or tin complexing agent in combination with at least one oxidizing agent and water. In yet another embodiment, the solder removal composition comprises, consists of, or consists essentially of at least one oxidizing agent, water, and at least one passivating agent for passivating the precious metals and/or base metal materials. In another embodiment, the solder removal composition comprises, consists of, or consists essentially of at least one lead and/or tin complexing agent, at least one oxidizing agent, water, and at least one passivating agent for passivating the precious metals and/or base metal materials. At least one organic solvent, at least one accelerator, at least one corrosion inhibitor, at least one NOx suppressing agent, at least one buffer, at least one surfactant, at least one anti-foaming agent, or any combination thereof can be added to any of the above solder removal composition embodiments. Accordingly, in yet another embodiment, the solder removal composition comprises, consists of, or consists essentially of at least one oxidizing agent, at least one accelerator, water, and at least one passivating agent for passivating the precious metals and/or base metal materials. The weight percent ratio of the at least one oxidizing agent to at least one passivating agent is in a range from about 1:1 to about 50:1, preferably about 15:1 to about 35:1. The weight percent ratio of the at least one accelerator to at least one passivating agent is in a range from about 1:1 to about 25:1, preferably about 8:1 to about 20:1.

Oxidizing agents are included in the composition to oxidize the metals to be removed into an ionic form and accumulate highly soluble salts of dissolved metals. Oxidizing agents contemplated herein include, but are not limited to, ozone, nitric acid (HNO₃), bubbled air, cyclohexylaminosulfonic acid, hydrogen peroxide (H₂O₂), oxone (potassium peroxymonosulfate, 2KHSO₅. KHSO₄K₂SO₄), ammonium polyatomic salts (e.g., ammonium peroxomonosulfate, ammonium chlorite (NH₄ClO₂), ammonium chlorate (NH₄ClO₃), ammonium iodate (NH₄IO₃), ammonium perborate (NH₄BO₃), ammonium perchlorate (NH₄ClO₄), ammonium periodate (NH₄IO₃), ammonium persulfate ((NH₄)₂S₂O₈), ammonium hypochlorite (NH₄ClO)), sodium polyatomic salts (e.g., sodium persulfate (Na₂S₂O₈), sodium hypochlorite (NaClO)), potassium polyatomic salts (e.g., potassium iodate (KIO₃), potassium permanganate (KMnO₄), potassium persulfate, potassium persulfate (K₂S₂O₈), potassium hypochlorite (KClO)), tetramethylammonium polyatomic salts (e.g., tetramethylammonium chlorite ((N(CH₃)₄)ClO₂), tetramethylammonium chlorate ((N(CH₃)₄)ClO₃), tetramethylammonium iodate ((N(CH₃)₄)IO₃), tetramethylammonium perborate ((N(CH₃)₄)BO₃), tetramethylammonium perchlorate ((N(CH₃)₄)ClO₄), tetramethylammonium periodate ((N(CH₃)₄)IO₄), tetramethylammonium persulfate ((N(CH₃)₄)S₂O₈)), tetrabutylammonium polyatomic salts (e.g., tetrabutylammonium peroxomonosulfate), peroxomonosulfuric acid, urea hydrogen peroxide ((CO(NH₂)₂)H₂O₂), peracetic acid (CH₃(CO)OOH), sodium nitrate, potassium nitrate, ammonium nitrate, sulfuric acid, and combinations thereof. Although not oxidizing agents per se, for the sake of the present disclosure, oxidizing agents further include alkanesulfonic acids (e.g., methanesulfonic acid (MSA), ethanesulfonic acid, 2-hydroxyethanesulfonic acid, n-propanesulfonic acid, isopropanesulfonic acid, isobutenesulfonic acid, n-butanesulfonic acid, n-octanesulfonic acid), benzenesulfonic acid, benzenesulfonic acid derivatives (e.g., 4-methoxybenzenesulfonic acid, 4-hydroxybenzenesulfonic acid, 4-aminobenzenesulfonic acid, 4-nitrobenzenesulfonic acid, toluenesulfonic acid, hexylbenzenesulfonic acid, heptylbenzenesulfonic acid, octylbenzenesulfonic acid, nonylbenzenesulfonic acid, decylbenzenesulfonic acid, undecylbenzenesulfonic acid, dodecylbenzenesulfonic acid, tridecylbenzenesulfonic acid, tetradecylbenzene sulfonic acid, hexadecylbenzene sulfonic acid, 3-nitrobenzenesulfonic acid, 2-nitrobenzenesulfonic acid, 2-nitronaphthalenesulfonic acid, 3-nitronaphthalenesulfonic acid, 2,3-dinitrobenzenesulfonic acid, 2,4-dinitrobenzenesulfonic acid, 2,5-dinitrobenzenesulfonic acid, 2,6-dinitrobenzenesulfonic acid, 3,5-dinitrobenzenesulfonic acid, 2,4,6-trinitrobenzenesulfonic acid, 3-aminobenzenesulfonic acid, 2-aminobenzenesulfonic acid, 2-aminonaphthalenesulfonic acid, 3-aminonaphthalenesulfonic acid, 2,3-diaminobenzenesulfonic acid, 2,4-diaminobenzenesulfonic acid, 2,5-diaminobenzenesulfonic acid, 2,6-diaminobenzenesulfonic acid, 3,5-diaminobenzenesulfonic acid, 2,4,6-triaminobenzenesulfonic acid, 3-hydroxybenzenesulfonic acid, 2-hydroxybenzenesulfonic acid, 2-hydroxynaphthalenesulfonic acid, 3-hydroxynaphthalenesulfonic acid, 2,3-dihydroxybenzenesulfonic acid, 2,4-dihydroxybenzenesulfonic acid, 2,5-dihydroxybenzenesulfonic acid, 2,6-dihydroxybenzenesulfonic acid, 3,5-dihydroxybenzene sulfonic acid, 2,3,4-trihydroxybenzenesulfonic acid, 2,3,5-trihydroxybenzenesulfonic acid, 2,3,6-trihydroxybenzene sulfonic acid, 2,4,5-trihydroxybenzenesulfonic acid, 2,4,6-trihydroxybenzene sulfonic acid, 3,4,5-trihydroxybenzenesulfonic acid, 2,3,4,5-tetrahydroxybenzenesulfonic acid, 2,3,4,6-tetrahydroxybenzenesulfonic acid, 2,3,5,6-tetmhydroxybenzenesulfonic acid, 2,4,5,6-tetrahydroxybenzenesulfonic acid, 3-methoxybenzenesulfonic acid, 2-methoxybenzenesulfonic acid, 2,3-dimethoxybenzenesulfonic acid, 2,4-dimethoxybenzenesulfonic acid, 2,5-dimethoxybenzenesulfonic acid, 2,6-dimethoxybenzenesulfonic acid, 3,5-dimethoxybenzenesulfonic acid, 2,4,6-trimethoxybenzenesulfonic acid), alkyl sulfate sulfonic acid, pyridine sulfonic acid, and combinations thereof. The oxidizing agents can include a combination of the any of the species defined herein as oxidizing agent. The oxidizing agent may be introduced to the solder removal composition at the manufacturer, prior to introduction of the solder removal composition to the PCB, or alternatively at the PCB, i.e., in situ. Preferably, the oxidizing agent comprises a peroxide compound, oxone, nitric acid, sodium nitrate, methanesulfonic acid, or any combination thereof. Most preferably, the oxidizing agent comprises methanesulfonic acid.

When present, it is thought that an effective amount of nitric acid or salt thereof serve as an accelerator of the solder removal process. Accordingly, in some embodiments, the oxidizing agent in the solder removal composition preferably comprises an alkane sulfonic acid (e.g., MSA) and nitric acid or salt thereof. Other accelerators contemplated include acids such as sulfuric acid, hydrochloric acid, phosphoric acid, hydrobromic acid, and any combination thereof.

The complexing agents are included to complex the ions produced by the oxidizing agent. Complexing agents contemplated herein include, but are not limited to: β-diketonate compounds such as acetylacetonate, 1,1,1-trifluoro-2,4-pentanedione, and 1,1,1,5,5,5-hexafluoro-2,4-pentanedione; carboxylates such as formate and acetate and other long chain carboxylates; and amides (and amines), such as bis(trimethylsilylamide) tetramer. Additional chelating agents include amines and amino acids (i.e. glycine, serine, proline, leucine, alanine, asparagine, aspartic acid, glutamine, valine, and lysine), citric acid, acetic acid, maleic acid, oxalic acid, malonic acid, succinic acid, phosphonic acid, phosphonic acid derivatives such as hydroxyethylidene diphosphonic acid (HEDP), 1-hydroxyethane-1,1-diphosphonic acid, nitrilo-tris(methylenephosphonic acid), nitrilotriacetic acid, iminodiacetic acid, etidronic acid, ethylenediamine, ethylenediaminetetraacetic acid (EDTA), and (1,2-cyclohexylenedinitrilo)tetraacetic acid (CDTA), uric acid, tetraglyme, pentamethyldiethylenetriamine (PMDETA), 1,3,5-triazine-2,4,6-thithiol trisodium salt solution, 1,3,5-triazine-2,4,6-thithiol triammonium salt solution, sodium diethyldithiocarbamate, disubstituted dithiocarbamates (R¹(CH₂CH₂O)₂NR²CS₂Na) with one alkyl group (R²=hexyl, octyl, deceyl or dodecyl) and one oligoether (R¹(CH₂CH₂O)₂, where R¹=ethyl or butyl), ammonium sulfate, monoethanolamine (MEA), Dequest 2000, Dequest 2010, Dequest 2060s, diethylenetriamine pentaacetic acid, propylenediamine tetraacetic acid, 2-hydroxypyridine 1-oxide, ethylendiamine disuccinic acid (EDDS), N-(2-hydroxyethyl)iminodiacetic acid (HEIDA), sodium triphosphate penta basic, sodium and ammonium salts thereof, ammonium chloride, sodium chloride, lithium chloride, potassium chloride, ammonium sulfate, triammonium citrate, sodium citrate, thiourea, hydrochloric acid, sulfuric acid, and combinations thereof. Preferably, the complexing agent comprises HEDP, HEIDA, EDDS, sodium or ammonium salts thereof, sulfuric acid, or combinations thereof.

Passivating agents for passivating the precious metals and/or base metals include, but are not limited to, ascorbic acid, adenosine, L(+)-ascorbic acid, isoascorbic acid, ascorbic acid derivatives, citric acid, ethylenediamine, gallic acid, oxalic acid, tannic acid, ethylenediaminetetraacetic acid (EDTA), uric acid, 1,2,4-triazole (TAZ), triazole derivatives (e.g., benzotriazole (BTA), tolyltriazole, 5-phenyl-benzotriazole, 5-nitro-benzotriazole, 3-amino-5-mercapto-1,2,4-triazole, 1-amino-1,2,4-triazole, hydroxybenzotriazole, 2-(5-amino-pentyl)-benzotriazole, 1-amino-1,2,3-triazole, 1-amino-5-methyl-1,2,3-triazole, 3-amino-1,2,4-triazole, 3-mercapto-1,2,4-triazole, 3-isopropyl-1,2,4-triazole, 5-phenylthiol-benzotriazole, halo-benzotriazoles (halo=F, Cl, Br or I), naphthotriazole), 4-amino-1,2,4-triazole (ATAZ), 2-mercaptobenzimidazole (MBI), 2-mercaptobenzothiazole, 4-methyl-2-phenylimidazole, 2-mercaptothiazoline, 5-aminotetrazole (ATA), 5-amino-1,3,4-thiadiazole-2-thiol, 2,4-diamino-6-methyl-1,3,5-triazine, thiazole, triazine, methyltetrazole, 1,3-dimethyl-2-imidazolidinone, 1,5-pentamethylenetetrazole, 1-phenyl-5-mercaptotetmzole, diaminomethyltriazine, imidazoline thione, mercaptobenzimidazole, 4-methyl-4H-1,2,4-triazole-3-thiol, 5-amino-1,3,4-thiadiazole-2-thiol, benzothiazole, tritolyl phosphate, imidazole, indiazole, benzoic acid, boric acid, malonic acid, ammonium benzoate, catechol, pyrogallol, resorcinol, hydroquinone, cyanuric acid, barbituric acid and derivatives such as 1,2-dimethylbathituric acid, alpha-keto acids such as pyruvic acid, adenine, purine, phosphonic acid and derivatives thereof, glycine/ascorbic acid, Dequest 2000, Dequest 7000, p-tolylthiourea, succinic acid, phosphonobutane tricarboxylic acid (PBTCA), sodium molybdate, ammonium molybdate, salts of chromate (e.g., sodium, potassium, calcium, barium), sodium tungstate, salts of dichromate (e.g., sodium, potassium, ammonium), sodium sulfate, suberic acid, azaleic acid, sebacic acid, adipic acid, octamethylene dicarboxylic acid, pimelic acid, dodecane dicarboxylic acid, dimethyl malonic acid, 3,3-diethyl succinic acid, 2,2-dimethyl glutaric acid, 2-methyl adipic acid, trimethyl adipic acid, 1,3-cyclopentane dicarboxylic acid, 1,4-cyclohexane dicarboxylic acid, terephthalic acid, isophthalic acid, 2,6-naphthalene dicarboxylic acid, 2,7-naphthalene dicaroxylic acid, 1,4-naphthalene dicarboxylic acid, 1,4-phenylenedioxy diacetic acid, 1,3-phenylenedioxy diacetic acid, diphenic acid, 4,4′-biphenyl dicarboxylic acid, 4,4′-oxydibenzoic acid, diphenylmethane-4,4′-dicarboxylic acid, diphenylsulfone-4,4′-dicarboxylic acid, decamethylene dicarboxylic acid, undecamethylene dicarboxylic acid, dodecamethylene dicarboxylic acid, orthophthalic acid, naphthalenedicarboxylic acid, paraphenylenedicarboxylic acid, trimellitic acid, pyromellitic acid, sodium phosphates (e.g., sodium hexametaphosphate), sodium silicates, amino acids and their derivatives such as 1-arginine, nucleoside and nucleobases such as adensosine and adenine, respectively, and combinations thereof. Most preferably, the passivating agent comprises BTA, ATAZ, TAZ, triazole derivatives, ascorbic acid, sodium molybdate, or combinations thereof.

Although not wishing to be bound by theory, it is thought that organic solvents, when added, enhance the metal etch rates by wetting the surface of the microelectronic device structure. Organic solvents contemplated herein include, but are not limited to, alcohols, ethers, pyrrolidinones, glycols, carboxylic acids, glycol ethers, amines, ketones, aldehydes, alkanes, alkenes, alkynes, carbonates, and amides, more preferably alcohols, ethers, pyrrolidinones, glycols, carboxylic acids, and glycol ethers such as methanol, ethanol, isopropanol, butanol, and higher alcohols (including diols, and triols), tetrahydrofuran (THF), N-methylpyrrolidinone (NMP), cyclohexylpyrrolidinone, N-octylpyrrolidinone, N-phenylpyrrolidinone, methyl formate, dimethyl formamide (DMF), dimethylsulfoxide (DMSO), tetramethylene sulfone (sulfolane), diethyl ether, phenoxy-2-propanol (PPh), propriopheneone, ethyl lactate, ethyl acetate, ethyl benzoate, acetonitrile, acetone, ethylene glycol, propylene glycol, dioxane, butyryl lactone, butylene carbonate, ethylene carbonate, propylene carbonate, dipropylene glycol, amphiphilic species (diethylene glycol monomethyl ether, triethylene glycol monomethyl ether, diethylene glycol monoethyl ether, triethylene glycol monoethyl ether, ethylene glycol monopropyl ether, ethylene glycol monobutyl ether, diethylene glycol monobutyl ether (i.e., butyl carbitol), triethylene glycol monobutyl ether, ethylene glycol monohexyl ether, diethylene glycol monohexyl ether, ethylene glycol phenyl ether, propylene glycol methyl ether, dipropylene glycol methyl ether (DPGME), tripropylene glycol methyl ether, dipropylene glycol dimethyl ether, dipropylene glycol ethyl ether, propylene glycol n-propyl ether, dipropylene glycol n-propyl ether (DPGPE), tripropylene glycol n-propyl ether, propylene glycol n-butyl ether, dipropylene glycol n-butyl ether, tripropylene glycol n-butyl ether, propylene glycol phenyl ether, and combinations thereof), branched non-fluorinated ether-linkage carboxylic acids (CH₃CH₂)ₙO(CH₂)ₘCOOH, where n=1 to 10 and m=1 to 10), unbranched non-fluorinated ether-linkage carboxylic acids (CH₃CH₂)ₙO(CH₂)ₘCOOH, where n=1 to 10 and m=1 to 10), branched non-fluorinated non-ether linkage carboxylic acids (CH₃(CH₂)—COOH, where n=1 to 10), unbranched non-fluorinated non-ether linkage carboxylic acids (CH₃(CH₂)—COOH, where n=1 to 10), dicarboxylic acids, tricarboxylic acids, and combinations thereof. Preferably, the organic solvent comprises diethylene glycol monobutyl ether, dipropylene glycol propyl ether, propylene glycol, or mixtures thereof.

Preferred embodiments of the solder removal composition include, but are not limited to, (i) a solder removal composition comprising, consisting of or consisting essentially of MSA, nitric acid, BTA and water; (ii) a solder removal composition comprising, consisting of or consisting essentially of MSA, nitric acid, TAZ and water; (iii) a solder removal composition comprising, consisting of or consisting essentially of MSA, nitric acid, 1-amino-1,2,4-triazole (ATAZ), and water; (iv) a solder removal composition comprising, consisting of or consisting essentially of MSA, nitric acid, 1-amino-1,2,3-triazole and water; (v) a solder removal composition comprising, consisting of or consisting essentially of MSA, nitric acid, 1-amino-5-methyl-1,2,3-triazole and water; (vi) a solder removal composition comprising, consisting of or consisting essentially of MSA, nitric acid, 3-amino-1,2,4-triazole and water; (vii) a solder removal composition comprising, consisting of or consisting essentially of MSA, nitric acid, 3-mercapto-1,2,4-triazole and water; (viii) a solder removal composition comprising, consisting of or consisting essentially of MSA, nitric acid, 3-isopropyl-1,2,4-triazole and water; (ix) a solder removal composition comprising, consisting of or consisting essentially of MSA, nitric acid, MBI and water; (x) a solder removal composition comprising, consisting of or consisting essentially of MSA, nitric acid, ATA and water; (xi) a solder removal composition comprising, consisting of or consisting essentially of MSA, nitric acid, 2,4-diamino-6-methyl-1,3,5-triazine and water; (xii) a solder removal composition comprising, consisting of or consisting essentially of MSA, nitric acid, ascorbic acid and water; (xiii) a solder removal composition comprising, consisting of or consisting essentially of MSA, nitric acid, sodium molybdate and water; and (xiv) a solder removal composition comprising, consisting of or consisting essentially of MSA, nitric acid, 3-amino-5-mercapto-1,2,4-triazole and water.

It will be appreciated by the person skilled in the art that the solder removal composition can be prepared upstream and stored in a tank for use, prepared upstream in the lines for introduction into the reaction tank, or prepared directly in the reaction tank by introducing the chemicals therein. Further, it is contemplated that a concentrate can be prepared and stored for dilution with a diluent (e.g., water) prior to, or in, the reaction tank.

In one embodiment, the solder removal composition is used until loaded with dissolved/solubilized metal ions, e.g., lead ions, and/or tin ions. In one embodiment, one or more constituents of the solder removal composition is a regenerated and/or recycled constituent from one or more effluent waste streams within the e-waste facility.

### Base Metal Removal Compositions

For the purposes of the presently disclosed matter, the base metal removal composition is preferably highly selective, wherein substantially no gold dissolves in the base metal removal composition. In one embodiment, the base metal removal composition comprises, consists of, or consists essentially of at least one oxidizing agent and water. The base metal removal composition may further comprise at least one complexing agent, at least one organic solvent, at least one anti-foaming agent, at least one NOx suppressing agent, and/or at least one passivating agent for passivating the precious metals. In another embodiment, the base metal removal composition comprises, consists of, or consists essentially of at least one complexing agent in combination with at least one oxidizing agent and water. In yet another embodiment, the base metal removal composition comprises, consists of, or consists essentially of at least one oxidizing agent, water, and at least one passivating agent for passivating the precious metals. In another embodiment, the base metal removal composition comprises, consists of, or consists essentially of at least one complexing agent, at least one oxidizing agent, water, and at least one passivating agent for passivating the precious metals. In still another embodiment, the base metal removal composition comprises, consists of, or consists essentially of at least one oxidizing agent, at least one NOx suppressing agent, and water, wherein the at least one oxidizing agent comprises nitric acid and/or at least one nitrate salt. At least one corrosion inhibitor, at least one buffer, at least one surfactant, or any combination thereof can be further added to any of the embodiments of the base metal removal composition above.

Oxidizing agents are included in the composition to oxidize the metals to be removed into an ionic form and accumulate highly soluble salts of dissolved metals. Oxidizing agents contemplated herein include, but are not limited to, ozone, nitric acid (HNO₃), bubbled air, cyclohexylaminosulfonic acid, hydrogen peroxide (H₂O₂), oxone (potassium peroxymonosulfate, 2KHSO₅.KHSO₄K₂SO₄), ammonium polyatomic salts (e.g., ammonium peroxomonosulfate, ammonium chlorite (NH₄ClO₂), ammonium chlorate (NH₄ClO₃), ammonium iodate (NH₄IO₃), ammonium perborate (NH₄BO₃), ammonium perchlorate (NH₄ClO₄), ammonium periodate (NH₄IO₃), ammonium persulfate ((NH₄)₂S₂O₈), ammonium hypochlorite (NH₄ClO)), sodium polyatomic salts (e.g., sodium persulfate (Na₂S₂O₈), sodium hypochlorite (NaClO)), potassium polyatomic salts (e.g., potassium iodate (KIO₃), potassium permanganate (KMnO₄), potassium persulfate, potassium persulfate (K₂S₂O₈), potassium hypochlorite (KClO)), tetramethylammonium polyatomic salts (e.g., tetramethylammonium chlorite ((N(CH₃)₄)ClO₂), tetramethylammonium chlorate ((N(CH₃)₄)ClO₃), tetramethylammonium iodate ((N(CH₃)₄)IO₃), tetramethylammonium perborate ((N(CH₃)₄)BO₃), tetramethylammonium perchlorate ((N(CH₃)₄)ClO₄), tetramethylammonium periodate ((N(CH₃)₄)IO₄), tetramethylammonium persulfate ((N(CH₃)₄)S₂O₈), tetramethylammonium nitrate), tetrabutylammonium polyatomic salts (e.g., tetrabutylammonium peroxomonosulfate, tetrabutylammonium nitrate), peroxomonosulfuric acid, urea hydrogen peroxide ((CO(NH₂)₂)H₂O₂), peracetic acid (CH₃(CO)OOH), sodium nitrate, potassium nitrate, ammonium nitrate, and combinations thereof. Most preferably, the oxidizing agent comprises a species selected from the group consisting of nitric acid, sodium nitrate, potassium nitrate, ammonium nitrate, tetraalkylammonium nitrate, and combinations thereof. The oxidizing agent(s) is present in a range from about 1 wt % to about 35 wt %, preferably about 10 wt % to about 30 wt %.

The at least one NOx suppressing agent can be added when the at least one oxidizing agent comprises nitric acid and/or at least one nitrate salt. NOx suppressing agents include, but are not limited to, hydrogen peroxide, fluorine (F₂), chlorine (Cl₂), urea, ammonia, sodium hydrosulfide, sodium hypochlorite, sodium hydroxide, and other oxidizing agents having a higher oxidizing potential than the nitric acid and/or at least one nitrate salt. Advantageously, hydrogen peroxide is able to react with the formed NOx to produce nitric acid, which can be reused. Alternatively, or in addition, azoles, ammonium sulfamate, sulfamic acid, sodium hydroxide, sodium hydrosulfide, urea, and combinations thereof can be useful NOx suppressing agents. Azoles contemplated include, but are not limited to, 1,2,4-triazole (TAZ), 1,2,3-triazole, benzotriazole (BTA), tolyltriazole, 5-phenyl-benzotriazole, 5-nitro-benzotriazole, 3-amino-5-mercapto-1,2,4-triazole, 1-amino-1,2,4-triazole, hydroxybenzotriazole, 2-(5-amino-pentyl)-benzotriazole, 1-amino-1,2,3-triazole, 1-amino-5-methyl-1,2,3-triazole, 3-amino-1,2,4-triazole, 3-mercapto-1,2,4-triazole, 3-isopropyl-1,2,4-triazole, 5-phenylthiol-benzotriazole, halo-benzotriazoles (halo=F, Cl, Br or I), naphthotriazole, 4-amino-1,2,4-triazole (ATAZ), 2-mercaptobenzimidazole (MBI), 2-mercaptobenzothiazole, 4-methyl-2-phenylimidazole, 2-mercaptothiazoline, 5-aminotetrazole (ATA), 5-amino-1,3,4-thiadiazole-2-thiol, 2,4-diamino-6-methyl-1,3,5-triazine, thiazole, triazine, methyltetrazole, 1,3-dimethyl-2-imidazolidinone, 1,5-pentamethylenetetrazole, 1-phenyl-5-mercaptotetmzole, diaminomethyltriazine, imidazoline thione, mercaptobenzimidazole, 4-methyl-4H-1,2,4-triazole-3-thiol, 5-amino-1,3,4-thiadiazole-2-thiol, benzothiazole, imidazole, indiazole, and combinations thereof. When present, the at least one NOx suppressing agent is present in an amount from about 0.1 wt % to about 20 wt %, preferably about 1 wt % to about 20 wt %. Put another way, the weight percent ratio of the at least one oxidizing agent to the at least one NOx suppressing agent is about 0.01:1 to about 40:1. When the at least one NOx suppressing agent is included in the base metal removal composition, it should be appreciated by the person skilled in the art that the at least one NOx suppressing agent can be added upstream of the reaction tank, introduced directly into the reaction tank just prior to the introduction of solid, introduced directly into the reaction tank at the same time that the solid is introduced, or introduced directly into the reaction tank after the solid is introduced. Without wishing to be bound by theory, when the base metal removal composition comprises nitric acid and/or at least one nitrate salt, the at least one NOx suppressing agent is added to minimize NOx production, e.g., by as much as 50%, preferably in a range from about 50% to 95%. For example, when hydrogen peroxide is used as the NOx suppressing agent and is added to the SPT base metal removal module (380) at the same time as the solids, the total amount of NOx is reduced by 79% and 92% for DRAM chips and powdered base metal, respectively.

It will be appreciated by the person skilled in the art that the base metal removal composition can be prepared upstream and stored in a tank for use, prepared upstream in the lines for introduction into the reaction tank, or prepared directly in the reaction tank by introducing the chemicals therein. Further, it is contemplated that a concentrate can be prepared and stored for dilution with a diluent (e.g., water) prior to, or in, the reaction tank.

In one embodiment, the base metal removal composition is used until loaded with dissolved/solubilized metal ions, e.g., copper ions, and/or nickel ions. In one embodiment, one or more constituents of the base metal removal composition is a regenerated and/or recycled constituent from one or more effluent waste streams within the e-waste facility.

### Silver Leaching Composition

One embodiment of a silver leaching (SL) composition comprises, consists of, or consists essentially of at least one complexing agent and at least one solvent. The silver leaching composition may further comprise at least one oxidizing agent, at least one organic solvent, and/or at least one passivating agent. In another embodiment, the silver leaching composition comprises, consists of, or consists essentially of at least one complexing agent in combination with at least one oxidizing agent and water. In yet another embodiment, the silver leaching composition comprises, consists of, or consists essentially of at least one complexing agent in combination with at least one oxidizing agent, water, and at least one passivating agent. In another embodiment, the silver leaching composition comprises, consists of, or consists essentially of at least one complexing agent in combination with water and at least one passivating agent. The silver leaching composition can further comprise at least one surfactant, at least one anti-foaming agent, at least one corrosion inhibitor, at least one NOx suppressing agent, at least one buffer, or any combination thereof.

Complexing agents are included in the composition to capture the silver metal to be removed. Complexing agents contemplated herein include, but are not limited to, thiosulfate compounds (i.e., sodium thiosulfate, ammonium thiosulfate, potassium thiosulfate), amines and amino acids (i.e. glycine, serine, proline, leucine, alanine, asparagine, aspartic acid, glutamine, valine, and lysine), citric acid, acetic acid, maleic acid, oxalic acid, malonic acid, succinic acid, phosphonic acid, phosphonic acid derivatives such as hydroxyethylidene diphosphonic acid (HEDP), 1-hydroxyethane-1,1-diphosphonic acid, nitrilo-tris(methylenephosphonic acid), nitrilotriacetic acid, iminodiacetic acid, etidronic acid, ethylenediamine, ethylenediaminetetraacetic acid (EDTA), and (1,2-cyclohexylenedinitrilo)tetraacetic acid (CDTA), uric acid, tetraglyme, pentamethyldiethylenetriamine (PMDETA), 1,3,5-triazine-2,4,6-thithiol trisodium salt solution, 1,3,5-triazine-2,4,6-thithiol triammonium salt solution, sodium diethyldithiocarbamate, disubstituted dithiocarbamates (R¹(CH₂CH₂O)₂NR²CS₂Na) with one alkyl group (R²=hexyl, octyl, deceyl or dodecyl) and one oligoether (R¹(CH₂CH₂O)₂, where R¹=ethyl or butyl), ammonium sulfate, monoethanolamine (MEA), Dequest 2000, Dequest 2010, Dequest 2060s, diethylenetriamine pentaacetic acid, propylenediamine tetraacetic acid, 2-hydroxypyridine 1-oxide, ethylendiamine disuccinic acid (EDDS), N-(2-hydroxyethyl)iminodiacetic acid (HEIDA), sodium triphosphate penta basic, ammonium chloride, sodium chloride, lithium chloride, potassium chloride, ammonium sulfate, hydrochloric acid, sulfuric acid, and combinations thereof. Preferably, the complexing agent comprises at least one thiosulfate compound such as sodium thiosulfate. The complexing agent(s) is present in a range from about 0.1 wt % to about 15 wt %, preferably about 1 wt % to about 10 wt %.

The at least one solvent includes, but is not limited to, water, methanol, ethanol, isopropanol, butanol, pentanol, hexanol, 2-ethyl-1-hexanol, heptanol, octanol, ethylene glycol, propylene glycol, butylene glycol, tetrahydrofurfuryl alcohol (THFA), butylene carbonate, ethylene carbonate, propylene carbonate, dipropylene glycol, diethylene glycol monomethyl ether, triethylene glycol monomethyl ether, diethylene glycol monoethyl ether, triethylene glycol monoethyl ether, ethylene glycol monopropyl ether, ethylene glycol monobutyl ether, diethylene glycol monobutyl ether, triethylene glycol monobutyl ether, ethylene glycol monohexyl ether, diethylene glycol monohexyl ether, ethylene glycol phenyl ether, propylene glycol methyl ether, dipropylene glycol methyl ether (DPGME), tripropylene glycol methyl ether (TPGME), dipropylene glycol dimethyl ether, dipropylene glycol ethyl ether, propylene glycol n-propyl ether, dipropylene glycol n-propyl ether (DPGPE), tripropylene glycol n-propyl ether, propylene glycol n-butyl ether, dipropylene glycol n-butyl ether, tripropylene glycol n-butyl ether, propylene glycol phenyl ether, 2,3-dihydrodecafluoropentane, ethyl perfluorobutylether, methyl perfluorobutylether, alkyl carbonates, alkylene carbonates, 4-methyl-2-pentanol, tetramethylene glycol dimethyl ether, and combinations thereof. Preferably, the at least one solvent comprises water.

In a particularly preferred embodiment, the SL composition comprises, consists of, or consists essentially of sodium thiosulfate and water. The pH is preferably in a range from about 6 to about 8.

It will be appreciated by the person skilled in the art that the silver removal composition can be prepared upstream and stored in a tank for use, prepared upstream in the lines for introduction into the reaction tank, or prepared directly in the reaction tank by introducing the chemicals therein. Further, it is contemplated that a concentrate can be prepared and stored for dilution with a diluent (e.g., water) prior to, or in, the reaction tank.

In one embodiment, the silver removal composition is used until loaded with dissolved/solubilized silver ions. In one embodiment, one or more constituents of the silver removal composition is a regenerated and/or recycled constituent from one or more effluent waste streams within the e-waste facility.

Although the invention has been variously disclosed herein with reference to illustrative embodiments and features, it will be appreciated that the embodiments and features described hereinabove are not intended to limit the invention, and that other variations, modifications and other embodiments will suggest themselves to those of ordinary skill in the art, based on the disclosure herein. The invention therefore is to be broadly construed, as encompassing all such variations, modifications and alternative embodiments within the spirit and scope of the claims hereafter set forth.

What is claimed is:

1. An integrated, intelligent system for recycling material selected from the group consisting of printed circuit boards (PCB), PCB components, materials comprising gold, and combinations thereof, wherein the system efficiently recovers more than about 80% of the gold contained in the material, wherein the system comprises a solids processing technology (SPT) base metal removal module and a SPT gold removal module, and optionally at least one additional module selected from the group consisting of:
(a) a SPT furnace module,
(b) a SPT milling module,
(c) a SPT silver leaching module,
(d) any combination of (a)-(c), and
(e) every module of (a)-(c),
wherein the modules are positioned and/or operated in series with one another, with or without intervening parts.

2. An integrated, intelligent system for recycling material selected from the group consisting of printed circuit boards (PCB), PCB components, materials comprising gold, and combinations thereof, wherein the system efficiently recovers more than about 80% of the gold contained in the material, wherein the system comprises a solids processing technology (SPT) furnace module and a SPT gold removal module, and optionally at least one additional module selected from the group consisting of:
(a) a SPT milling module,
(b) a SPT base metal removal module
(c) a SPT silver leaching module,
(d) any combination of (a)-(c), and
(e) every module of (a)-(c),
wherein the modules are positioned and/or operated in series with one another, with or without intervening parts.

3. An integrated, intelligent system for recycling material selected from the group consisting of printed circuit boards (PCB), PCB components, materials comprising gold, and combinations thereof, wherein the system efficiently recovers more than about 80% of the gold contained in the material, said system comprising a gold leaching module and a SPT gold removal module, and optionally at least one additional module selected from the group consisting of:
(a) a pre-board clearing module,
(b) a Board clearing module,
(c) a desoldering module,
(d) a base metal removal module,
(e) a SPT furnace module,
(f) a SPT milling module,
(g) a SPT base metal removal module,
(h) a SPT silver leaching module,
(i) any combination of (a)-(h), and
(j) every module of (a)-(h),
wherein the modules are positioned and/or operated in series with one another, with or without intervening parts.

4. (canceled)

5. The system of any of claim 14, wherein the material to be recycled moves from module to module and/or within a module, automatically or manually, using a moving means.

6. The system of claim 1, wherein the SPT base metal removal module comprises:
(a) at least one reaction tank,
(b) at least one holding tank in liquid communication with the at least one reaction tank,
(c) at least one rinse tank in liquid communication with the at least one holding tank, wherein said SPT base metal removal module is capable of removing at least one base metal from a solid, wherein the solid comprises material that has been ashed, ground, and/or crushed.

7. The system of claim 6, wherein the SPT base metal removal module further comprise at least one of: at least one base metal removal composition tank in liquid communication with the at least one reaction tank; at least one rinse liquid tank in liquid communication with the at least one rinse tank; at least one centrifuge; agitation means in at least one of the reaction tank, the at least one holding tank, and/or the at least one rinse tank; at least one pump; heating/cooling means for at least one of the reaction tank, the at least one holding tank, and/or the at least one rinse tank; at least one air input for at least one of the reaction tank, the at least one holding tank, and/or the at least one rinse tank; realtime sampling and adjustment; programmable logic controllers or equivalent thereof; sensing means for at least one of the reaction tank, the at least one holding tank, and/or the at least one rinse tank; and ventilation means for at least one of the reaction tank, the at least one holding tank, and/or the at least one rinse tank.

8. The system of claim 6, wherein the at least one reaction tank and/or the at least one holding tank comprise a base metal removal composition.

9. The system of claim 7, wherein the base metal removal composition comprises at least one oxidizing agent and water and optionally at least one additional constituent selected from the group consisting of at least one complexing agent, at least one organic solvent, at least one anti-foaming agent, at least one NOx suppressing agent, and at least one passivating agent for passivating the precious metals.

10. (canceled)

11. The system of claim 2, wherein the SPT gold removal module comprises at least one of:
(a) at least one reaction tank,
(b) at least one holding tank in liquid communication with the at least one reaction tank,
(c) at least one rinse tank in liquid communication with the at least one holding tank, and wherein said SPT gold removal module is capable of removing gold from a solid, wherein the solid comprises material that has been ashed, ground, and/or crushed.

12. The system of claim 11, wherein the SPT gold removal module further comprise at least one of: at least one gold removal composition tank in liquid communication with the at least one reaction tank; at least one rinse liquid tank in liquid communication with the at least one rinse tank; at least one centrifuge; agitation means in at least one of the reaction tank, the at least one holding tank, and/or the at least one rinse tank; at least one pump; heating/cooling means for at least one of the reaction tank, the at least one holding tank, and/or the at least one rinse tank; at least one air input for at least one of the reaction tank, the at least one holding tank, and/or the at least one rinse tank; real-time sampling and adjustment; programmable logic controllers or equivalent thereof; sensing means for at least one of the reaction tank, the at least one holding tank, and/or the at least one rinse tank; and ventilation means for at least one of the reaction tank, the at least one holding tank, and/or the at least one rinse tank, wherein said SPT gold removal module is capable of removing gold from a solid, wherein the solid comprises material that has been ashed, ground, and/or crushed.

13. The system of claim 11, wherein the at least one reaction tank and/or the at least one holding tank comprise a gold removal composition.

14. The system of claim 11, wherein the gold removal composition comprises at least one oxidizing agent, optionally at least one halide, optionally at least one acid, and optionally at least one solvent, preferably at least one oxidizing agent, at least one halide, at least one acid, and at least one solvent.

15. (canceled)

16. The system of claim 2, wherein the SPT furnace module comprises (a) a furnace and (b) means to control the air input into the furnace, wherein the SPT furnace module converts the material into ash or powder.

17. (canceled)

18. The system of claim 12, wherein the SPT furnace module further comprises (i) support surfaces within the furnace, (ii) moving means, or both (i) and (ii).

19. The system of claim 13, wherein the moving means comprises at least one mechanism selected from the group consisting of a conveyor belt, a conveyor track, a conveying wheel, a conveying roller, gravity conveyor, robots, a robotic loading arm with a moving mechanism, overhead conveyors with powered channels/tracks, tracks, elevators, collection conveyors, monorails, belts, link chains, transporter with wheels, trucks, hand trucks, trays, fork lifts, boom lifts, scissor lifts, straddle lifts, cantilever lifts, post lifts, vertical lifts, horizontal lifts, trolleys, pallets, dollies, caddies, pulleys, clamps, hoists, hooks, forks, stackers, bucket elevators, carousels, cranes, guided vehicles, carts, pumps, or combinations of the foregoing.

20. The system of claim 1, further comprising at least one additional module selected from the group consisting of:
(a) a pre-board clearing module,
(b) a Board clearing module,
(c) a desoldering module,
(d) a base metal removal module,
(e) a gold leaching module,
(f) any combination of (a)-(e), and
(g) every module of (a)-(e),
wherein the modules are positioned and/or operated in series with one another, with or without intervening parts.

21. The system of claim 3, wherein the gold leaching module comprises a drum-line system comprising: at least at least one gold removal tank, optionally comprising a gold removal composition; at least one dragout tank; and at least one rinsing tank, wherein each tank has the volumetric capacity to contain a drum therein.

22. The system of claim 2416, comprising the gold removal composition, wherein the gold removal composition comprises at least one oxidizing agent, optionally at least one halide, optionally at least one acid, and optionally at least one solvent, preferably at least one oxidizing agent, at least one halide, at least one acid, and at least one solvent.

23. The system of claim 16, wherein the drum-line system comprises moving means to move the drum from tank to tank.

24. The system of claim 16, wherein each tank further comprises one or more of: agitation means; at least one filter; real-time sampling and adjustment; a cover to minimize evaporation; heating/cooling means; air inputs; sensing means; ventilation means; and any combination thereof.

25.-58. (canceled)
